(19) United States
(12) Patent Application Publication
(10) Pub. No.: US 2004/0067435 A1
(43) Pub. Date: Apr. 8, 2004

(54) Image forming material

(75) Inventors: Kaoru Iwato, Shizuoka-ken (JP); Tadahiro Sorori, Shizuoka-ken (JP)

Correspondence Address: SUGHRUE MION, PLLC, 2100 PENNSYLVANIA AVENUE, N.W., SUITE 800, WASHINGTON, DC, 20037, US

(73) Assignee: FUJI PHOTO FILM CO., LTD.

(21) Appl. No.: 10/662,534

(22) Filed: Sep. 16, 2003

(30) Foreign Application Priority Data
Sep. 17, 2002 (JP) 2002-269900
Sep. 30, 2002 (JP) 2002-287818

(51) Int. Cl. G03F 7/039

(52) U.S. Cl. 430/270.1; 430/964

(57) ABSTRACT

The present invention includes a support having thereon an image forming layer containing at least a water-insoluble and alkali-soluble high-molecular compound and a dissolution inhibitor. The dissolution inhibitor is a compound having a structure represented by the following general formula (1) and having an absorption maximum at a wavelength in a range of 760 nm to 1,200 nm, or an onium salt represented by the following general formula (2).

X⁻M⁺ General formula (1):

In the general formula (1), X⁻ represents an anion containing at least one substituent having an alkali-dissociating proton; and M⁺ represents a counter cation which is an atomic group having an absorption maximum at a wavelength in a range of 760 nm to 1,200 nm.

X⁻M₁⁺ General formula (2):

In the general formula (2), X⁻ represents an anion containing at least one substituent having an alkali-dissociating proton; and M₁⁺ represents a counter cation selected from solfonium, iodonium, ammonium, phosphonium, and oxonium.

### CROSS-REFERENCE TO RELATED APPLICATION

This application claims priority under 35USC 119 from Japanese Patent Application Nos.2002-269900 and 2002-287818, the disclosures of which are incorporated by reference herein.

### BACKGROUND OF THE INVENTION

1. Field of the Invention

The present invention relates to an image forming material, and particularly to an image forming material that can be used as an offset printing master. More particularly, the invention relates to a positive image forming material useful as a positive planographic printing plate precursor for an infrared laser for so-called direct plate making in which plate making can be performed directly from digital signals from computers, and the like.

2. Description of the Related Art

In recent years, development of lasers has been remarkable. In particular, with respect to solid lasers or semiconductor lasers having an emitting region in the near infrared to infrared wavelength region, high-output and small-sized products have become easily available. In a field of planographic printing plates, these lasers are very useful as exposure light sources during direct plate making from digital data form computers, and the like.

In positive photosensitive image forming materials for an infrared laser for direct plate making, which have hitherto been known, novolac resins are used as alkaline aqueous solution-soluble resins. For example, Japanese Patent Application Laid-open (JP-A) No. 7-285275 discloses positive photosensitive image forming materials in which a substance that absorbs light to generate heat and a positive photosensitive compound, such as an onium salt or quinonediazide compound, are added to a phenolic hydroxyl group-containing alkaline aqueous solution-soluble resin, such as a novolac resin. The positive photosensitive compound works as a dissolution inhibitor that substantially lowers solubility of the alkaline aqueous solution-soluble resin in image areas, does not exhibit a dissolution inhibiting ability due to heat in non-image area, and the non-image areas can be removed by development to form an image.

Further, for example, WO 97/39894 and EP-A No. 823,327 disclose positive photosensitive image forming materials comprising a substance that absorbs light to generate heat and a resin whose solubility in alkaline aqueous solutions is changed by heat, in which the resin is low in solubility in alkaline aqueous solutions at image areas and high in solubility in alkaline aqueous solutions at non-image areas, and the non-image areas can be removed by development to form an image.

As alkali-soluble resins to be used in such positive image forming materials, phenolic hydroxyl group-containing novolac resins are suitably used. The novolac resins are especially preferably used for the reasons that they strongly mutually act with the above-described dissolution inhibitor so that a difference between solubilities in developing solutions at exposed areas and unexposed areas is large and that they are excellent in ink receptivity.

As the dissolution inhibitor, a wide variety of compounds have been investigated.

For example, among infrared (IR) absorbing materials that play an important role by exhibiting a light-heat converting ability in infrared-sensitive image forming materials, ones having a strong dissolution inhibiting ability are known, and such compounds receive attention because they have dual functions together. In particular, IR coloring materials having a cation site in the molecule thereof have a strong mutual action with novolac resins, etc. and exhibit a high dissolution inhibiting ability. However, these coloring materials have a problem such that, although they exhibit an enhancing effect of dissolution inhibiting ability in image areas (unexposed areas), when an addition amount thereof increases, solubility in alkalis in non-image areas (exposed areas) lowers so as to increase an amount of energy necessary for removing the non-image areas, leading to a reduction in sensitivity. On the other hand, IR coloring materials are an essential material for thermal image formation, and when an addition amount thereof is too small, light-heat converting ability is reduced, and therefore, there are limits to the degree to which the addition amount can be controlled to adjust image forming property, which presents an obstacles to enhancement of sensitivity.

Further, it is known that onium salt type dissolution inhibitors especially have a very strong dissolution inhibiting ability as the dissolution inhibitor. However, the addition of general onium salt compounds involves a problem of occurrence of a reduction in sensitivity, although an enhancing effect of alkali resistance in unexposed areas is obtained due to their high dissolution inhibiting ability. As measures for overcoming such a problem, new photosensitive materials using a specific onium salt have been disclosed. For example, it has become clear that onium salts disclosed in JP-A No. 2002-278050 and quaternary ammonium salts disclosed in JP-A No. 2003-107688 have an excellent characteristic such that a high dissolution inhibiting ability can be achieved with high sensitivity.

However, it has been found that, as time passes after exposure, developability of the photosensitive materials using the above-mentioned onium salt type dissolution inhibitors may decline, resulting in development failure. Such a decline in developability due to an amount of time that has passed after exposure causes problems in the processing step. Therefore, there is a demand for further improvement with respect to image forming material.

### SUMMARY OF THE INVENTION

Accordingly, A first aspect of the present invention is to provide an image forming material having a large difference between solubilities in developing solutions at exposed areas and unexposed areas and being useful as a high-sensitivity heat mode type positive planographic printing plate precursor. The difference in solubility in developing solutions between exposed areas and unexposed areas will be hereinafter properly referred to as “solubility discrimination”.

Under such circumferences, the present inventors made extensive and intensive investigations. As a result, it has been found that by including a specific IR coloring material in an image forming layer, it is possible to achieve excellent solubility discrimination together with high sensitivity, which led to accomplishment of a first embodiment of the image forming material of the invention.

Specifically, the first embodiment of the image forming material of the invention is concerned with an image forming material comprising a support and an image forming layer which is laminated on the support and contains at least (A) a water-insoluble and alkali-soluble high-molecular compound and (B) a compound having a structure represented by the following general formula (1) and having an absorption maximum at a wavelength in a range of 760 nm to 1,200 nm:

X⁻M⁺ General formula (1):

wherein in the general formula (1), X⁻ represents an anion containing at least one substituent having an alkali-dissociating proton; and M⁺ represents a counter cation which is an atomic group having an absorption maximum at a wavelength in a range of 760 nm to 1,200 nm.

A second aspect of the invention is to provide an image forming material that is excellent in a difference between solubilities in developing solutions at exposed areas and unexposed areas, is small in a degree of change in developability due to an amount of time that has passed after exposure, and is useful as a high-sensitivity heat mode type positive planographic printing plate precursor. The degree of change of developability due to an amount of time that has passed after exposure will be hereinafter properly referred to as “latent image stability”.

Under such circumferences, the present inventors made extensive and intensive investigations. As a result, it has been found that by including a specific onium salt in an image forming layer, it is possible to achieve enhancement of solubility discrimination together with improvement of latent image stability, which led to accomplishment of a second embodiment of the image forming material of the invention.

Specifically, a second embodiment of the image forming material of the invention is concerned with an image forming material comprising a support and an image forming layer which is laminated on the support and contains at least (A) a water-insoluble and alkali-soluble high-molecular compound, (C) a light-heat converting agent, and (D) an onium salt represented by the following general formula (2):

X⁻M₁⁺ General Formula (2):

wherein in the general formula (2), X⁻ represents an anion containing at least one substituent having an alkali-dissociating proton; and M₁⁺ represents a counter cation selected from solfonium, iodonium, ammonium, phosphonium, and oxonium.

The exact mechanism resulting in the effects of the first embodiment of the invention is not completely clear but is presumed to be as follows.

That is, in general, when a compound containing an alkali-dissociating substituent, such as a phenolic hydroxyl group, a carboxyl group, or a mercapto group, is added to an image forming layer, the compound functions as a dissolution accelerator, whereby its dissolution inhibiting ability in unexposed areas is lowered. However, in the compound having a structure represented by the above-described general formula (1) and having an absorption maximum at a wavelength ranging from 760 nm to 1,200 nm (this compound being hereinafter properly referred to as a “specific IR coloring material”), such an alkali-dissociating substituent is present on a counter anion, and the compound has an infrared absorbing ability, and a cation matrix having a structure as a dissolution inhibitor does not have a structure that lowers such a dissolution inhibiting ability. Accordingly, in image areas (unexposed areas), it is possible to keep high resistance to alkaline dissolution without substantially deteriorating the dissolution inhibiting ability derived from the structure of the IR pigment. This is because in the unexposed areas, the water-insoluble and alkali-soluble high-molecular compound (alkali-soluble resin) (A) forms a strong mutual action with the cation segment of the specific IR coloring material and surrounds the whole of the molecule of the specific IR coloring material so as to cover it.

On the other hand, in the exposed areas, it is thought that flexibility of the matrix increases due to strong heat generation, and at this moment, a degree of freedom of movement in a film enhances. In this specific IR coloring material, since the counter anion is not covalently fixed but only ionically bonded to the cation matrix, the degree of freedom of movement is high so that a large change of alignment is likely caused. For this reason, the alkali-dissociating substituent present in the counter anion functions effectively, whereby release of the alkali dissolution inhibiting ability is rapidly carried out. Moreover, in the specific IR coloring material according to the invention, the cation matrix site itself has a photothermal converting ability, and it is estimated that this change takes place in the surroundings of the molecule with extremely good efficiency. It is thought that high sensitivity and high discrimination are realized as a result thereof.

The exact mechanism resulting the effects of the second embodiment of the invention is not completely clear but is presumed to be as follows.

That is, in general, when a compound containing an alkali-dissociating substituent, such as a phenolic hydroxyl group, a carboxyl group, or a mercapto group, is added to a photosensitive layer (image forming layer), the compound works as a dissolution accelerator, whereby its dissolution inhibiting ability in unexposed areas is lowered. In the invention, in the onium salt represented by the above-described general formula (2), it is estimated that by including the alkali-dissociating substituent on the counter anion, it is possible to achieve only enhancement of solubility in the exposed areas without substantially deteriorating the dissolution inhibiting ability derived from the structure of the onium matrix.

Also, it is thought that in heat mode exposure systems, flexibility of the matrix increases due to strong heat generation during exposure, and at this moment, a degree of freedom of movement in a film enhances. In the general formula (2), since the counter anion is not covalently fixed to the cation matrix, the degree of freedom of movement during exposure is high so that a large change of alignment is likely caused. As a result, the caused change, i.e., release of the dissolution inhibiting ability in the exposed areas, is maintained even after exposure when an instantaneous heat due to the exposure is lost, and hence, it is estimated that the latent image stability enhances.

Incidentally, the term “heat mode type” as referred to in the invention means that recording by heat mode exposure can be carried out.

The definition of the heat mode exposure in the invention, will be described in detail. As described on page 209 of Hans-Joachim Timpe, IS&Ts NIP 15:1999, International Conference on Digital Printing Technologies, it is known that in photosensitive materials, when a light-absorbing substance (for example, a dye) is photo-excited to form an image via a chemical or physical change, there are roughly two modes in the process from photo-excitation of the light-absorbing substance to the chemical or physical change. One mode is a so-called photon mode in which the photo-excited light-absorbing substance is deactivated by some photochemical mutual action (for example, energy transfer or electron transfer) with other reactive substances in the photosensitive material, and as a result, the activated reactive substance causes a chemical or physical change necessary for the above-described image formation. The other mode is a so-called heat mode in which the photo-excited light-absorbing substance is deactivated by the generation of a heat, and the reactive substance causes a chemical or physical change necessary for the above-described image formation while utilizing the generated heat. In addition, there are also special modes such as ablation in which the substance explosively flies about due to locally concentrated light energy and multimolecular absorption in which one molecule absorbs a number of photons all at once, but such special modes are omitted herein.

The exposure processes utilizing each of the above-described modes are referred to as “photon mode exposure” and “heat mode exposure”, respectively. A technical difference between the photon mode exposure and the heat mode exposure resides in whether an energy amount of several photons to be exposed can be added to an energy amount of the desired reaction and used. For example, causing a certain reaction using n photons will be consider. In the photon mode exposure, since a photochemical mutual action is utilized, it is impossible, according to the demands of the laws of conservation of quantum energy and momentum, to add the energy of one photon and use it. Namely, in order to cause some reaction, a relation of “(energy amount of one photon)≧(energy amount of reaction)” is necessary. On the other hand, in the heat mode exposure, since heat is generated after photo-excitation, and light energy is converted to heat and utilized, it is possible to add an energy amount. For this reason, it is sufficient if a relation of “(energy amount of n photons)≧(energy amount of reaction)” is present. However, the addition of this energy amount is restricted by thermal diffusion. That is, if a next photo-excitation-to-deactivation step takes place to generate a heat by the time until heat escapes from an exposed portion (reaction point), which is the present point of concern, due to thermal diffusion, the heat is surely accumulated and added, leading to a temperature elevation in that portion. However, in the case where next heat generation is slow, the heat escapes and is not accumulated. Namely, in the heat mode exposure, even if the entire exposure energy amount is identical, the result is different between the case where light having a high energy amount is irradiated for a short period of time and the case where light having a low energy amount is irradiated for a long period of time, and the short-period irradiation is advantageous for heat accumulation.

As a matter of course, in the photon mode exposure, a similar phenomenon may occurs due to influences of diffusion of subsequent reaction seeds, but basically the above-described phenomenon does not take place.

Namely, when characteristics of photosensitive material are concerned, according to the photon mode, an inherent sensitivity (energy amount for reaction necessary for image formation) of the photosensitive material against an exposure power density (W/cm²) (=energy density per unit time) is constant, whereas according to the heat mode, the inherent sensitivity of the photosensitive material relative to the exposure power density increases. Accordingly, when the respective modes are compared while fixing an exposure time to an extent such that productivity necessary for actual image forming materials can be maintained from the standpoint of practical use, according to the photon mode exposure, a high sensitivity of about 0.1 mJ/cm² can be usually achieved, but since the reaction occurs even at a low exposure amount, a problem of low-exposure fogging in unexposed areas is liable to occur. On the other hand, according to the heat mode exposure, the reaction does not take place unless the exposure amount exceeds a certain amount. Further, an exposure amount of about 50 mJ/cm² is usually required due to the relationship with thermal stability of the photosensitive material, but the problem of low-exposure fogging is avoided.

Further, according to the heat mode exposure, an exposure power density of 5,000 W/cm² or more, and preferably 10,000 W/cm² or more is actually required on a printing plate surface of the photosensitive material. However, although the details have not been described herein, when a high-power density laser of 5.0×10⁵ W/cm² or more is utilized, ablation takes place to bring about problems such as staining of light sources, and hence, such is not preferred.

### DETAILED DESCRIPTION OF THE INVENTION

The image forming material of the present invention will be described in detail below.

A first embodiment of the image forming material of the invention is necessary to contain as components of an image forming layer (A) a water-insoluble and alkali-soluble high-molecular compound and (B) a compound having a structure represented by the following general formula (1) and having an absorption maximum at a wavelength in a range of 760 nm to 1,200 nm.

X⁻M⁺ General formula (1):

In the general formula (1), X⁻ represents an anion containing at least one substituent having an alkali-dissociating proton; and M⁺ represents a counter cation which is an atomic group having an absorption maximum at a wavelength in a range of 760 nm to 1,200 nm.

Further, a second embodiment of the image forming material of the invention is required to contain as components of an image forming layer (A) a water-insoluble and alkali-soluble high-molecular compound, (C) a Light-heat Converting agent, and (D) an onium salt represented by the following general formula (2).

X⁻M₁⁺ General formula (2):

In the general formula (2), X⁻ represents an anion containing at least one substituent having an alkali-dissociating proton; and M₁⁺ represents a counter cation selected from sulfonium, iodonium, ammonium, phosphonium, and oxonium.

Each of the components constituting the image forming layer in the image forming material of the invention will be hereunder described one by one. Incidentally, the component (B) as a characteristic component in the first embodiment of the invention and the component (D) as a characteristic component of the second embodiment of the invention will be first described below. Then, the respective components common to the both embodiments will be described.

[(B) Compound Having a Structure Represented by the General Formula (1) and Having an Absorption Maximum at a Wavelength in a Range of 760 nm to 1,200 nm]

The image forming layer according to the first embodiment of the invention contains a compound (specific IR absorbing material) having a structure represented by the following general formula (1) and having an absorption maximum at a wavelength in a range of 760 nm to 1,200 nm.

X⁻M⁺ General formula (1):

In the general formula (1), X⁻ represents an anion containing at least one substituent having an alkali-dissociating proton. Suitable examples of such substituents having an alkali-dissociating proton that can be used include a phenolic hydroxyl group (Ar—OH), a carboxyl group (—COOH), a mercapto group (—SH), a phosphonic acid group (—PO₃H₂), a phosphoric acid group (—OPO₃H₂), a sulfonamide group (—SO₂NH₂ and (—SO₂NHR), a substituted sulfonamide based group (hereinafter referred to as “active imide group”; —SO₂NHCOR, —SO₂NHSO₂R, and —CONHSO₂R), a sulfonic acid group (—SO₃H), a sulfinic acid group (—SO₂H), —C(CF₃)₂OH, and —COCH₂COCF₃. Here, Ar represents an optionally substituted aryl group, and R represents an optionally substituted hydrocarbon group. As systems having a good balance between the dissolution inhibiting ability and the sensitivity, can be enumerated a phenolic hydroxyl group, a carboxyl group, a mercapto group, a sulfonamide group, an active imide group, —C(CF₃)₂OH, and —COCH₂COCF₃, with a phenolic hydroxyl group and a carboxyl group being the most preferred.

X⁻ is preferably an anion corresponding to a conjugated base of a Bronsted acid, and more preferably an anion corresponding to a conjugated base of an organic acid. Though the organic acid can be selected from sulfonic acid, carboxylic acids, phosphonic acid, phenols, active imides, and sulfinic acid, acids of pKa<3 are preferable, acids of pKa<1 are more preferable, and sulfonic acid is particularly preferable.

In the general formula (1), M⁺ represents a counter cation which is an atomic group having an absorption maximum at a wavelength in a range of 760 nm to 1,200 nm. As the structure of M⁺, structures represented by the following general formulae (A), (C), (D), (F-1) and (F-2) are preferable because they are excellent in light-heat conversion efficiency. Especially, cation segments of cyanine dyes represented by the general formula (A) are the most preferable because they give a high mutual action with the alkali-soluble resin (A) described later and are excellent in stability and economy.

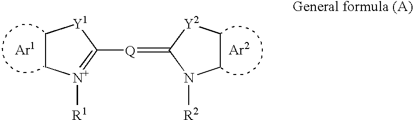

In the general formula (A), R¹ and R² each independently represents an alkyl group having from 1 to 12 carbon atoms, which may have a substituent selected from an alkoxy group, an aryl group, an amide group, an alkoxycarbonyl group, a hydroxyl group, a sulfo group, and a carboxyl group. Y¹ and y² each independently represents an oxygen atom, a sulfur atom, a selenium atom, a dialkylmethylene group, or —CH═CH—. Ar¹ and Ar² each independently represents an aromatic hydrocarbon group, which may have a substituent selected from an alkyl group, an alkoxy group, a halogen atom, and an alkoxycarbonyl group, and may fuse the aromatic ring together with Y¹ or Y² and two carbon atoms adjacent thereto.

In the general formula (A), Q represents an alkoxy group, an aryloxy group, an alkylthio group, an arylthio group, a dialkylamino group, a diarylamino group, a halogen atom, an alkyl group, an aralkyl group, a cycloalkyl group, an aryl group, an oxy group, or an iminium salt group. Suitable examples of substituents as Q include halogen atoms such as a chlorine atom, diarylamino groups such as a diphenylamino group, and arylthio groups such as a phenylthio group.

Among the cation segments of cyanine dyes represented by the general formula (A), in the case of exposure with an infrared ray having a wavelength from 800 to 840 nm, cation segments of heptamethinecyanine dyes represented by the following general formulae (A-1) to (A-3) can be preferably enumerated.

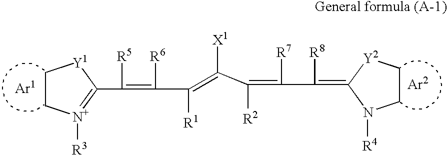

In the general formula (A-1), X¹ represents a hydrogen atom or a halogen atom. R¹ and R² each independently represents a hydrocarbon group having from 1 to 12 carbon atoms. R¹ and R² are preferably a hydrocarbon group having two or more carbon atoms from the standpoint of storage stability of coating solutions for image forming layer. Further, it is particularly preferred that R¹ and R² are taken together to form a 5-membered or 6-membered ring.

In the general formula (A-1), Ar¹ and Ar² may be the same or different and each represents an optionally substituted aromatic hydrocarbon group. Preferred examples of aromatic hydrocarbon groups include a benzene ring and a naphthalene ring. Preferred examples of substituents include hydrocarbon groups having not more than 12 carbon atoms, halogen atoms, and alkoxy groups having not more than 12 carbon atoms. Y¹ and Y² may be the same or different and each represent a sulfur atom or a dialkylmethylene group having not more than 12 carbon atoms. R³ and R⁴ may be the same or different and each represent an optionally substituted hydrocarbon group having not more than 20 carbon atoms. Preferred examples of substituents include alkoxy groups having not more than 12 carbon atoms, a carboxyl group, and a sulfo group. R⁵, R⁶, R⁷ and R⁸ may be the same or different and each represent a hydrogen atom or a hydrocarbon group having not more than 12 carbon atoms, with a hydrogen atom being preferred from the standpoint of easiness of availability of raw materials.

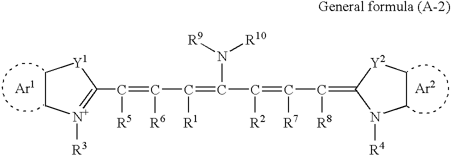

In the general formula (A-2), R¹ and R² each independently represents a hydrogen atom or a hydrocarbon group having from 1 to 12 carbon atoms, and R¹ and R² may bond with each other to form a ring structure. As the ring formed by R¹ and R², 5-membered or 6-membered rings are preferable, and 5-membered rings are particularly preferable. Ar¹ and Ar² may be the same or different and each represent an optionally substituted aromatic hydrocarbon group. Preferred examples of aromatic hydrocarbon groups include a benzene ring and a naphthalene ring. Preferred examples of substituents on the aromatic hydrocarbon group include hydrocarbon groups having not more than 12 carbon atoms, halogen atoms, and alkoxy groups, alkoxycarbonyl groups, alkylsulfonyl group and halogenated alkyl groups each having not more than 12 carbon atoms, with electron-withdrawing substituents being particularly preferred. Y¹ and Y² may be the same or different and each represent a sulfur atom or a dialkylmethylene group having not more than 12 carbon atoms. R³ and R⁴ may be the same or different and each represent an optionally substituted hydrocarbon group having not more than 20 carbon atoms. Preferred examples of substituents include alkoxy groups having not more than 12 carbon atoms, a carboxyl group, and a sulfo group. R⁵, R⁶, R⁷ and R⁸ may be the same or different and each represent a hydrogen atom or a hydrocarbon group having not more than 12 carbon atoms, with a hydrogen atom being preferred from the standpoint of easiness of availability of raw materials. R⁹ and R¹⁰ may be the same or different and each represent an optionally substituted aromatic hydrocarbon group having from 6 to 10 carbon atoms, an alkyl group having from 1 to 8 carbon atoms, or a hydrogen atom, or R⁹ and R¹⁰ may bond with each other to form a ring having any one of the following structures.

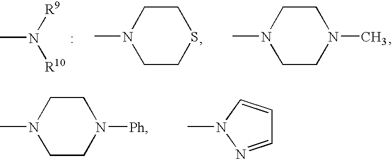

In the general formula (A-2), R⁹ and R¹⁰ are most preferably an aromatic hydrocarbon group such as a phenyl group.

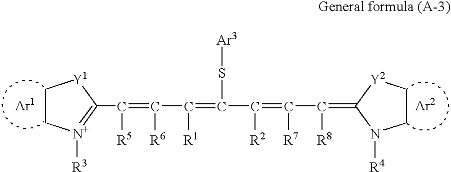

In the general formula (A-3), R¹ to R⁸, Ar¹, Ar², Y¹, and Y² are respectively synonymous with those in the foregoing general formula (A-2). Ar³ represents an aromatic hydrocarbon group such as a phenyl group and a naphthyl group, or a monocyclic or polycyclic heterocyclic group containing at least one of nitrogen, oxygen and sulfur atoms, and preferably a heterocyclic group selected from the group consisting of thiazole based, benzothiazole based, naphthothiazole based, thianaphtheno-7,6,4,5-thiazole based, oxazole based, benzoxazole based, naphthoxazole based, selenazole based, benzoselenazole based, naphthoselenazole based, thiazoline based, 2-quinoline based, 4-quinoline based, 1-isoquinoline based, 3-isoquinoline based, benzoimidazole based, 3,3-dialkylbenzoindolenine based, 2-pyridine based, 4-pyridine based, 3,3-dialkylbenzo[e]indole based, tetrazole based, triazole based, pyrimidine based, and thiadiazole based groups. As the heterocyclic group, the following structures are the most preferable.

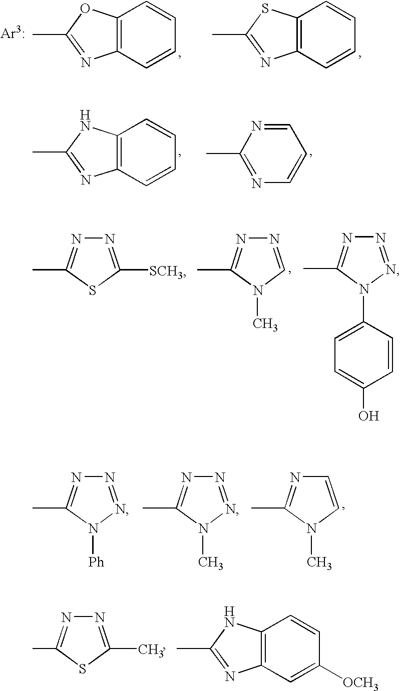

In the invention, specific examples of cation segments of the specific IR dye represented by the general formula (A) that can suitably be used include cation segments of dyes described in paragraphs [0017] to [0019] of JP-A No. 2001-133969, paragraphs [0012] to [0038] of JP-A No. 2002-40638, and paragraphs [0012] to [0023] of JP-A No. 2002-23360, in addition to those enumerated below.

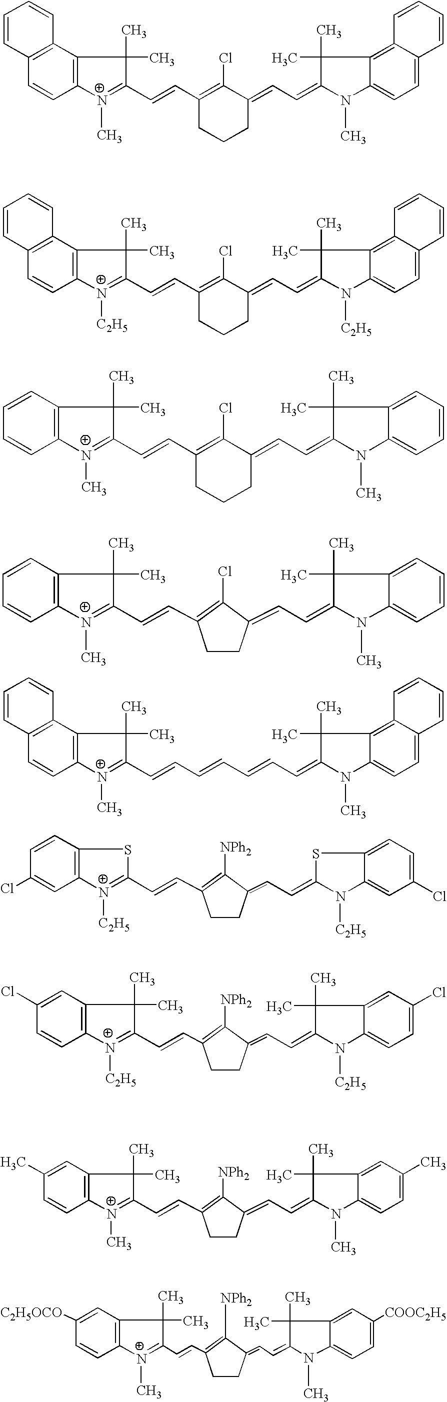

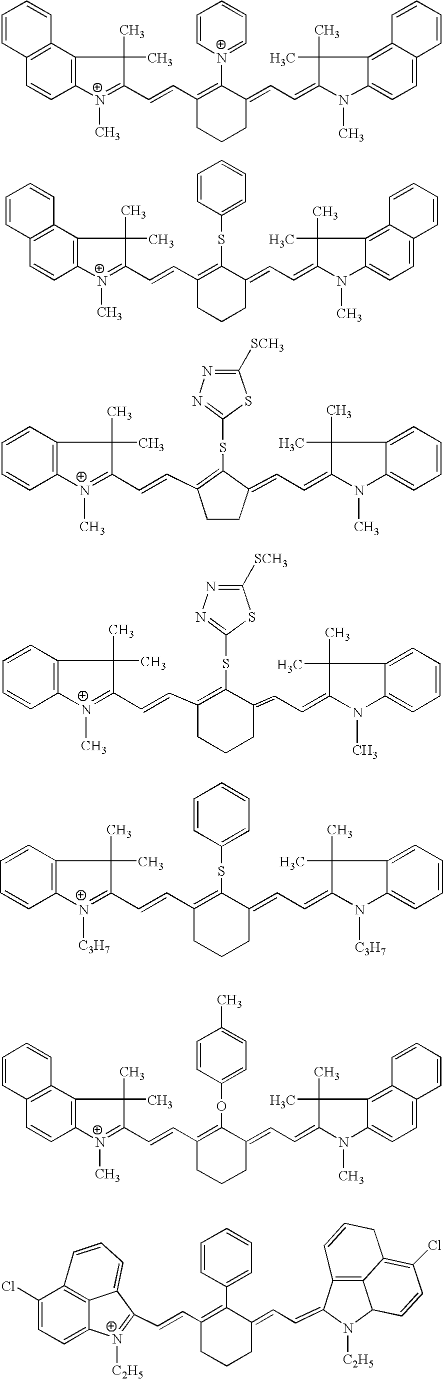

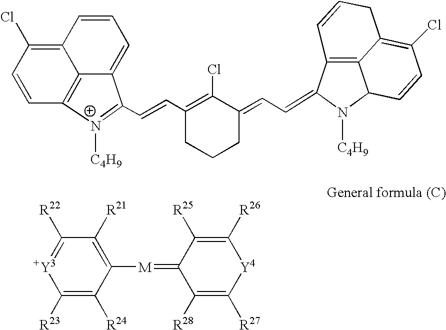

In the general formula (C), Y³ and Y⁴ each independently represents an oxygen atom, a sulfur atom, a selenium atom, or a tellurium atom. M represents a methine chain having at least five or more conjugated carbon atoms. R²¹ to R²⁴ and R²⁵ to R²⁸ each independently represents a hydrogen atom, a halogen atom, a cyano group, an alkyl group, an aryl group, an alkenyl group, an alkynyl group, a carbonyl group, a thio group, a sulfonyl group, a sulfinyl group, an oxy group, or an amino group.

In the invention, specific examples of cation segments of the specific IR dye represented by the general formula (C) that can suitably be used include those enumerated below.

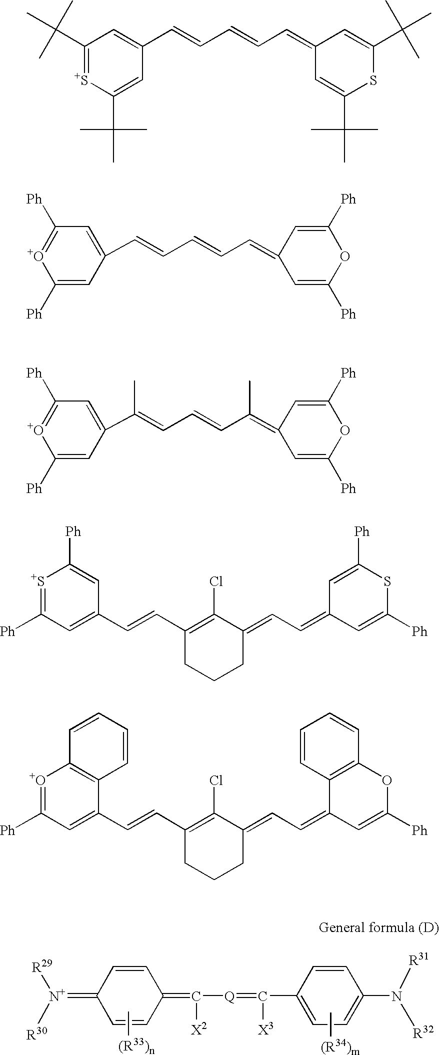

In the general formula (D), R²⁹ to R³² each independently represents a hydrogen atom, an alkyl group, or an aryl group. R³³ and R³⁴ each independently represents an alkyl group, a substituted oxy group, or a halogen atom. n and m each independently represents an integer from 0 to 4. R²⁹ and R³⁰, or R³¹ and R³² may bond with each other to form a ring, at least one of R²⁹ and R³⁰ may bond with R³³ to form a ring, and at least one of R³¹ and R³² may bond with R³⁴ to form a ring. Further, in the case when a plural number of R³³ or R³⁴ are present, the plurality of R³³ or the plurality of R³⁴ may bond with each other to form a ring. X² and X³ each independently represents a hydrogen atom, an alkyl group, or an aryl group. Q represents an optionally substituted trimethine group or pentamethine group and may form a ring structure together with a divalent organic group.

In the invention, specific examples of cation segments of the specific IR dye represented by the general formula (D) that can suitably be used include those enumerated below.

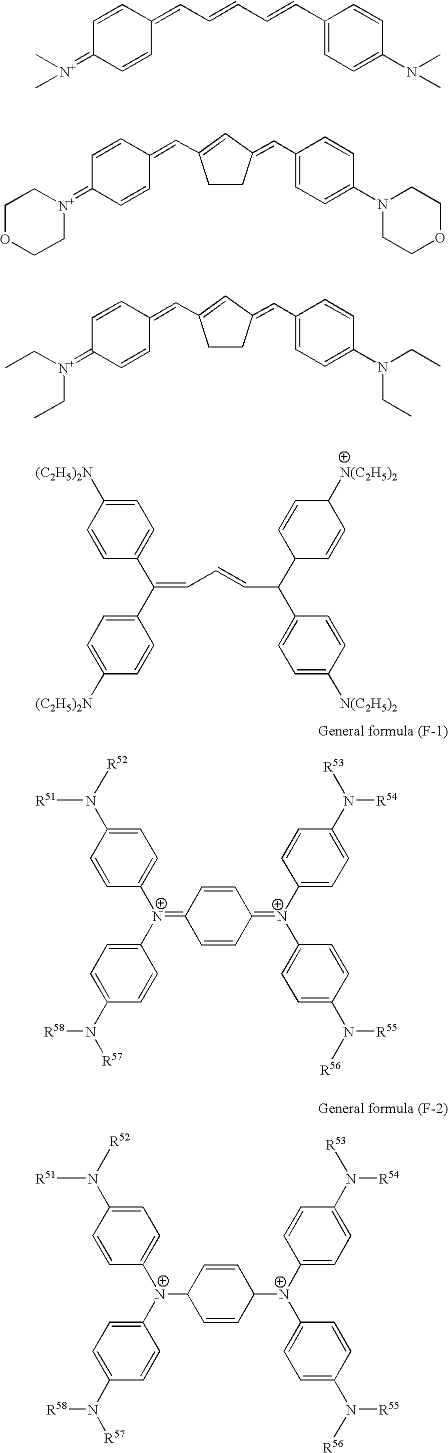

In the general formulae (F-1) and (F-2), R⁵¹ to R⁵⁸ each independently resents a hydrogen atom or an optionally substituted alkyl group or aryl group.

In the invention, specific examples of cation segments of the specific IR dye represented by the general formula (F-1) or (F-2) that can suitably be used include those enumerated below.

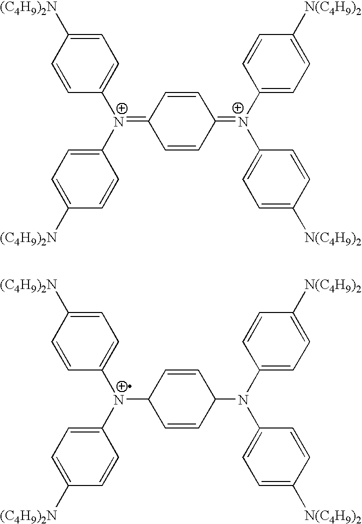

Of the specific IR absorbing materials represented by the general formula (1) according to the invention, onium salts represented by the following general formula (1-A), in which an anion segment thereof has a sulfonium structure, can be enumerated as a preferred embodiment.

R^{A}—SO₃⁻M⁺ General formula (1-A):

In the general formula (1-A), R^{A} represents a substituent containing at least one substituent having an alkali-dissociating proton. Here, the substituent having an alkali-dissociating proton is synonymous with the substituent having an alkali-dissociating proton described above for the general formula (1).

M⁺ is synonymous with M⁺ in the foregoing general formula (1).

In R^{A}, as the skeleton to which the substituent having an alkali-dissociating proton is bonded, optionally substituted hydrocarbon groups can be enumerated, and those containing an aromatic ring in the structure thereof are preferable though they are not specifically limited. Examples of such aromatic rings include aromatic hydrocarbon rings such as a benzene ring, a naphthalene ring, an anthracene ring, and a phenanthrene ring and aromatic heterocyclic rings such as a pyrrole group, a pyridine ring, a quinoline ring, an acridine ring, an imidazole ring, a furan ring, a thiophene group, and a thiazole ring. Of these, aromatic hydrocarbon rings are preferable, and a benzene ring is the most preferable.

Of the specific IR absorbing materials represented by the general formula (1), onium salts represented by the following general formula (1-B) can be enumerated as a more preferred embodiment.

Ar^{B}—SO₃⁻M⁺ General formula (1-B):

In the general formula (1-B), Ar^{B represents an aryl group containing at least one substituent having an alkali-dissociating proton. Here, the substituent having an alkali-dissociating proton is synonymous with the substituent having an alkali-dissociating proton described above for the general formula (}1).

M⁺ is synonymous with M⁺ in the foregoing general formula (1).

Specific examples of the specific IR absorbing materials that are suitably used in the invention will be given below. However, any of compounds represented by the general formula (1) can be arbitrarily selected within this range, and it should not be construed that the invention is limited to these illustrative compounds.

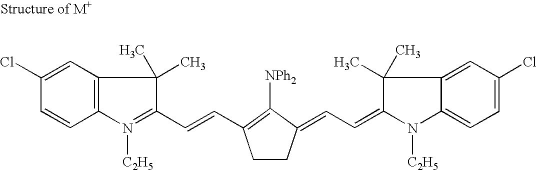

| Compound No. | Structure of X⁺ |
|---|---|
| CD-1 | 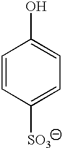 |
| CD-2 | 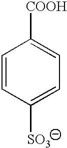 |
| CD-3 | 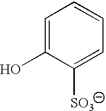 |
| CD-4 | 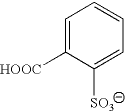 |
| CD-5 | 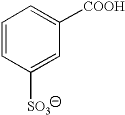 |
| CD-6 | 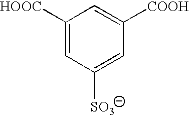 |
| CD-7 | 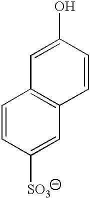 |
| CD-8 | 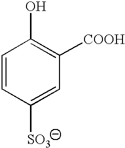 |
| CD-9 | 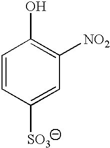 |
| CD-10 | 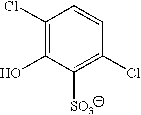 |
| CD-11 | 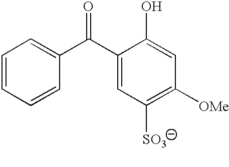 |
| CD-12 | 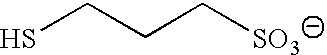 |
| CD-13 | 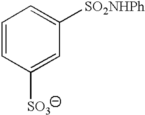 |
| CD-14 | 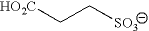 |
| CD-15 | 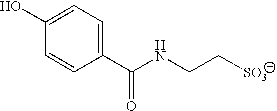 |
| CD-16 | 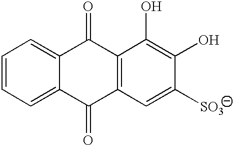 |

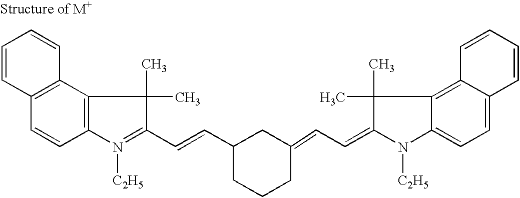

| Compound No. | Structure of X⁻ |
|---|---|
| CD-17 | 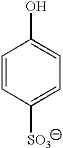 |
| CD-18 | 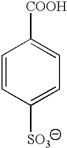 |
| CD-19 | 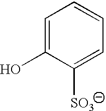 |
| CD-20 | 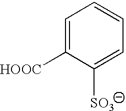 |
| CD-21 | 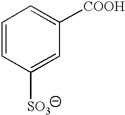 |
| CD-22 | 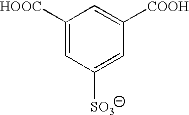 |
| CD-23 | 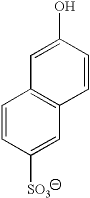 |
| CD-24 | 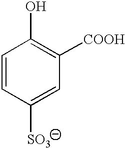 |

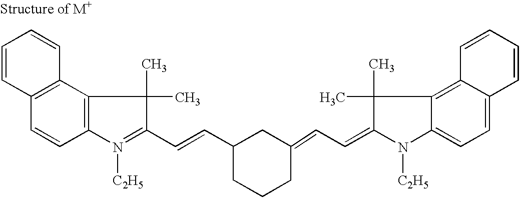

| Compound No. | Structure of X⁺ |
|---|---|
| CD-25 | 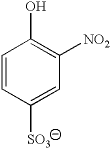 |
| CD-26 | 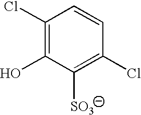 |
| CD-27 | 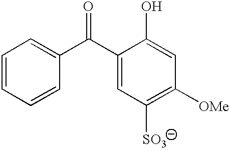 |
| CD-28 | 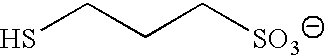 |
| CD-29 | 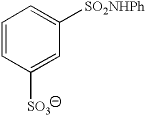 |
| CD-30 | 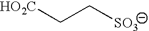 |
| CD-31 | 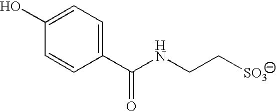 |
| CD-32 | 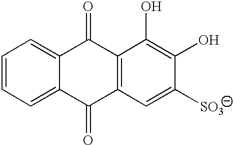 |

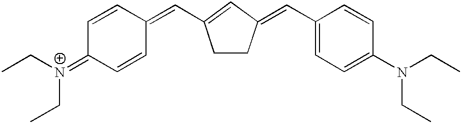

| Compound No. | Structure of X⁻ |
|---|---|
| CD-33 | 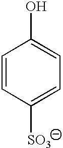 |
| CD-34 | 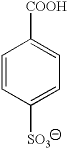 |
| CD-35 | 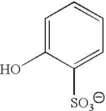 |
| CD-36 | 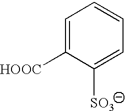 |
| CD-37 | 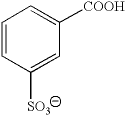 |
| CD-38 | 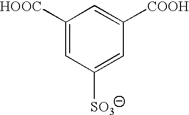 |
| CD-39 | 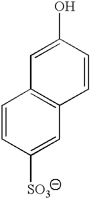 |
| CD-40 | 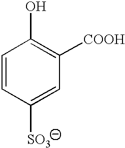 |
| CD-41 | 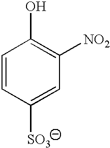 |
| CD-42 | 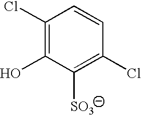 |
| CD-43 | 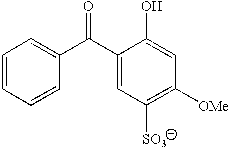 |
| CD-44 | 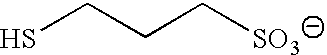 |
| CD-45 | 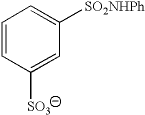 |
| CD-46 | 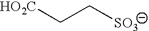 |
| CD-47 | 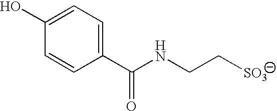 |
| CD-48 | 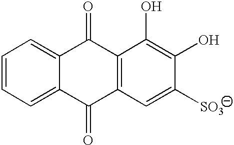 |

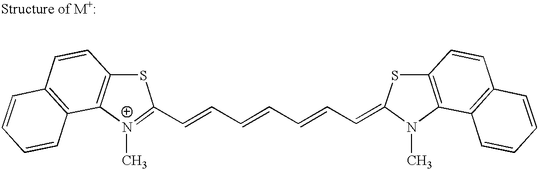

| Compound No. | Structure of X⁻ |
|---|---|
| CD-49 | 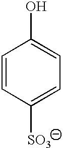 |
| CD-50 | 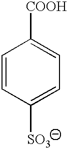 |
| CD-51 | 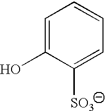 |
| CD-52 | 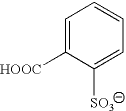 |
| CD-53 | 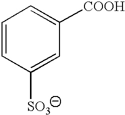 |
| CD-54 | 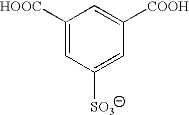 |
| CD-55 | 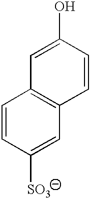 |
| CD-56 | 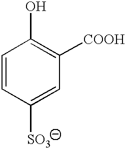 |
| CD-57 | 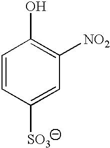 |
| CD-58 | 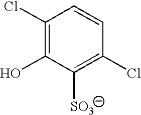 |
| CD-59 | 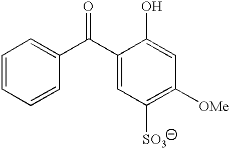 |
| CD-60 | 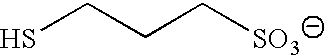 |
| CD-61 | 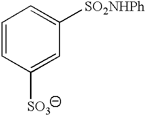 |
| CD-62 | 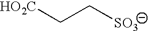 |
| CD-63 | 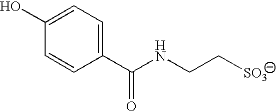 |
| CD-64 | 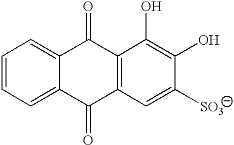 |

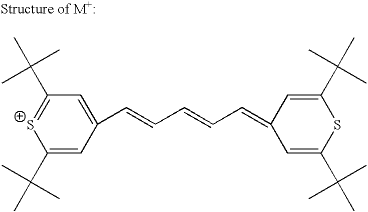

| Compound No. | Structure of X⁻ |
|---|---|
| PD-1 | 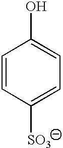 |
| PD-2 | 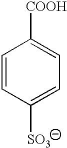 |
| PD-3 | 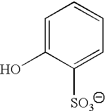 |
| PD-4 | 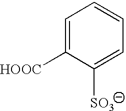 |
| PD-5 | 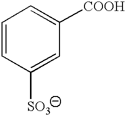 |
| PD-6 | 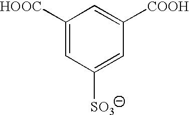 |
| PD-7 | 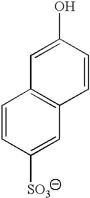 |
| PD-8 | 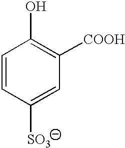 |
| PD-9 | 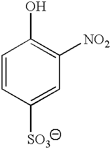 |
| PD-10 | 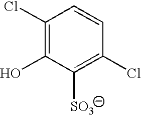 |
| PD-11 | 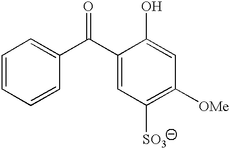 |
| PD-12 | 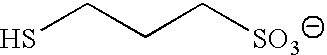 |
| PD-13 | 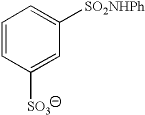 |
| PD-14 | 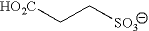 |
| PD-15 | 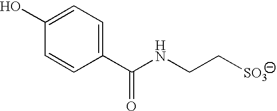 |
| PD-16 | 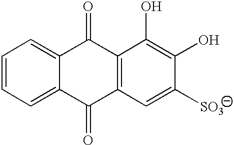 |

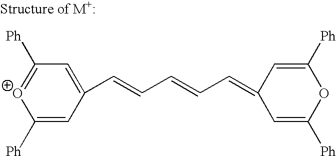

| Compound No. | Structure of X⁻ |
|---|---|
| PD-17 | 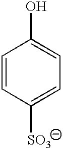 |
| PD-18 | 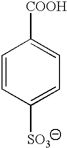 |
| PD-19 | 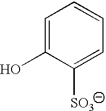 |
| PD-20 | 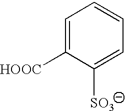 |
| PD-21 | 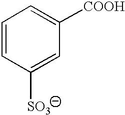 |
| PD-22 | 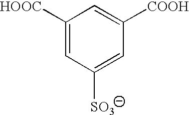 |
| PD-23 | 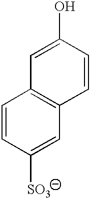 |
| PD-24 | 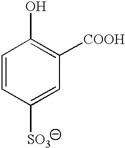 |
| PD-25 | 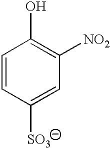 |
| PD-26 | 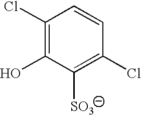 |
| PD-27 | 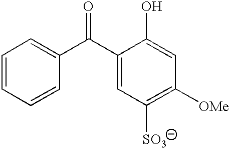 |
| PD-28 | 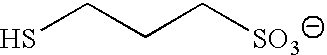 |
| PD-29 | 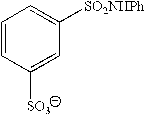 |
| PD-30 | 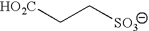 |
| PD-31 | 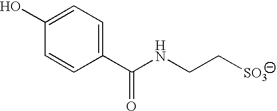 |
| PD-32 | 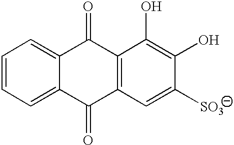 |

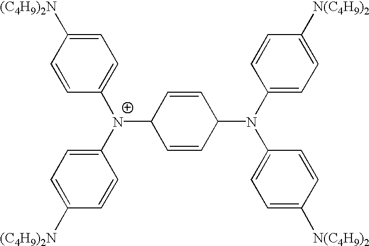

| Compound No. | Structure of X⁻ |
|---|---|
| AD-1 | 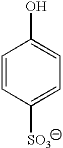 |
| AD-2 | 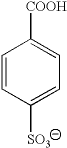 |
| AD-3 | 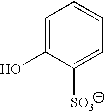 |
| AD-4 | 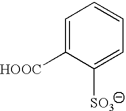 |
| AD-5 | 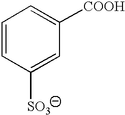 |
| AD-6 | 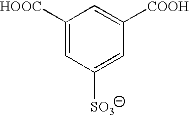 |
| AD-7 | 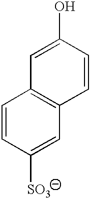 |
| AD-8 | 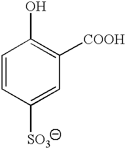 |
| AD-9 | 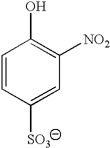 |
| AD-10 | 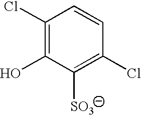 |
| AD-11 | 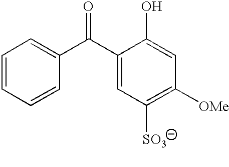 |
| AD-12 | 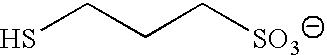 |
| AD-13 | 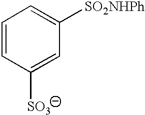 |
| AD-14 | 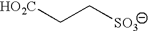 |
| AD-15 | 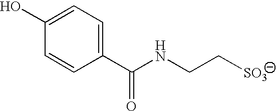 |
| AD-16 | 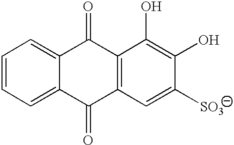 |

The specific IR absorbing material that is used in the image forming material of the first embodiment may be used singly or in admixture of two or more thereof. The content of the specific IR absorbing material is preferably not more than 50% of the mass of the whole of solid contents of the image forming layer from the viewpoint of film forming property; preferably in the range of 0.1% to 30% from the viewpoint that the image forming property is extremely good; and most preferably in the range of 0.5% to 15% from the viewpoint that the printing performance such as press life can consist with the image forming property at high levels.

[(D) Onium Salt Represented by the General Formula (2)]

The image forming layer according to the second embodiment of the image forming material of the invention is characterized by containing an onium salt represented by the following general formula (2).

X⁻M₁⁺ General formula (2):

In the general formula (2), X⁻ represents an anion containing at least one substituent having an alkali-dissociating proton; and M₁⁺ represents a counter cation selected from sulfonium, iodonium, ammonium, phosphonium, and oxonium.

The onium salt represented by the general formula (2) will be hereunder described in detail.

As the substituents having an alkali-dissociating proton in the anion represented by X⁻ are preferable a phenolic hydroxyl group (Ar—OH), a carboxyl group (—COOH), a mercapto group (—SH), a phosphonic acid group (—PO₃H₂), a phosphoric acid group (—OPO₃H₂), a sulfonamide group (—SO₂NH₂ and —SO₂NHR), a substituted sulfonamide based group (hereinafter referred to as “active imide group”; —SO₂NHCOR, —SO₂NHSO₂R, and —CONHSO₂R), a sulfonic acid group (—SO₃H), a sulfinic acid group (—SO₂H), —C(CF₃)₂OH, and —COCH₂COCF₃. Here, Ar represents an optionally substituted aryl group, and R represents an optionally substituted hydrocarbon group. As systems having a good balance between the dissolution inhibiting ability and the sensitivity, can be enumerated a phenolic hydroxyl group, a carboxyl group, a mercapto group, a sulfonamide group, an active imide group, —C(CF₃)₂OH, and —COCH₂COCF₃, with a phenolic hydroxyl group and a carboxyl group being the most preferred.

X⁻ is preferably an anion corresponding to a conjugated base of a Bronsted acid, and more preferably an anion corresponding to a conjugated base of an organic acid. Though the organic acid can be selected from sulfonic acid, carboxylic acids, phosphonic acid, phenols, active imides, and sulfinic acid, acids of pKa<3 are preferable, acids of pKa<1 are more preferable, and sulfonic acid is particularly preferable.

The counter cation represented by M₁⁺ is necessary to be selected from sulfonium, iodonium, ammonium, phosphonium, and oxonium. From the viewpoint of dissolution inhibiting ability, M₁⁺ preferably sulfonium, iodonium, or quaternary ammonium, and most preferably quaternary ammonium.

Structures presented by the following general formula (M) can be enumerated as a preferred embodiment of the quaternary ammonium.

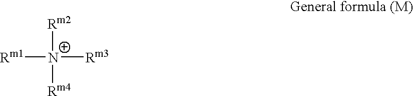

In the general formula (M), R^{m1} to R^{m4} each independently represents a substituent having one or more carbon atoms and may bond with each other to form a ring structure.

Examples of substituents having one or more carbon atoms represented by R^{m1} to R^{m4} include alkyl groups (preferably ones having from 1 to 20 carbon atoms, more preferably from 1 to 16 carbon atoms, and particularly preferably from 1 to 12, such as a methyl group, an ethyl group, an n-butyl group, an iso-propyl group, a tert-butyl group, an n-octyl group, an n-decyl group, an n-hexadecyl group, a cyclopropyl group, a cyclopentyl group, a cyclohexyl group, and a 2-cyclohexylethyl group); alkenyl groups (preferably ones having from 2 to 20 carbon atoms, more preferably from 2 to 12 carbon atoms, and particularly preferably from 2 to 8 carbon atoms, such as a vinyl group, an allyl group, a 2-butenyl group, a 3-pentenyl group, and a 2-cyclohexenylmethyl group); alkynyl groups (preferably ones having from 2 to 20 carbon atoms, more preferably from 2 to 12 carbon atoms, and particularly preferably from 2 to 8 carbon atoms, such as a propargyl group and a 3-pentynyl group); and aryl groups (preferably ones having from 6 to 30 carbon atoms, more preferably from 6 to 20 carbon atoms, and particularly preferably from 6 to 12 carbon atoms, such as a phenyl group, a p-methylphenyl group, and a naphthyl group).

These substituents may further be substituted. In the case where two or more substituents are present, the substituents may be the same or different. If possible, the substituents may be taken to form a ring.

As R^{m1} to R^{m4}, are preferable alkyl groups and aryl groups, or groups on which these groups are arbitrarily substituted. From the viewpoint of alkali resistance of image areas, the total number of carbon atoms of R^{m1} to R^{m4} is preferably from 8 to 80, more preferably from 10 to 64, and most preferably from 12 to 48. When the total number of carbon atoms is too small, hydrophilicity of the molecule is too high so that the water resistance is possibly deteriorated. On the other hand, when it is too large, the influence of the cation segment is reduced so that the dissolution inhibiting ability is possibility deteriorated.

Structures presented by the following general formula (M-1) can be enumerated as a preferred embodiment of the quaternary ammonium.

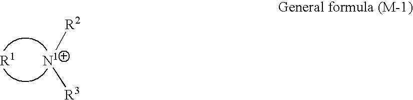

In the general formula (M-1), R¹ represents a residue forming a ring structure containing an N¹ atom. R² and R³ each independently represents an organic group and may bond with each other to form a ring structure. At least one of R² and R³ may be bonded to R¹ to from a ring structure.

As the residue represented by R¹, any divalent organic groups that form a ring structure containing an N¹ atom, including not only hydrocarbon based ring structures but also ring structures containing a plural number of nitrogen atoms or other hetero atoms such as an oxygen atom and a sulfur atom. Further, ones having a double bond within the ring structure or taking a polycyclic structure may also be employed.

As a preferred embodiment of the ring structure comprising R¹ and an N¹ atom, can be enumerated ones in which the ring structure to be formed is from 3-membered to 10-membered. From the viewpoint of more effective inhibition release property, the ring structure is preferably from 3-membered to 8-membered, and from the viewpoint of synthesis adaptability, the ring structure is preferably from 5-membered to 6-membered.

The ring structure comprising R¹ and an N¹ atom may further have a substituent. Examples of substituents that can be introduced include an alkyl group, an aryl group, and a halogen atom.

R² and R³ may be the same or different and can be arbitrarily selected from the whole of organic groups. From the viewpoint where the inhibition, i.e., a strong dissolution inhibiting action, reveals, R² and R³ are preferably an alkyl group, an aryl group, or a group represented by the following general formula (3), provided that the total number of carbon atoms of the both groups is 6 or more. Further, it is preferred that at least one of R² and R³ has a branched structure or a cyclic structure. Moreover, it is preferred from viewpoint of inhibition release property that at least one of R² and R³ contains an aromatic ring. More preferably, both R² and R³ contain an aromatic ring.

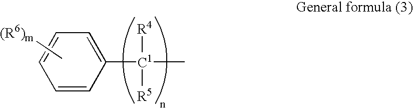

In the general formula (3), R⁴, R⁵ and R⁶ may be the same or different and each represent an arbitrary substituent that can be bonded. R⁴, R⁵ and R⁶ may bond with each other to form a ring structure and may each be bonded to a C¹ carbon atom by the same carbon atom to form a double bond. n represents an integer of 0 or 1. m represents an integer from 0 to 5, and in the case where a plural number of R⁶ are present, the plurality of R⁶ may be the same or different or may bond with each other to form a ring structure. In the case of n=1, from the viewpoint of synthesis adaptability, preferably at least one of R⁴ and R⁵ represents a hydrogen atom, and most preferably both R⁴ and R⁵ represent a hydrogen atom.

Examples of substituents represented by R² and R³ include alkyl groups (preferably ones having from 1 to 20 carbon atoms, more preferably from 1 to 16 carbon atoms, and particularly preferably from 1 to 12, such as a methyl group, an ethyl group, an n-butyl group, an isopropyl group, a tert-butyl group, an n-octyl group, an n-decyl group, an n-hexadecyl group, a cyclopropyl group, a cyclopentyl group, a cyclohexyl group, and a 2-cyclohexylethyl group); alkenyl groups (preferably ones having from 2 to 20 carbon atoms, more preferably from 2 to 12 carbon atoms, and particularly preferably from 2 to 8 carbon atoms, such as a vinyl group, an allyl group, a 2-butenyl group, a 3-pentenyl group, and a 2-cyclohexenylmethyl group); alkynyl groups (preferably ones having from 2 to 20 carbon atoms, more preferably from 2 to 12 carbon atoms, and particularly preferably from 2 to 8 carbon atoms, such as a propargyl group and a 3-pentynyl group); aryl groups (preferably ones having from 6 to 30 carbon atoms, more preferably from 6 to 20 carbon atoms, and particularly preferably from 6 to 12 carbon atoms, such as a phenyl group, a p-methylphenyl group, and a naphthyl group); amino group (preferably ones having from 0 to 20 carbon atoms, more preferably from 0 to 12 carbon atoms, and particularly preferably from 0 to 6 carbon atoms, such as an amino group, a methylamino group, a dimethylamino group, a diethylamino group, a diphenylamino group, and a dibenzylamino group); alkoxy groups (preferably ones having from 1 to 20 carbon atoms, more preferably from 1 to 12 carbon atoms, and particularly preferably from 1 to 8 carbon atoms, such as a methoxy group, an ethoxy group, and a butoxy group); aryloxy groups (preferably ones having from 6 to 20 carbon atoms, more preferably from 6 to 16 carbon atoms, and particularly preferably from 6 to 12 carbon atoms, such as a phenyloxy group and a 2-naphthyloxy group); acyl groups (preferably ones having from 1 to 20 carbon atoms, more preferably from 1 to 16 carbon atoms, and particularly preferably from 1 to 12 carbon atoms, such as an acetyl group, a benzoyl group, a formyl group, and a pivaroyl group); alkoxycarbonyl groups (preferably ones having from 2 to 20 carbon atoms, more preferably from 2 to 16 carbon atoms, and particularly preferably from 2 to 12 carbon atoms, such as a methoxycarbonyl group and an ethoxycarbonyl group); aryloxycarbonyl groups (preferably ones having from 7 to 20 carbon atoms, more preferably from 7 to 16 carbon atoms, and particularly preferably from 7 to 10 carbon atoms, such as a phenyloxycarbonyl group); acyloxy groups (preferably ones having from 2 to 20 carbon atoms, more preferably from 2 to 16 carbon atoms, and particularly preferably from 2 to 10 carbon atoms, such as an acetoxy group and a benzoyloxy group); acylamino groups (preferably ones having from 2 to 20 carbon atoms, more preferably from 2 to 16 carbon atoms, and particularly preferably from 2 to 10 carbon atoms, such as an acetylamino group and a benzoylamino group); alkoxycarbonylamino groups (preferably ones having from 2 to 20 carbon atoms, more preferably from 2 to 16 carbon atoms, and particularly preferably 2 to 12 carbon atoms, such as a methoxycarbonylamino group); aryloxycarbonylamino groups (preferably ones having from 7 to 20 carbon atoms, more preferably from 7 to 16 carbon atoms, and particularly preferably from 7 to 12 carbon atoms, such as a phenyloxycarbonylamino group); sulfonylamino groups (preferably ones having from 1 to 20 carbon atoms, more preferably from 1 to 16 carbon atoms, and particularly preferably from 1 to 12 carbon atoms, such as a methanesulfonylamino group and a benzenesulfonylamino group); sulfamoyl groups (preferably ones having from 0 to 20 carbon atoms, more preferably from 0 to 16 carbon atoms, and particularly preferably from 0 to 12 carbon atoms, such as a sulfamoyl group, a methylsulfamoyl group, a dimethylsulfamoyl group, and a phenylsulfamoyl group); carbamoyl groups (preferably ones having from 1 to 20 carbon atoms, more preferably from 1 to 16 carbon atoms, and particularly preferably from 1 to 12 carbon atoms, such as a carbamoyl group, a methylcarbamoyl group, a diethylcarbamoyl group, and a phenylcarbamoyl group); alkylthio groups (preferably ones having from 1 to 20 carbon atoms, more preferably from 1 to 16 carbon atoms, and particularly preferably from 1 to 12 carbon atoms, such as a methylthio group and an ethylthio group); arylthio groups (preferably ones having from 6 to 20 carbon atoms, more preferably from 6 to 16 carbon atoms, and particularly preferably from 6 to 12 carbon atoms, such as a phenylthio group); sulfonyl groups (preferably ones having from 1 to 20 carbon atoms, more preferably from 1 to 16 carbon atoms, and particularly preferably from 1 to 12 carbon atoms, such as a mesyl group and a tosyl group); sulfinyl groups (preferably ones having from 1 to 20 carbon atoms, more preferably from 1 to 16 carbon atoms, and particularly preferably from 1 to 12 carbon atoms, such as a methanesulfinyl group and a benzenesulfinyl group); ureido groups (preferably ones having from 1 to 20 carbon atoms, more preferably from 1 to 16 carbon atoms, and particularly preferably from 1 to 12 carbon atoms, such as a ureido group, a methylureido group, and a phenylureido group); phosphoric acid amide groups (preferably ones having from 1 to 20 carbon atoms, more preferably from 1 to 16 carbon atoms, and particularly preferably from 1 to 12 carbon atoms, such as a diethylphosphoric acid amide group and a phenylphosphoric acid amide group); a hydroxyl group; a mercapto group; halogen atoms (such as a fluorine atom, a chlorine atom, a bromine atom, and an iodine atom); a cyano group; a sulfo group; a carboxyl group; a nitro group; a hydroxamic acid group; a sulfino group; a hydrazino group; an imino group; heterocyclic groups (preferably ones having from 1 to 30 carbon atoms, more preferably from 1 to 12 carbon atoms; and examples of hetero atoms including a nitrogen atom, an oxygen atom, and a sulfur atom, such as an imidazolyl group, a pyridyl group, a quinolyl group, a furyl group, a thienyl group, a piperidyl group, a morpholino group, a benzoxazolyl group, a benzoimidazolyl group, a benzothiazolyl group, a carbazolyl group, an azepinyl group, and an oxilanyl group); and silyl groups (preferably ones having from 3 to 40 carbon atoms, more preferably from 3 to 30 carbon atoms, and particularly preferably from 3 to 24 carbon atoms, such as a trimethylsilyl group and a triphenylsilyl group).

These substituents may further be substituted. In the case where two or more substituents are present, the substituents may be the same or different. If possible, the substituents may bond with each other to form a ring.

As R² and R³, are preferable alkyl groups, aryl groups, alkenyl groups, alkynyl groups, or groups on which these groups are arbitrarily substituted. From the viewpoint of inhibition, the total number of carbon atoms of R² and R³ is preferably 6 or more, more preferably 8 or more, and most preferably 10 or more.

Structures presented by the following general formula (M-2) can be enumerated as a more preferred embodiment of the quaternary ammonium.

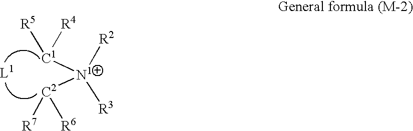

In the general formula (M-2), R² and R³ are synonymous with R² and R³ in the general formula (M-1), and their preferred ranges are also the same. In the general formula (M-2), as R² and R³, are preferable alkyl groups, aryl groups, alkenyl groups, alkynyl groups, or groups on which these groups are arbitrarily substituted. From the viewpoint of inhibition, the total number of carbon atoms of R² and R³ is preferably 6 or more, more preferably 8 or more, and most preferably 10 or more.

In the general formula (M-2), R⁴ to R⁷ each represent a hydrogen atom or a substituent. As the substituent, the substituents enumerated as examples of R² and R³ in the general formula (M-1) can be enumerated. These substituents may be the same or different and may bond with each other to form a ring. Further, R⁴ to R⁷ may each be bonded to L¹, R² or R³ to form a ring structure. Moreover, in the case where a C¹ carbon atom and a C² carbon atom form a double bond or a triple bond together with L¹, R⁴ to R⁷ may be absent corresponding thereto.

In the general formula (M-2), L¹ represents a divalent connecting group to form a ring structure containing —C¹—N¹—C²— or a single bond. In the case where L¹ represents a divalent connecting group, it may further have a substituent. As a preferred embodiment of the ring structure containing L¹, can be enumerated from 3-membered to 10-membered ring structures to be formed. From the viewpoint of inhibition release property, from 3-membered to 8-membered ring structures are preferable, and in view of synthesis adaptability, 5-membered and 6-membered ring structures are preferable.

In R⁴ to R⁷ in the general formula (M-2), in the case where two substituents are bonded to the same atom, the two substituents may represent the same atom or substituent to form a double bond together. (As an example of R⁴═R⁵═O, a carbonyl group (—CO—) may be formed.)

Of the foregoing quaternary ammoniums, structures represented by the following general formula (M-3) can be enumerated as a further preferred embodiment.

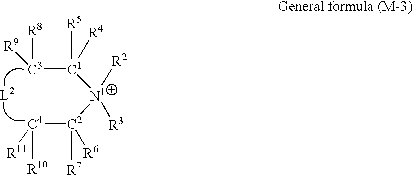

In the general formula (M-3), R², R³ and X⁻ are respectively synonymous with R², R³ and X⁻ in the general formula (M-1), and their preferred ranges are also the same.

In the general formula (M-3), R⁴ to R¹¹ each represent a hydrogen atom or a substituent. As the substituent, the substituents enumerated as examples of R² and R³ in the general formula (M-1) can be enumerated. These substituents may be the same or different and may bond with each other to form a ring. Further, R⁴ to R¹¹ may each be bonded to L², R² or R³ to form a ring structure. Moreover, in the case where a C³ carbon atom and a C⁴ carbon atom form a double bond or a triple bond together with a C³ carbon atom and a C² carbon atom, respectively, in the case where the C³ carbon atom and the C⁴ carbon atom form a double bond or a triple bond together with L², or in the case where L² represents a double bond to connect the C³ carbon atom to the C⁴ carbon atom, R⁴ to R¹¹ may be absent corresponding thereto.

In the general formula (M-3), L² represents a divalent connecting group to form a ring structure containing —C³—C¹—N¹—C²—C⁴—, or a single bond or a double bond to connect C³ to C⁴. In the case where L² is a divalent connecting group, L² may further have a substituent. As a preferred embodiment of the ring structure containing L², can be enumerated from 5-membered to 10-membered ring structures to be formed. From the viewpoint of inhibition release property, from 5-membered to 8-membered ring structures are preferable, and in view of synthesis adaptability, 5-membered and 6-membered ring structures are preferable.

In R⁴ to R¹¹ in the general formula (M-3), in the case where two substituents are bonded to the same atom, the two substituents may represent the same atom or substituent to form a double bond together. (As an example of R⁴═R¹═O, a carbonyl group (—CO—) may be formed.)

In R⁴ to R¹¹ in the general formula (M-3), in the case where two substituents are bonded to two adjacent atoms, the two substituents may represent the same atom or substituent to form a 3-membered ring together. (As an example of R⁴═R⁸=oxygen atom, an epoxy group may be formed.) Of the foregoing quaternary ammoniums, structures represented by the following general formula (M-4) can be enumerated as a further preferred embodiment.

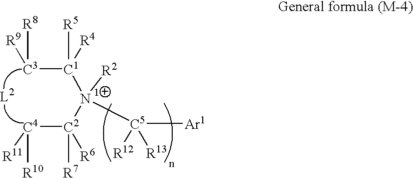

In the general formula (M-4), R² is synonymous with R² in the general formula (M-1), and its preferred range is also the same. As R² in the general formula (M-4), are more preferable alkyl groups, aryl groups, alkenyl groups, alkynyl groups, or groups on which these groups are arbitrarily substituted. From the viewpoint of inhibition, the number of carbon atoms of R² is preferably 2 or more, more preferably 3 or more, and particularly preferably 4 or more.

In the general formula (M-4), R⁴ to R¹³ each represent a hydrogen atom or a substituent. As the substituent, the substituents enumerated as examples of R² and R³ in the general formula (M-1) can be enumerated. These substituents may be the same or different and may bond with each other to form a ring. Further, R⁴ to R¹³ may each be bonded to L² or R² to form a ring structure. Moreover, in the case where a C³ carbon atom and a C⁴ carbon atom form a double bond or a triple bond together with a C¹ carbon atom and a C² carbon atom, respectively, in the case where the C³ carbon atom and the C⁴ carbon atom form a double bond or a triple bond together with L², or in the case where L² represents a double bond to connect the C³ carbon atom to the C⁴ carbon atom, R⁴ to R¹¹ may be absent corresponding thereto.

In the general formula (M-4), Ar¹ represents an aromatic ring group. Suitable examples of aromatic ring groups include substituted or unsubstituted phenyl group, naphthyl group, anthranyl group, phenanthrenyl group, pyridyl group, pyrazyl group, imidazolyl group, quinolinyl group, indolyl group, isoquinolinyl group, pyrrolyl group, furanyl group, pyrazolyl group, triazolyl group, tetrazolyl group, oxazolyl group, oxadiazolyl group, thiazolyl group, and pyrimidinyl group. Ar¹ may be bonded to any one of L², R², and R⁴ to R¹³ to form a ring structure.

In the general formula (M-4), n represents 0 or a positive integer, preferably 0, 1, 2 or 3, more preferably 0, 1 or 2, and particularly preferably 0 or 1. In the case where n is 2 or more, R¹²s and R¹³s to be present in a plural number may be the same of different and may bond with each other to form a ring structure.

In the general formula (M-4), L² represents a divalent connecting group to form a ring structure containing —C³—C¹—N¹—C²—C⁴—, or a single bond or a double bond to connect C³ to C⁴. In the case where L² is a divalent connecting group, L² may further have a substituent. As a preferred embodiment of the ring structure containing L², can be enumerated from 5-membered to 10-membered ring structures to be formed. From the viewpoint of inhibition release property, from 5-membered to 8-membered ring structures are preferable, and in view of synthesis adaptability, 5-membered and 6-membered ring structures are preferable.

In R⁴ to R¹³ in the general formula (M-4), in the case where two substituents are bonded to the same atom, the two substituents may represent the same atom or substituent to form a double bond together. (As an example of R¹═R⁵═O, a carbonyl group (—CO—) may be formed.)

In R⁴ to R¹³ in the general formula (M-4), in the case where two substituents are bonded to two adjacent atoms, the two substituents may represent the same atom or substituent to form a 3-membered ring together. (As an example of R⁴═R⁸═O, an epoxy group may be formed.)

Of the foregoing quaternary ammoniums, structures represented by the following general formula (M-5) can be enumerated as a further preferred embodiment.

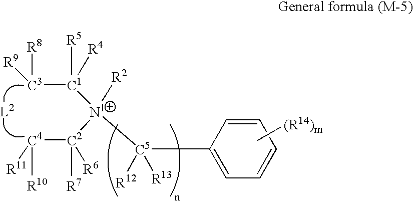

In the general formula (M-5), R² is synonymous with R² in the general formula (M-1), and its preferred range is also the same. As R² in the general formula (M-5), are more preferable alkyl groups, aryl groups, alkenyl groups, alkynyl groups, or groups on which these groups are arbitrarily substituted. From the viewpoint of inhibition, the number of carbon atoms of R² is preferably 2 or more, more preferably 3 or more, and particularly preferably 4 or more.

In the general formula (M-5), R⁴ to R¹⁴ each represent a hydrogen atom or a substituent. As the substituent, the substituents enumerated as examples of R² and R³ in the general formula (M-1) can be enumerated. These substituents may be the same or different and may bond with each other to form a ring. Further, R⁴ to R¹⁴ may each be bonded to L² or R² to form a ring structure. Moreover, in the case where a C³ carbon atom and a C⁴ carbon atom form a double bond or a triple bond together with a C¹ carbon atom and a C² carbon atom, respectively, in the case where the C³ carbon atom and the C⁴ carbon atom form a double bond or a triple bond together with L², or in the case where L² represents a double bond to connect the C³ carbon atom to the C⁴ carbon atom, R⁴ to R¹¹ may be absent corresponding thereto.

In the general formula (M-5), m represents an integer from 0 to 5. In the case where m is 2 or more, R¹⁴s to be present in a plural number may be the same or different and may bond with each other to form a ring structure.

In the general formula (M-5), n represents 0 or a positive integer, preferably 0, 1, 2 or 3, more preferably 0, 1 or 2, and particularly preferably 0 or 1. In the case where n is 2 or more, R¹²s and R¹³s to be present in a plural number may be the same of different and may bond with each other to form a ring structure.

In the general formula (M-5), L² represents a divalent connecting group to form a ring structure containing —C³—C¹—N¹—C²—C⁴—, or a single bond or a double bond to connect C³ to C⁴. In the case where L² is a divalent connecting group, L² may further have a substituent. As a preferred embodiment of the ring structure containing L², can be enumerated from 5-membered to 10-membered ring structures to be formed. From the viewpoint of inhibition release property, from 5-membered to 8-membered ring structures are preferable, and in view of synthesis adaptability, 5-membered and 6-membered ring structures are preferable.

In R⁴ to R¹⁴ in the general formula (M-5), in the case where two substituents are bonded to the same atom, the two substituents may represent the same atom or substituent to form a double bond together. (As an example of R⁴═R⁵═O, a carbonyl group (—CO—) may be formed.)

In R⁴ to R¹⁴ in the general formula (M-5), in the case where two substituents are bonded to two adjacent atoms, the two substituents may represent the same atom or substituent to form a 3-membered ring together. (As an example of R⁴═R⁸═O, an epoxy group may be formed.)

Of the foregoing quaternary ammoniums, structures represented by the following general formula (M-6) can be enumerated as a further preferred embodiment.

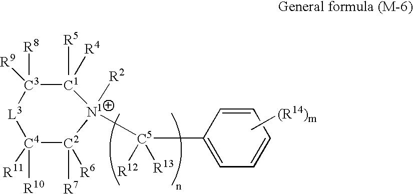

In the general formula (M-6), R² is synonymous with R² in the general formula (M-1), and its preferred range is also the same. As R² are more preferable alkyl groups, aryl groups, alkenyl groups, alkynyl groups, or groups on which these groups are arbitrarily substituted. From the viewpoint of inhibition, the number of carbon atoms of R² is preferably 2 or more, more preferably 3 or more, and particularly preferably 4 or more.

In the general formula (M-6), R⁴ to R¹⁴ each represent a hydrogen atom or a substituent. As the substituent, the substituents enumerated as examples of R² and R³ in the general formula (M-1) can be enumerated. These substituents may be the same or different and may bond with each other to form a ring. Further, R⁴ to R¹⁴ may each be bonded to L³ or R² to form a ring structure. Moreover, in the case where a C³ carbon atom and a C⁴ carbon atom form a double bond or a triple bond together with a C¹ carbon atom and a C² carbon atom, respectively, in the case where the C³ carbon atom and the C⁴ carbon atom form a double bond or a triple bond together with L³, or in the case where L³ represents a double bond to connect the C³ carbon atom to the C⁴ carbon atom, R⁴ to R¹¹ may be absent corresponding thereto.

In the general formula (M-6), m represents an integer from 0 to 5. In the case where m is 2 or more, R¹⁴s to be present in a plural number may be the same or different and may bond with each other to form a ring structure.

In the general formula (M-6), n represents 0 or a positive integer, preferably 0, 1, 2 or 3, more preferably 0, 1 or 2, and particularly preferably 0 or 1. In the case where n is 2 or more, R¹²s and R¹³s to be present in a plural number may be the same of different and may bond with each other to form a ring structure.

In the general formula (M-6), L³ represents a single bond or a double bond to connect C³ to C⁴, or a divalent connecting group to form a ring structure containing —C³—C¹—N¹—C²—C⁴—. Suitable examples of connecting groups include —O—, —S—, —N(R^{L1})—, and —C(R^{L2})(R^{L3})—. Here, as R^{L1} to R^{L3}, can be enumerated a hydrogen atom and the substituents enumerated as examples of R² and R³ in the general formula (M-1), and R^{L1} to R^{L3} may be each bonded to any one of R² and R⁴ to R¹⁴ to form a ring structure. In the case where C³ and C⁴ form a double bond together with L³, R^{L1} to R^{L3} may be absent.

In R⁴ to R¹⁴ and R^{L1} to R^{L3} in the general formula (M-6), in the case where two substituents are bonded to the same atom, the two substituents may represent the same atom or substituent to form a double bond together. (As an example of R⁴═R⁵═O, a carbonyl group (—CO—) may be formed.)

In R⁴ to R¹⁴ and R^{L1} to R^{L3} in the general formula (M-6), in the case where two substituents are bonded to two adjacent atoms, the two substituents may represent the same atom or substituent to form a 3-membered ring together. (As an example of R⁴═R⁸═O, an epoxy group may be formed.)

Of the foregoing quaternary ammoniums, structures represented by the following general formula (M-7) can be enumerated as a further preferred embodiment.

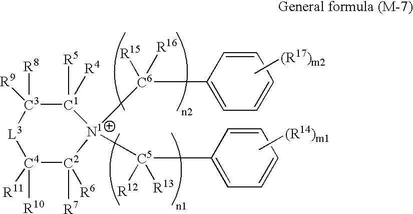

In the general formula (M-7), R⁴ to R¹⁷ each represent a hydrogen atom or a substituent. As the substituent, the substituents enumerated as examples of R² and R³ in the general formula (M-1) can be enumerated. These substituents may be the same or different and may bond with each other to form a ring. Further, R⁴ to R¹⁷ may each be bonded to L³ to form a ring structure. Moreover, in the case where a C³ carbon atom and a C⁴ carbon atom form a double bond or a triple bond together with a C¹ carbon atom and a C² carbon atom, respectively, in the case where the C³ carbon atom and the C⁴ carbon atom form a double bond or a triple bond together with L³, or in the case where L³ represents a double bond to connect the C³ carbon atom to the C⁴ carbon atom, R⁴ to R¹¹ may be absent corresponding thereto.

In the general formula (M-7), m1 and m2 each represent an integer from 0 to 5. In the case where m1 and m2 are each 2 or more, R¹⁴s and R¹⁷s to be present in a plural number may be the same or different and may bond with each other to form a ring structure.

In the general formula (M-7), n1 and n2 each represent 0 or a positive integer, preferably 0, 1, 2 or 3, more preferably 0, 1 or 2, and particularly preferably 0 or 1. In the case where n1 and n2 are each 2 or more, R¹²s and R¹³s and R¹⁵s and R¹⁶s to be present in a plural number may be the same of different and may bond with each other to form a ring structure.

In the general formula (M-7), L³ represents a single bond or a double bond to connect C³ to C⁴, or a divalent connecting group to form a ring structure containing —C³—C¹—N¹—C²—C⁴—. Suitable examples of connecting groups include —O—, —S—, —N(R^{L1})—, and —C(R^{L2})(R^{L3})—. Here, as R^{L1} to R^{L3}, can be enumerated a hydrogen atom and the substituents enumerated as examples of R² and R³ in the general formula (M-1), and R^{L1} to R^{L3} may be each bonded to any one of R² and R⁴ to R¹⁴ to form a ring structure. In the case where C³ and C⁴ form a double bond together with L³, R^{L1} to R^{L3} may be absent.

In R⁴ to R¹⁷ and R^{L1} to R^{L3} in the general formula (M-7), in the case where two substituents are bonded to the same atom, the two substituents may represent the same atom or substituent to form a double bond together. (As an example of R⁴═R⁵═O, a carbonyl group (—CO—) may be formed.)

In R⁴ to R¹⁷ and R^{L1} to R^{L3} in the general formula (M-7), in the case where two substituents are bonded to two adjacent atoms, the two substituents may represent the same atom or substituent to form a 3-membered ring together. (As an example of R⁴═R⁸═O, an epoxy group may be formed.)

Of the onium salts represented by the general formula (2), onium salts represented by the following general formula (2-A) can be enumerated as a preferred embodiment.

R^{A}—SO₃⁻M₁⁺ General formula (2-A):

In the general formula (2-A), R^{A} represents a substituent containing at least one substituent having an alkali-dissociating proton, which is synonymous with the substituent having an alkali-dissociating proton in the foregoing general formula (2). M₁⁺ is synonymous with M₁⁺ in the foregoing general formula (2), and its preferred range is also the same.

In R^{A}, as the skeleton to which the substituent having an alkali-dissociating proton is bonded, optionally substituted hydrocarbon groups can be enumerated, and those containing an aromatic ring in the structure thereof are preferable though they are not specifically limited. Examples of such aromatic rings include aromatic hydrocarbon rings such as a benzene ring, a naphthalene ring, an anthracene ring, and a phenanthrene ring and aromatic heterocyclic rings such as a pyrrole group, a pyridine ring, a quinoline ring, an acridine ring, an imidazole ring, a furan ring, a thiophene group, and a thiazole ring. Of these, aromatic hydrocarbon rings are preferable, and a benzene ring is the most preferable.

In the general formula (2-A), M₁⁺ is preferably sulfonium, iodonium, or quaternary ammonium, and most preferably quaternary ammonium from the viewpoint of dissolution inhibiting ability. Preferred embodiments of the quaternary ammonium are the same as in those in the general formula (2).

Of the onium salts represented by the general formula (2), onium salts represented by the following general formula (2-B) can be enumerated as a preferred embodiment.

Ar^{B}—SO₃⁻M₁⁺ General formula (2-B):

In the general formula (2-B), Ar^{B} represents an aryl group containing at least one substituent having an alkali-dissociating proton. The substituent having an alkali-dissociating proton is synonymous with the substituent having an alkali-dissociating proton in the foregoing general formula (2). M₁⁺ is synonymous with M₁⁺ in the foregoing general formula (2), and its preferred range is also the same.

In the general formula (2-B), M₁⁺ is preferably sulfonium, iodonium, or quaternary ammonium, and most preferably quaternary ammonium from the viewpoint of dissolution inhibiting ability. Preferred embodiments of the quaternary ammonium are the same as in those in the general formula (2).

In the invention, preferably, the onium salt represented by the general formula (2) does not substantially have absorption between 500 nm and 600 nm, and more preferably, it does not substantially have absorption in visible light regions.

The onium salt represented by the general formula (2) that is used in the second embodiment of the invention may be used singly or in admixture of two or more thereof. The content of the onium salt represented by the general formula (2) is preferably not more than 50% of the mass of the whole of solid contents of the image forming layer from the viewpoint of film forming property; preferably in the range of 0.1% to 30% from the viewpoint that the image forming property is extremely good; and most preferably in the range of 0.5% to 15% from the viewpoint that the printing performance such as press life can consist with the image forming property at high levels.

Specific examples of the onium salt represented by the general formula (2) that are suitably used in the second embodiment of the invention will be given below (Illustrative Compounds C-1 to C-30). Any of onium salts represented by the general formula (2) can be arbitrarily selected within this range, and it should not be construed that the invention is limited to these illustrative compounds.

| Compound No. | Anion segment | Cation segment |
|---|---|---|
| C-1 | 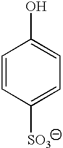 | 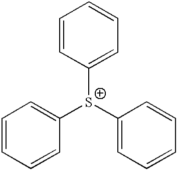 |
| C-2 | 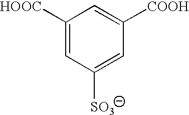 | 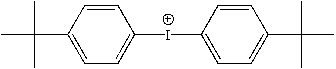 |
| C-3 | 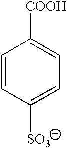 | 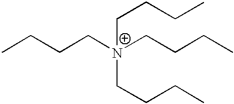 |
| C-4 | 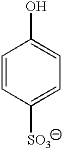 | 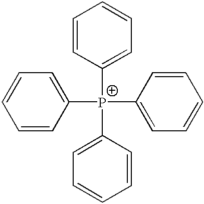 |
| C-5 | 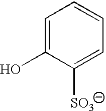 | 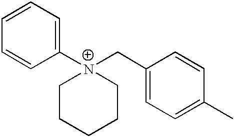 |
| C-6 | 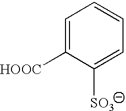 | 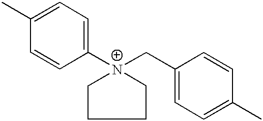 |
| C-7 | 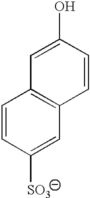 | 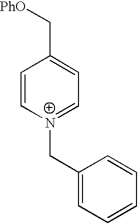 |
| C-8 | 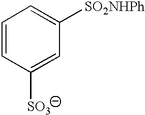 | 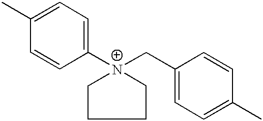 |
| C-9 | 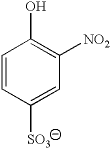 | 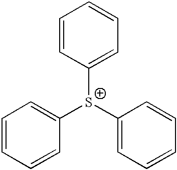 |
| C-10 | 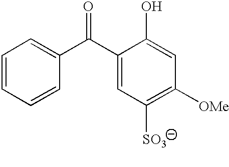 | 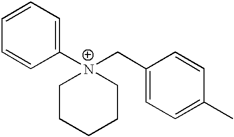 |
| C-11 | 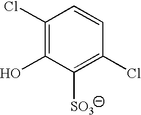 | 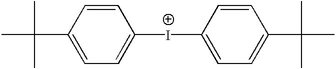 |
| C-12 | 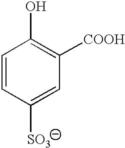 | 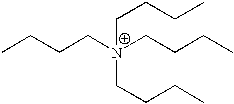 |
| C-13 | 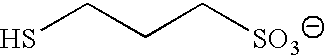 | 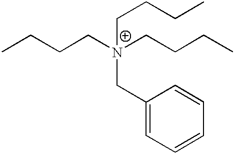 |
| C-14 | 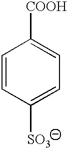 | 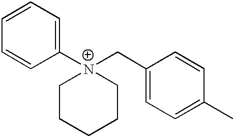 |
| C-15 | 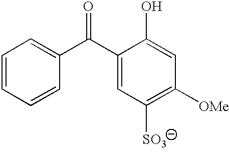 | 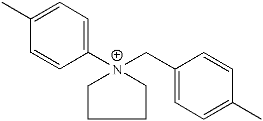 |
| C-16 | 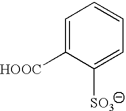 | 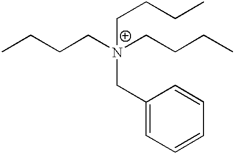 |
| C-17 | 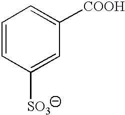 | 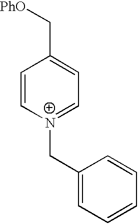 |
| C-18 | 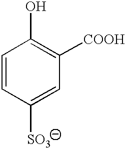 | 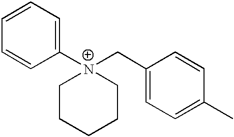 |
| C-19 | 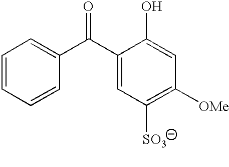 | 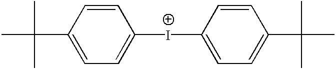 |
| C-20 | 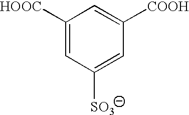 | 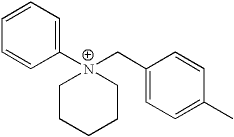 |
| C-21 | 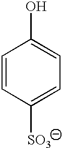 | 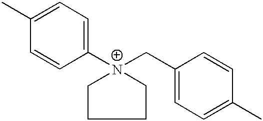 |
| C-22 | 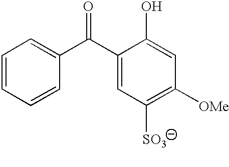 | 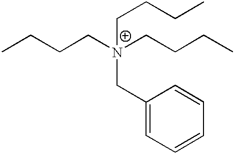 |
| C-23 | 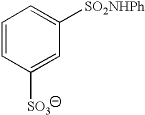 | 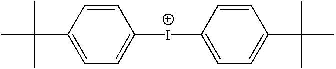 |
| C-24 | 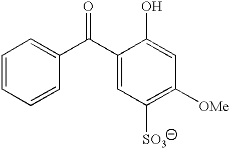 | 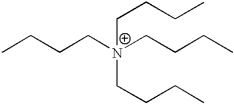 |
| C-25 | 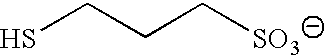 | 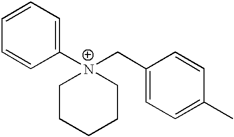 |
| C-26 | 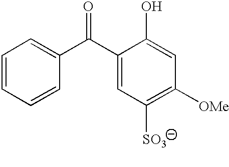 | 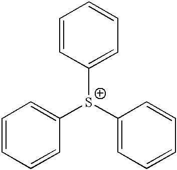 |
| C-27 | 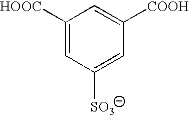 | 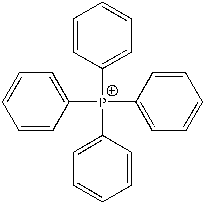 |
| C-28 | 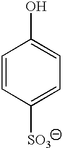 | 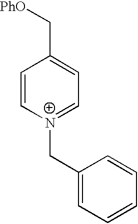 |
| C-29 | 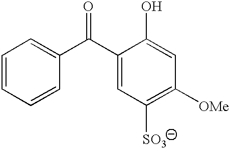 | 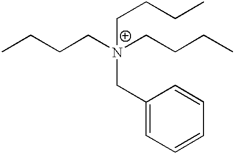 |
| C-30 | 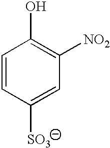 | 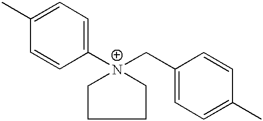 |

[(A) Water-Insoluble and Alkali-Soluble High-Molecular Compound]

The water-insoluble and alkali-soluble high-molecular compound (alkali-soluble resin) (A) that can be used in the positive image forming layer in the image forming material of the invention includes homopolymers having an acid group in the main chain or side chains thereof and copolymers or mixtures thereof. The acid group may be introduced by any of a method of introducing it by polymerizing a monomer previously having an acid group and a method of introducing it by polymeric reaction after polymerization, or a combination of these methods.

Examples of such alkali-soluble resins include phenol resins described in Phenol Resins, published by Plastic Age Co., Ltd., Synthesis, Curing, Toughening and Application of Phenol Resins, published by IPC Ltd., Plastic Material Course (15): Phenol Resins, published by The Nikkan Kogyo Shimbun, Ltd., and Plastic Book (15): Phenol Resins, published by Kogyo Chosakai Publishing Co., Ltd.; polyhydroxystyrenes; polyhalogenated hydroxystyrenes; N-(4-hydroxyphenyl)methacrylamide copolymers; hydroquinone monomethacrylate copolymers; sulfonylimide based polymers described in JP-A No. 7-28244;carboxyl group-containing polymers described in JP-A No. 7-36184;phenolic hydroxyl group-containing acrylic resins described in JP-A No. 51-34711;sulfonamide group-containing acrylic resins described in JP-A No. 2-866;urethane based resins; and various alkali-soluble high-molecular compounds. Though there are no particular limitations with respect to the alkali-soluble resin, ones having an acid group selected from the following (1) to (6) groups in the main chain or side chains thereof are preferable from the standpoints of solubility in alkaline developing solutions and revelation of dissolution inhibiting ability.

(1) Phenol group (—Ar—OH)

(2) Sulfonamide group (—SO₂NH—R)

(3) Substituted sulfonamide based acid group (hereinafter referred to as “active imide group”) [—SO₂NHCOR, —SO₂NHSO₂R, and —CONHSO₂R]

(4) Carboxylic acid group (—CO₂H)

(5) Sulfonic acid group (—SO₃H)

(6) Phosphoric acid group (—OPO₃H₂)

In the foregoing (1) to (6) groups, Ar represents an optionally substituted divalent aryl connecting group; and R represents an optionally substituted hydrocarbon group.

Of the alkali-soluble resins having an acid group selected from the foregoing (1) to (6) groups, are preferable alkali-soluble resins having (1) a phenol group, (2) a sulfonamide group, (3) an active imide group, or (4) a carboxylic acid group. Especially, alkali-soluble resins having (1) a phenol group, (2) a sulfonamide group, or (4) a carboxylic acid group are the most preferable from the standpoint of sufficiently ensuring solubility in alkaline developing solutions, development latitude and film strength.

As the alkali-soluble resin having an acid group selected from the foregoing (1) to (6) groups, can be enumerated the following resins.

Examples of alkali-soluble resins having (1) a phenol group include novolac resins, resol resins, polyvinylphenol resins, and phenolic hydroxyl group-containing acrylic resins. From the viewpoints of image forming property and thermosetting property, novolac resins, resol resins, and polyvinylphenol resins are preferable; from the viewpoint of stability, novolac resins and polyvinylphenol resins are more preferable; and from the viewpoints of easiness of availability of raw materials and flexibility of raw materials, novolac resins are particularly preferable.

The novolac resins as referred to herein mean resins obtained by polycondensing at least one kind of phenols such as phenol, o-cresol, m-cresol, p-cresol, 2,5-xylenol, 3,5-xylenol, o-ethylphenol, m-ethylphenol, p-ethylphenol, propylphenol, n-butylphenol, tert-butylphenol, 1-naphthol, 2-naphthol, pyrrocatechol, resorsinol, hydroquinone, pyrogallol, 1,2,4-benzenetriol, fluoroglucinol, 4,4′-biphenyldiol, and 2,2-bis(4′-hydroxyphenyl)propane with at least one kind of aldehydes such as formaldehyde, acetaldehyde, propionaldehyde, benzaldehyde, and furfural (paraformaldehyde and paraldehyde may be used in place of formaldehyde and acetaldehyde, respectively) or ketones such as acetone, methyl ethyl ketone, and methyl isobutyl ketone in the presence of an acid catalyst.

In the invention, polycondensates of phenol, o-cresol, m-cresol, p-cresol, 2,5-xylenol, 3,5-xylenol, or resorcinol as the phenol with formaldehyde, acetaldehyde, or propionaldehyde as the alhedyde or ketone are preferable. Especially, polycondensates of a mixed phenol of m-cresol, p-cresol, 2,5-xylenol, 3,5-xylenol and resorcinol in a mixing molar ratio of (40 to 100) to (0 to 50) to (0 to 20) to (0 to 20) to (0 to 20) or a mixed phenol of phenol, m-cresol and p-cresol in a mixing molar ratio of (0 to 100) to (0 to 70) to (0 to 60) with formaldehyde are preferable.

Incidentally, it is preferred that the positive image forming layer in the invention contains a solvent inhibitor. In such a case, polycondensates of a mixed phenol of m-cresol, p-cresol, 2,5-xylenol, 3,5-xylenol and resorcinol in a mixing molar ratio of (70 to 100) to (0 to 30) to (0 to 20) to (0 to 20) to (0 to 20) or a mixed phenol of phenol, m-cresol and p-cresol in a mixing molar ratio of (10 to 100) to (0 to 60) to (0 to 40) with formaldehyde are preferable.

Examples of phenol group-containing alkali-soluble resins include polymers of phenol group-containing polymerizable monomers.

Examples of phenol group-containing polymerizable monomers include phenol group-containing acrylamides, methacrylamides, acrylic acid esters, methacrylic acid esters, and hydroxystyrenes.

Specific examples of phenol group-containing polymerizable monomers that can suitably be used include N-(2-hydroxyphenyl)acrylamide, N-(3-hydroxyphenyl)acrylamide, N-(4-hydroxyphenyl)acrylamide, N-(2-hydroxyphenyl)methacrylamide, N-(3-hydroxyphenyl)methacrylamide, N-(4-hydroxyphenyl)methacrylamide, o-hydroxyphenyl acrylate, m-hydroxyphenyl acrylate, p-hydroxyphenyl acrylate, o-hydroxyphenyl methacrylate, m-hydroxyphenyl methacrylate, p-hydroxyphenyl methacrylate, o-hydroxystyrene, m-hydroxystyrene, p-hydroxystyrene, 2-(2-hydroxyphenyl)ethyl acrylate, 2-(3-hydroxyphenyl)ethyl acrylate, 2-(4-hydroxyphenyl)ethyl acrylate, 2-(2-hydroxyphenyl)ethyl methacrylate, 2-(3-hydroxyphenyl)ethyl methacrylate, and 2-(4-hydroxyphenyl)ethyl methacrylate.

Further, an acid group may be derived by polymerization of an acid group precursor and then polymeric reaction. For example, after polymerizing p-acetoxystyrene as an acid group precursor, the ester segment may be derived into a phenolic hydroxyl group upon hydrolysis. Moreover, polycondensates of a phenol containing an alkyl group having from 3 to 8 carbon atoms as a substituent with formaldehyde, such as t-butylphenol-formaldehyde resins and octylphenol-formaldehyde resins, as described in U.S. Pat. No. 4,123,279, can be enumerated as preferred examples.

Examples of alkali-soluble resins having (2) a sulfonamide group include polymers constituted of a minimum constituent unit derived from a sulfonamide group-containing compound as the major constituent component. As such a compound are enumerated compounds having one or more sulfonamide groups having at least one hydrogen atom bonded to a nitrogen atom and one or more polymerizable unsaturated groups within the molecule thereof. Especially, low-molecular compounds having an acryloyl group, an allyl group or a vinyloxy group and a substituted or monosubstituted aminosulfonyl group or a substituted sulfonylimino group within the molecule thereof are preferable, and examples include compounds represented by the following general formulae (i) to (v).

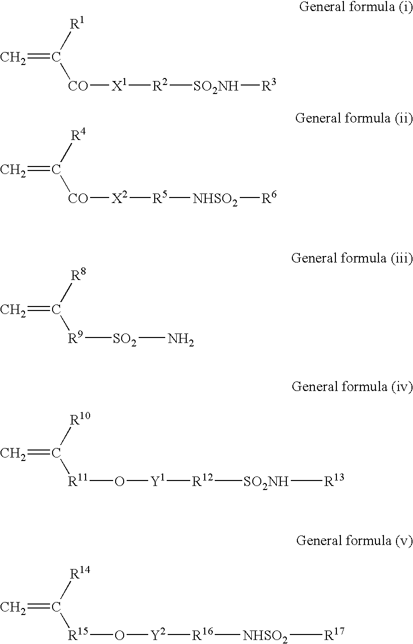

In the general formulae (i) to (v), X¹ and X² each independently represents —O— or —NR⁷. R¹ and R⁴ each independently represents a hydrogen atom or —CH₃. R², R⁵, R⁹, R¹² and R¹⁶ each independently represents an optionally substituted alkylene group having from 1 to 12 carbon atoms, cycloalkylene group, arylene group or aralkylene group. R³, R⁷ and R¹³ each independently represents a hydrogen atom or an optionally substituted alkyl group having from 1 to 12 carbon atoms, cycloalkyl group, aryl group or aralkyl group. R⁶ and R¹⁷ each independently represents an optionally substituted alkyl group having from 1 to 12 carbon atoms, cycloalkyl group, aryl group or aralkyl group. R⁸, R¹⁰ and R¹⁴ each independently represents a hydrogen atom or —CH₃. R¹¹ and R¹⁵ each independently represents a single bond or an optionally substituted alkylene group having from 1 to 12 carbon atoms, cycloalkylene group, arylene group or aralkylene group. Y¹ and Y² each independently represents a single bond or CO.

Of the compounds represented by the general formulae (i) to (v), in particualr, m-aminosulfonylphenyl methacrylate, N-(p-aminosulfonylphenyl)methacrylamide, and N-(p-amino-sulfonylphenyl)acrylamide can suitably be used in the invention.

Examples of alkali-soluble resins having (3) an active imide group include polymers constituted of a minimum constituent unit derived from an active imide group-containing compound as the major constituent component. As such a compound are enumerated compounds having one or more active imide groups represented by the following structural formula and one or more polymerizable unsaturated groups within the molecule thereof.

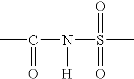

Specifically, N-(p-toluenesulfonyl)methacrylamide and N-(p-toluenesulfonyl)acrylamide can suitably be used.

Examples of alkali-soluble resins having (4) a carboxylic acid group include polymers constituted of a minimum constituent unit derived from a compound having one or more carboxylic acid groups and one or more polymerizable unsaturated groups within the molecule thereof as the major constituent component.

Examples of alkali-soluble resins having (5) a sulfonic acid group include polymers constituted of a minimum constituent unit derived from a compound having one or more sulfonic acid groups and one or more polymerizable unsaturated groups within the molecule thereof as the major constituent component.

Examples of alkali-soluble resins having (6) a phosphoric acid group include polymers constituted of a minimum constituent unit derived from a compound having one or more phosphoric acid groups and one or more polymerizable unsaturated groups within the molecule thereof as the major constituent component.

The minimum constituent component unit having an acid group selected from the foregoing (1) to (6) groups, which constitutes the alkali-soluble resin to be used in the positive image forming layer is not always limited to one kind only. Copolymers of two kinds or more minimum constituent units having the same acid group or two kinds or more minimum constituent units each having a different acid group can also be used.

From the viewpoint of enhancement of alkali solubility and solubility discrimination, copolymers containing 10% by mole or more, and preferably 20% by mole or more of a compound having an acid group selected from the foregoing (1) to (6) groups, which is to be copolymerized, are preferable.

In the invention, in the case where a compound is copolymerized, and an alkali-soluble resin is used as a copolymer, other compounds not containing an acid group selected from the foregoing (1) to (6) groups can be used as the compound to be copolymerized. As other compounds not containing an acid group selected from the foregoing (1) to (6) groups, compounds set forth in the following (m1) to (m13) groups can be enumerated, but it should not be construed that the invention is limited thereto.

(m1) Acrylic acid esters and methacrylic acid esters having an aliphatic hydroxyl group, such as 2-hydroxyethyl acrylate and 2-hydroxyethyl methacrylate.

(m2) Alkyl acrylates such as methyl acrylate, ethyl acrylate, propyl acrylate, butyl acrylate, amyl acrylate, hexyl acrylate, octyl acrylate, benzyl acrylate, 2-chloroethyl acrylate, and glycidyl acrylate.

(m3) Alkyl methacrylates such as methyl methacrylate, ethyl methacrylate, propyl methacrylate, butyl methacrylate, amyl methacrylate, hexyl methacrylate, cyclohexyl methacrylate, benzyl methacrylate, 2-chloroethyl methacrylate, and glycidyl methacrylate.

(m4) Acrylamides and methacrylamides such as acrylamide, methacrylamide, N-methylolacrylamide, N-ethylacrylamide, N-hexylmethacrylamide, N-cyclohexylacrylamide, N-hydroxyethylacrylamide, N-phenylacrylamide, N-nitrophenylacrylamide, and N-ethyl-N-phenylacrylamide.

(m5) Vinyl ethers such as ethyl vinyl ether, 2-chloroethyl vinyl ether, hydroxyethyl vinyl ether, propyl vinyl ether, butyl vinyl ether, octyl vinyl ether, and phenyl vinyl ether.

(m6) Vinyl esters such as vinyl acetate, vinyl chloroacetate, vinyl butyrate, and vinyl benzoate.

(m7) Styrenes such as styrene, a-methylstyrene, methylstyrene, chloromethylstyrene, and p-acetoxystyrene.

(m8) Vinyl ketones such as methyl vinyl ketone, ethyl vinyl ketone, propyl vinyl ketone, and phenyl vinyl ketone.

(m9) Olefins such as ethylene, propylene, isobutylene, butadiene, and isoprene.

(m10) N-Vinylpyrrolidone, acrylonitrile, methacrylonitrile, and the like.

(m11) Unsaturated imides such as maleimide, N-acryloylacrylamide, N-acetylmethacrylamide, N-propionylmethacrylamide, and N-(p-chlorobenzoyl)methacrylamide.

(m12) Maleic anhydride, itaconic anhydride, acrylic acid chloride, methacrylic acid chloride, and the like.

(m13) Methacrylic acid based monomers having a hetero atom bonded at the α-position, such as compounds described in Japanese Patent Application Nos. 2001-115595 and 2001-115598.

In the invention, in the case where the alkali-soluble resin is a homopolymer or copolymer of a polymerizable monomer having (1) a phenolic hydroxyl group, a polymerizable monomer having (2) a sulfonamide group, a polymerizable monomer having (3) an active imide group, a polymerizable monomer having (4) a carboxylic acid group, a polymerizable monomer having (5) a sulfonic acid group, or a polymerizable monomer having (6) a phosphoric acid group, ones having a weight average molecular weight as reduced into polystyrene by the gel permeation chromatography method (hereinafter simply referred to as “weight average molecular weight”) of 2,000 or more and a number average molecular weight of 500 or more are preferable, and ones having a weight average molecular weight from 5,000 to 300,000 and a number average molecular weight from 800 to 250,000, with a degree of dispersion (weight average molecular weight/number average molecular weight) being from 1.1 to 10, are more preferable.

In the invention, in the case where the alkali-soluble high-molecular compound is a novolac resin, ones having a weight average molecular weight from 500 to 100,000 and a number average molecular weight from 200 to 50,000 are preferable. Novolac resins having a low ratio of low-molecular component described in Japanese Patent Application No. 2001-126278 may also be used.

The alkali-soluble resins may be used singly or in combination of two or more thereof and are used in an addition amount from 30 to 99% by mass, preferably from 40 to 95% by mass, and particularly preferably from 50 to 90% by mass in the whole of solid contents of the image forming layer (photosensitive layer). When the total addition amount of the alkali-soluble resin is less than 30% by mass, durability of the photosensitive layer is deteriorated. On the other hand, the addition amount exceeding 99% by mass is not preferred from the viewpoints of sensitivity and image forming property.

In the case where a combination of alkali-soluble resins is used, any combinations can be used. Examples of particularly preferred combinations include a combination of a phenolic hydroxyl group-containing polymer and a sulfonamide group-containing polymer, a combination of a phenolic hydroxyl group-containing polymer and a carboxylic acid group-containing polymer, a combination of two kinds or more of phenolic hydroxyl group-containing polymers, and combinations with polycondensates of phenol and formaldehyde containing an alkyl group having from 3 to 8 carbon atom as a substituent, such as a polycondensate of t-butylphenol and formaldehyde and a polycondensate of octylphenol and formaldehyde, as described in U.S. Pat. No. 4,123,279, and alkaline-soluble resins having an electron-withdrawing group-containing phenol structure on the aromatic ring, as described in JP-A No. 2000-241972.

[(C) Light-Heat Converting Agent]

In the first embodiment of the image forming material of the invention, the following light-heat Converting agent (C) may be used in combination with the specific IR coloring material according to the invention, the use of which is, however, not essential.

Further, in the second embodiment of the image forming material of the invention, the following Light-to-heat Converting agent (C) is contained as an essential component in the image forming layer.

As the light-heat Converting agent (C) to be used in the invention, any substances that absorb light energy radiations used for recording to generate a heat can be used without limitations on absorption wavelength region. However, infrared absorbing dyes or pigments having an absorption maximum at a wavelength of 760 nm to 1,200 nm are preferable from the viewpoint of adaptability to readily available high-output lasers.

(Infrared absorbing dye or pigment)

As dyes, commercially available dyes and known dyes described in literatures such as Dye Handbooks (edited by The Society of Synthetic Organic Chemistry, Japan, 1970) can be utilized. Specific examples include dyes such as azo dyes, metal complex salt azo dyes, pyrazolone azo dyes, naphthoquinone dyes, anthraquinone dyes, phthalocyanine dyes, naphthalocyanine dyes, carbonium dyes, quinoneimine dyes, methine dyes, cyanine dyes, squarylium dyes, (thio)pyrylium salts, metal thiolate complexes, indoaniline metal complex based dyes, oxonol dyes, diimonium dyes, aminium dyes, croconium dyes, and intermolecular CT dyes.

Preferred examples of dyes include cyanine dyes described in JP-A Nos. 58-125246, 59-84356, 59-202829, and 60-78787; methine dyes described in JP-A Nos. 58-173696, 58-181690, and 58-194595; naphtoquinone dyes described in JP-A Nos. 58-112793, 58-224793, 59-48187, 59-73996, 60-52940, and 60-63744; squarylium dyes described in JP-A No. 58-112792; and cyanine dyes described in British Patent No. 434,875.

Further, near infrared absorbing sensitizers described in U.S. Pat. No. 5,156,938 can also suitably be used. Moreover, substituted aryl benzo(thio)pyrylium salts described in U.S. Pat. No. 3,881,924, trimethine thiapyrylium salts described in JP-A No. 57-142645 (counterpart to U.S. Pat. No. 4,327,169), pyrylium based compounds described in JP-A Nos. 58-181051, 58-220143, 59-41363, 59-84248, 59-84249, 59-146063, and 59-146061, cyanine dyes described in JP-A No. 59-216146, pentamethine thiopyrylium salts described in U.S. Pat. No. 4,283,475, and pyrylium compounds disclosed in JP-B Nos. 5-13514 and 5-19702 can also suitably be used.

Near infrared absorbing dyes described as formulae (I) and (II) in U.S. Pat. No. 4,756,993 can also be enumerated as other preferred examples of the dye.

Of these dyes are particularly preferable cyanine dyes, phthalocyanine dyes, oxonol dyes, squarylium dyes, pyrylium salts, thiopyrylium dyes, and nickel thiolate complexes.

In addition, dyes represented by the following general formulae (a) to (f) are preferable because of their excellent light-heat conversion efficiency. Especially, cyanine dyes represented by the general formula (a) are the most preferable because when used in the invention, they give a high mutual action with the alkali-soluble resin and are excellent in stability and economy.

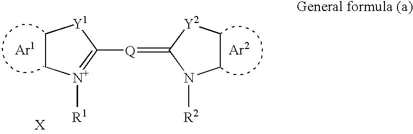

In the general formula (a), R¹ and R² each independently represents an alkyl group having from 1 to 12 carbon atoms, which may be substituted with a substituent selected from an alkoxy group, an aryl group, an amide group, an alkoxycarbonyl group, a hydroxyl group, a sulfo group, and a carboxyl group. Y¹ and Y² each independently represents oxygen, sulfur, selenium, a dialkylmethylene group, or —CH═CH—. Ar¹ and Ar² each independently represents an aromatic hydrocarbon group, which may be substituted with a substituent selected from an alkyl group, an alkoxy group, a halogen atom, and an alkoxycarbonyl group, and the aromatic ring may be fused with Y¹ and Y² via adjacent continuous two carbon atoms.

In the general formula (a), X represents a counter ion necessary for neutralizing charges, and in the case where the dye cation segment has an anionic substituent, X is not always necessary. Q represents a polymethine group selected from a trimethine group, a pentamethine group, a heptamethine group, a nonamethine group, and an undecamethine group; from the standpoints of wavelength adaptability against infrared rays to be used for exposure and stability, Q is preferably a pentamethine group, a heptamethine group, or a nonmethine group; and it is preferred from the standpoint of stability to have a cyclohexene ring or cyclopentene ring containing continuous three methine chains on any one of carbon atoms.

In the general formula (a), Q may be substituted with a group selected from an alkoxy group, an aryloxy group, an alkylthio group, an arylthio group, a dialkylamino group, a diarylamino group, a halogen atom, an alkyl group, an aralkyl group, a cycloalkyl group, an aryl group, an oxy group, an iminium salt group, and a substituent represented by the following general formula (I). Preferred examples of substituents include halogen atoms such as a chlorine atom, diarylamino groups such as a diphenylamino group, and arylthio groups such as a phenylthio group.

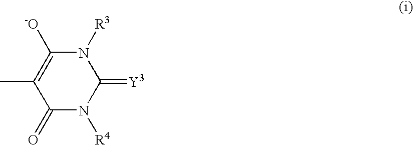

In the general formula (I), R³ and R⁴ each independently represents a hydrogen atom, an alkyl group having from 1 to 8 carbon atoms, or an aryl group having from 6 to 10 carbon atoms. Y³ represents an oxygen atom or a sulfur atom.

Of the cyanine dyes represented by the general formula (a), in the case of exposure with infrared rays having a wavelength of 800 to 840 nm, heptamethinecyanine dyes represented by the following general formulae (a-1) to (a-4) are especially preferable.

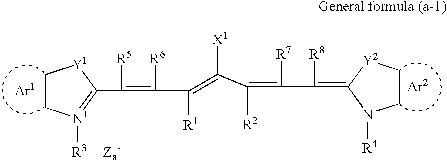

In the general formula (a-1), X¹ represents a hydrogen atom or a halogen atom. R¹ and R² each independently represents a hydrocarbon group having from 1 to 12 carbon atoms. From the standpoint of storage stability of coating solutions for image forming layer, it is preferred that R¹ and R² are each a hydrocarbon group having two or more carbon atoms, and it is especially preferred that R¹ and R² are taken together to form a 5-membered or 6-membered ring.

In the general formula (a-1), Ar¹ and Ar² may be the same or different and each represent an optionally substituted aromatic hydrocarbon group. Preferred examples of aromatic hydrocarbon groups include a benzene ring and a naphthalene ring. Preferred examples of substituents include hydrocarbon groups having not more than 12 carbon atoms, halogen atoms, and alkoxy groups having not more than 12 carbon atoms. Y¹ and Y² may be the same or different and each represent a sulfur atom or a dialkylmethylene group having not more than 12 carbon atoms. R³ and R⁴ may be the same or different and each represent an optionally substituted hydrocarbon groups having not more than 20 carbon atoms. Preferred examples of substituents include an alkoxy group having not more than 12 carbon atoms, a carboxyl group, and a sulfo group. R⁵, R⁶, R⁷ and R⁸ may be the same or different and each represent a hydrogen atom or a hydrocarbon group having not more than 12 carbon atoms, with a hydrogen atom being preferred from the standpoint of easiness of availability of raw materials. Za⁻ represents a counter anion necessary for neutralizing charges, and in the case where any one of R¹ to R⁸ is substituted with an anionic substituent, Za⁻ is not necessary. From the standpoint of storage stability of coating solutions for image forming layer, Za⁻ is preferably a halogen ion, a perchloric acid ion, a tetrafluoroborate ion, a hexafluorophosphate ion, or a sulfonic acid ion, and particularly preferably a perchloric acid ion, a tetrafluoroborate ion, a hexafluorophosphate ion, or a sulfonic acid ion. The heptamethine dyes represented by the general formula (a-1) can suitably be used in positive image forming materials, and especially, can preferably be used in so-called mutual action-releasing type positive photosensitive materials combined with a phenolic hydroxyl group-containing alkali-soluble resin.

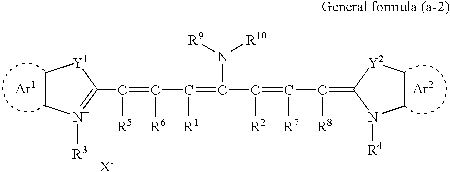

In the general formula (a-2), R¹ and R² each independently represents a hydrogen atom or a hydrocarbon group having from 1 to 12 carbon atoms, and R¹ and R² may bond with each other to form a ring structure. The ring to be formed is preferably a 5-membered ring or a 6-membered ring, and particularly preferably a 5-membered ring. Ar¹ and Ar² may be the same or different and each represent an optionally substituted aromatic hydrocarbon group. Preferred examples of aromatic hydrocarbon groups include a benzene ring and a naphthalene ring. Preferred examples of substituents on the aromatic hydrocarbon group include hydrocarbon groups having not more than 12 carbon atoms, halogen atoms, and alkoxy groups, alkoxycarbonyl groups, alkylsufonyl groups and halogenated alkyl groups each having not more than 12 carbon atoms, with electron-withdrawing substituents being particularly preferred. Y¹ and Y² may be the same or different and each represent a sulfur atom or a dialkylmethylene group having not more than 12 carbon atoms. R³ and R⁴ may be the same or different and each represent an optionally substituted hydrocarbon group having not more than 20 carbon atoms. Preferred examples of substituents include an alkoxy group having not more than 12 carbon atoms, a carboxyl group, and a sulfo group. R⁵, R⁶, R⁷ and R⁸ may be the same or different and each represent a hydrogen atom or a hydrocarbon group having not more than 12 carbon atoms, with a hydrogen atom being preferred from the standpoint of easiness of availability of raw materials. R⁹ and R¹⁰ may be the same or different and each represent an optionally substituted aromatic hydrocarbon group having from 6 to 10 carbon atoms, an optionally substituted alkyl group having from 1 to 8 carbon atoms, or a hydrogen atom, or may bond with each other to form a ring having any one of the following structures.

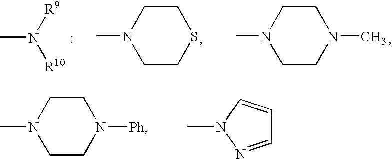

In the general formula (a-2), R⁹ and R¹⁰ are most preferably an aromatic hydrocarbon group such as a phenyl group.

X⁻ represents a counter anion necessary for neutralizing charges and is synonymous with Za⁻ in the foregoing general formula (a-1).

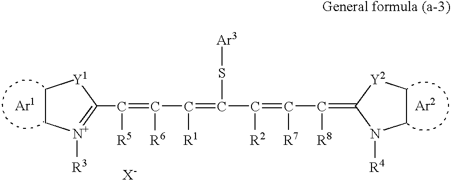

In the general formula (a-3), R¹ to R⁸, Ar¹, Ar², Y¹, Y² and X⁻ are respectively synonymous with those in the foregoing general formula (a-2). Ar³ represents an aromatic hydrocarbon group such as a phenyl group and a naphthyl group or a monocyclic or polycyclic heterocyclic group containing at least one of nitrogen, oxygen and sulfur atoms, and preferably a heterocyclic group selected from the group consisting of thiazole based, benzothiazole based, naphthothiazole based, thianaphtheno-7,6,4,5-thiazole based, oxazole based, benzoxazole based, naphthoxazole based, selenazole based, benzoselenazole based, naphthoselenazole based, thiazoline based, 2-quinoline based, 4-quinolin based, 1-isoquinoline based, 3-isoquinoline based, benzimidazole based, 3,3-dialkylbenzoindolenine based, 2-pyridine based, 4-pyridine based, 3,3-dialkylbenzo[e]indole based, tetrazole based, triazole based, pyrimidine based, and thiadiazole based groups. As the heterocyclic group, the following structures are the most preferable.

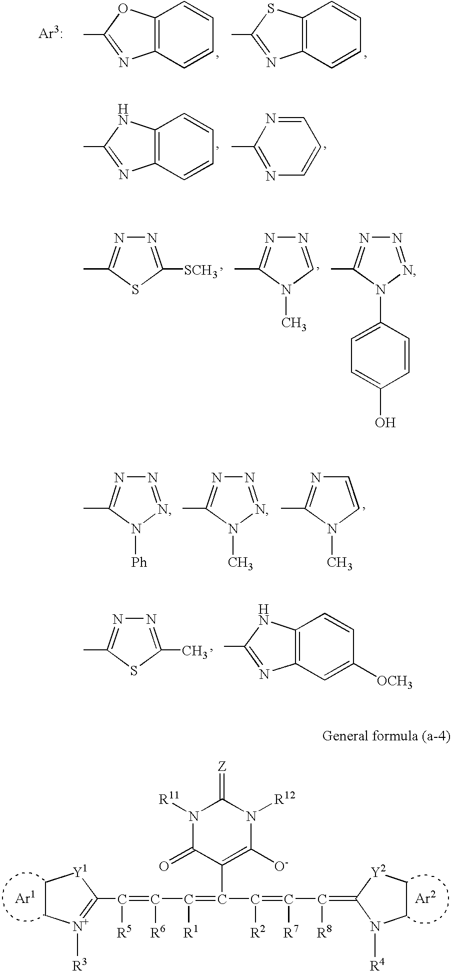

In the general formula (a-4), R¹ to R⁸, Ar¹, Ar², Y¹ and Y² are respectively synonymous with those in the foregoing general formula (a-2). R¹¹ and R¹² may be the same or different and each represent a hydrogen atom, an allyl group, a cyclohexyl group, or an alkyl group having from 1 to 8 carbon atoms. Z represents an oxygen atom or a sulfur atom.

In the invention, specific examples of cyanine dyes represented by the general formula (a) that can suitably be used include those described in paragraphs [0017] to [0019] of JP-A No. 2001-133969, paragraphs [0012] to [0038] of JP-A No. 2002-40638, and paragraphs [0012] to [0023] of JP-A No. 2002-23360, in addition to those enumerated below.

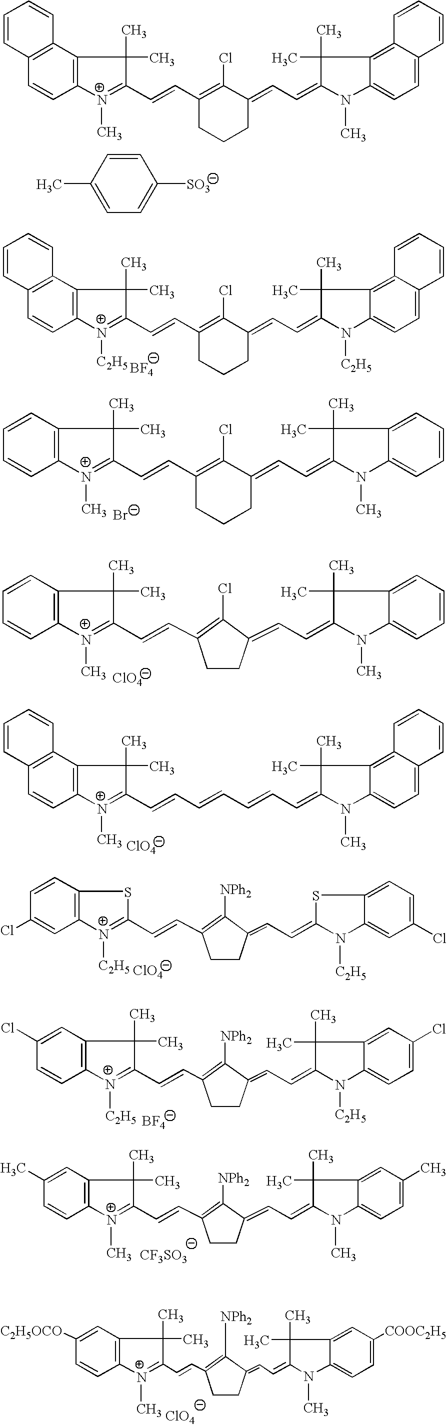

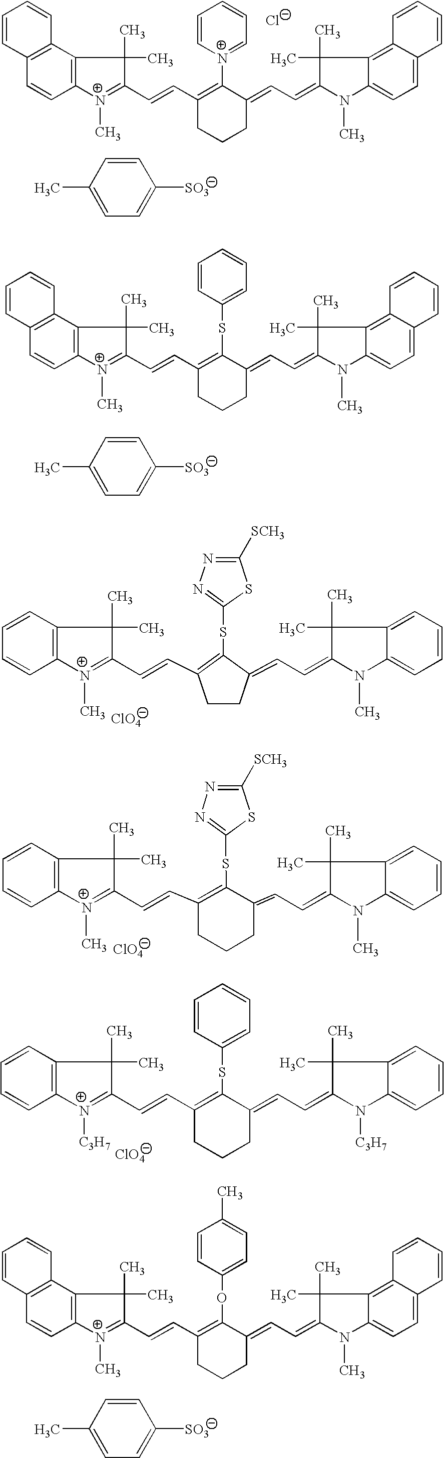

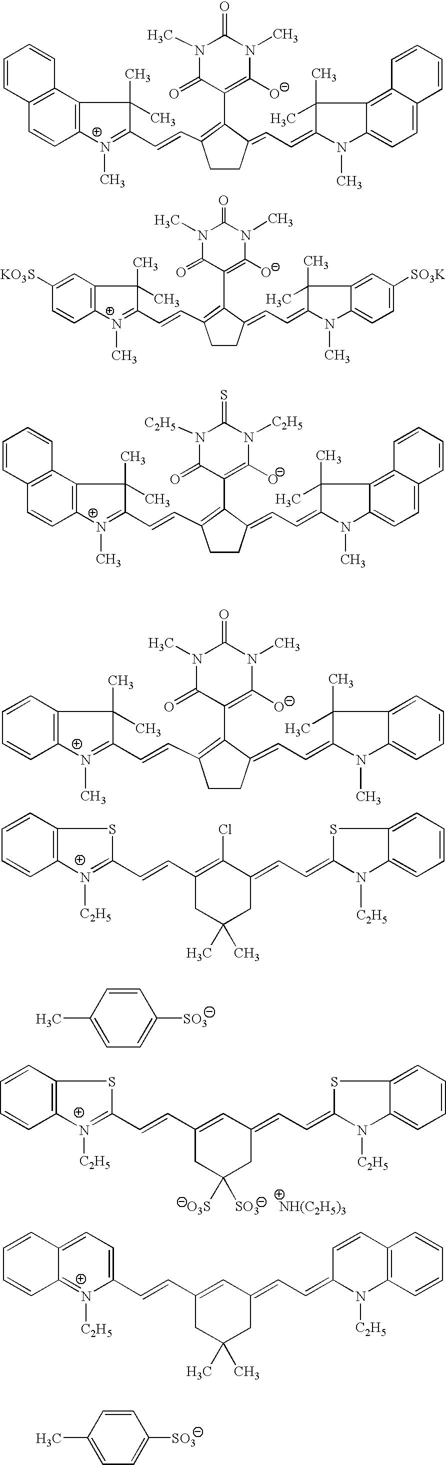

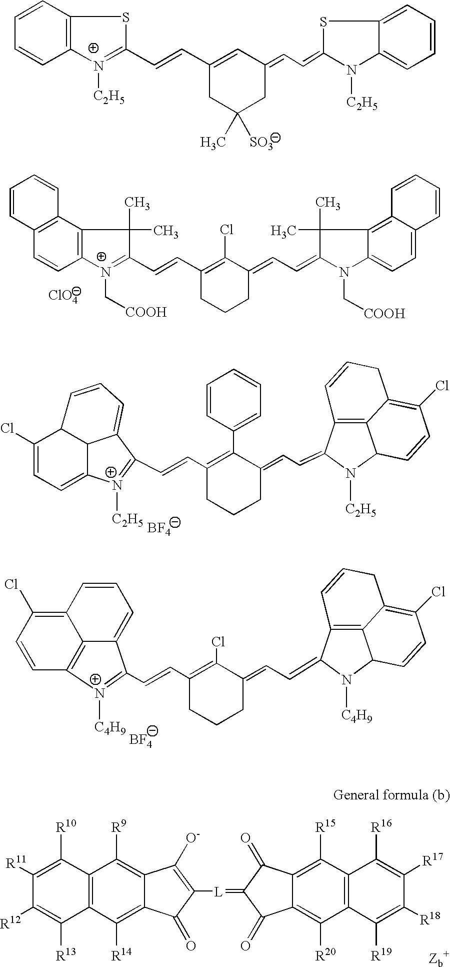

In the general formula (b), L represents a methine chain having 7 or more conjugated carbons. The methine chain may have a substituent, and substituents may bond with each other to form a ring structure. Zb⁺ represents a counter cation. Preferred examples of counter cations include ammonium, iodonium, sulfonium, phosphonium, pyridinium, and alkali metal cations (such as Na⁺, K⁺, and Li⁺). R⁹ to R¹⁴ and R¹⁵ to R²⁰ each independently represents a hydrogen atom or a substituent selected from a halogen atom, a cyano group, an alkyl group, an aryl group, an alkenyl group, an alkynyl group, a carbonyl group, a thio group, a sulfonyl group, a sulfinyl group, an oxy group, and an amino group, or a substituent comprising a combination of two or three of these groups, and may bond with each other to form a ring structure. Here, in the general formula (b), ones in which L represents a methine chain having 7 conjugated carbons, and R⁹ to R¹⁴ and R¹⁵ to R²⁰ are all a hydrogen atom are preferable from the standpoints of easiness of availability of raw materials and effect.

In the invention, specific examples of dyes represented by the general formula (b), which can suitably be used, will be given below.

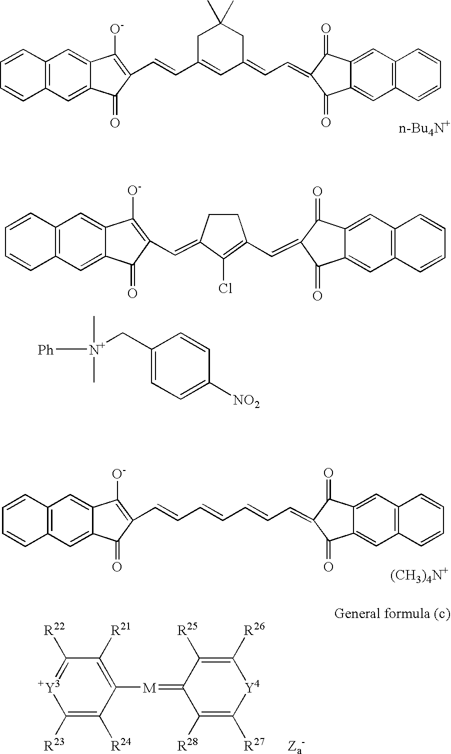

In the general formula (c), Y³ and Y⁴ each independently represents an oxygen atom, a sulfur atom, a selenium atom, or a tellurium atom. M represents a methine chain having at least five or more conjugated carbon atoms. R²¹ to R²⁴ and R²⁵ to R²⁸ may be the same or different and each represent a hydrogen atom, a halogen atom, a cyano group, an alkyl group, an aryl group, an alkenyl group, an alkynyl group, a carbonyl group, a thio group, a sulfonyl group, a sulfinyl group, an oxy group, or an amino group. Za⁻ represents a counter anion and is synonymous with Za⁻ in the foregoing general formula (a).

In the invention, specific examples of dyes represented by the general formula (c), which can suitably be used, will be given below.

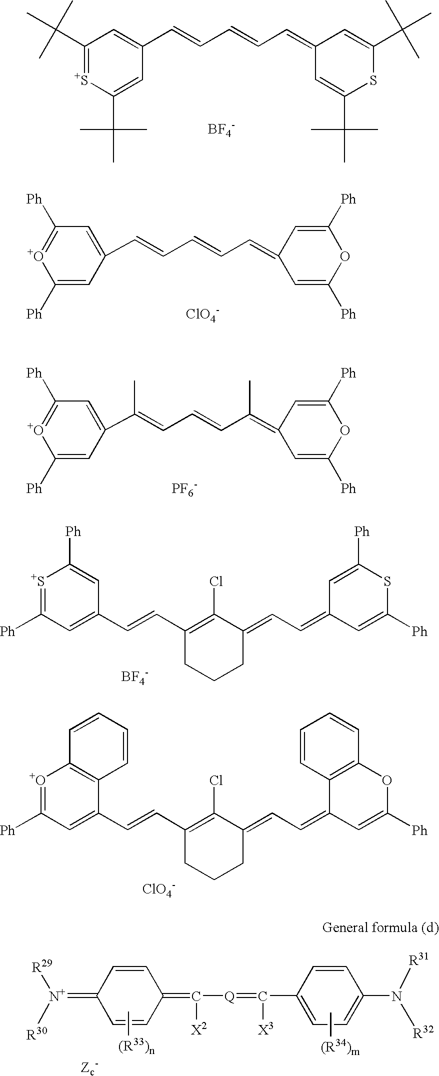

In the general formula (d), R²⁹ to R³² each independently represents a hydrogen atom, an alkyl group, or an aryl group. R³³ and R³⁴ each independently represents an alkyl group, a substituted oxy group, or a halogen atom. n and m each independently represents an integer from 0 to 4. R²⁹ and R³⁰, or R³¹ and R³² may bond with each other to form a ring, at least one of R²⁹ and R³⁰ may bond with R³³ to form a ring, and at least one of R³¹ and R³² may bond with R³⁴ to form a ring. Further, in the case when a plural number of R³³ or R³⁴ are present, the plurality of R³³ or the plurality of R³⁴ may bond with each other to form a ring. X² and X³ each independently represents a hydrogen atom, an alkyl group, or an aryl group. Q represents an optionally substituted trimethine group or pentamethine group and may form a ring structure together with a divalent organic group. Zc⁻ represents a counter anion and is synonymous with Za⁻ in the foregoing general formula (a).

In the invention, specific examples of dyes represented by the general formula (d), which can suitably be used, will be given below.

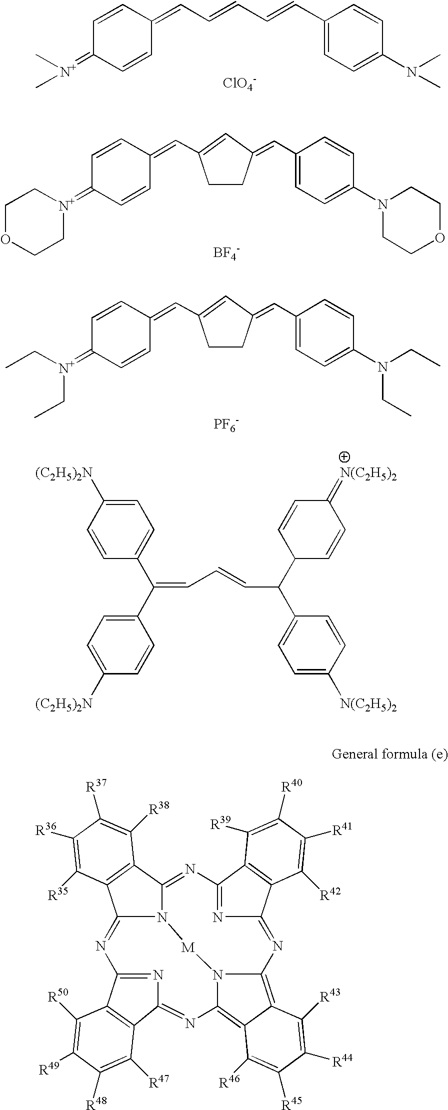

In the general formula (e), R³⁵ to R⁵⁰ each independently represents a hydrogen atom, a halogen atom, a cyano group, an alkyl group, an aryl group, an alkenyl group, an alkynyl group, a hydroxyl group, a carbonyl group, a thio group, a sulfonyl group, a sulfinyl group, an oxy group, an amino group, or an onium salt structure, and in the case where a substituent can be introduced, these groups may have a substituent. M represents two hydrogen atoms, a metal atom, a halometal group, or an oxy metal group. Examples of metal atoms to be contained therein include atoms belonging to the Groups IA, IIA, IIIB and IVB of the Periodic Table, transition metals of the first, second and third periods, and lanthanoid elements. Of these, copper, nickel, magnesium, iron, zinc, tin, cobalt, aluminum, titanium, and vanadium are preferable, and vanadium, nickel, zinc, and tin are particularly preferable. For making the valence proper, these metal atoms may be bonded to an oxygen atom, a halogen atom, and the like.

In the invention, specific examples of dyes represented by the general formula (e), which can suitably be used, will be given below.

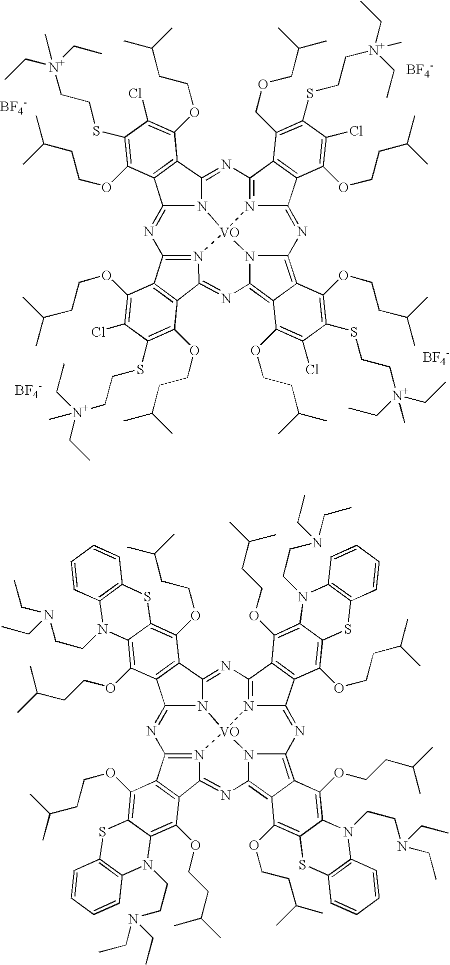

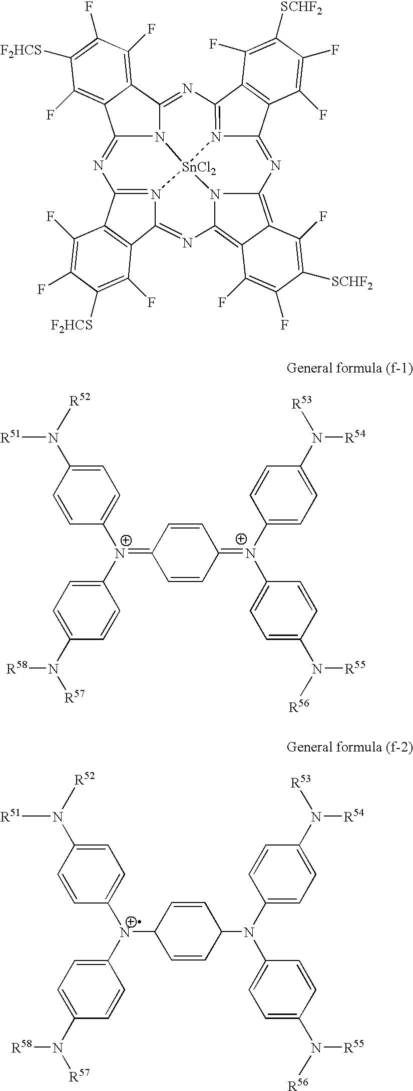

In the general formulae (f-1) and (f-2), R⁵¹ to R⁵⁸ each independently represents a hydrogen atom or an optionally substituted alkyl group or aryl group. X⁻ is synonymous with X⁻ in the foregoing general formula (a-2).

In the invention, specific examples of dyes represented by the general formulae (f-1) and (f-2), which can suitably be used, will be given below.

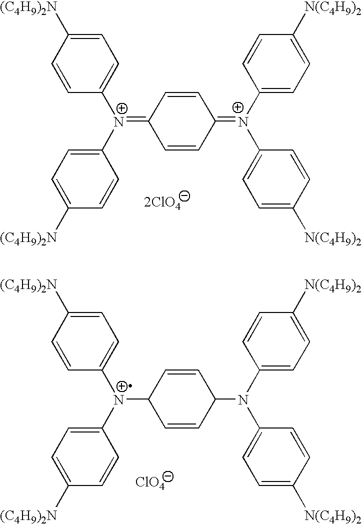

As Light-heat Converting agents other than those described above, dyes having a plurality of chromophores described in JP-A No. 2001-242613, coloring materials comprising a high-molecular compound having a chromophore covalently connected thereto described in JP-A No. 2002-97384 and U.S. Pat. No. 6,124,425, anionic dyes described in U.S. Pat. No. 6,248,893, and dyes having a surface orientating group described in JP-A No. 2001-347765 can suitably be used.

As pigments that are used as the Light-heat Converting agent in the invention can be utilized commercially available pigments and pigments described in Color Index (C.I.) Handbook, Saishin Ganryo Binran (The Newest Pigment Handbook) (edited by The Japan Pigment Technology Association, 1977), Saishin Ganryo Oyo Gijutsu (The Newest Pigment Application Technology) (published by CMC Publishing Co., Ltd., 1986), and Insatsu Inki Gijutsu (Printing Ink Technology) (published by CMC Publishing Co., Ltd., 1984).

As kinds of pigments are enumerated black pigment, yellow pigments, orange pigments, brown pigments, red pigments, violet pigments, blue pigments, green pigments, fluorescent pigments, metallic flake pigments, and polymer-binding pigments. Specifically, insoluble azo pigments, azo lake pigments, condensed azo pigments, chelate azo pigments, phthalocyanine based pigments, anthraquinone based pigments, perylene or perynone based pigments, thioindigo based pigments, quinacridone based pigments, dioxazine based pigments, isoindolinone based pigments, quinophthalone based pigments, dyeing lake pigments, azine pigments, nitroso pigments, nitro pigments, natural pigments, fluorescent pigments, inorganic pigments, and carbon black. Of these is preferable carbon black.

These pigments may be used without being subjected to surface processing, or may be used after being subjected to surface processing. As the method of the surface processing, there may be considered a method of coating the surface of the pigment with a resin or a wax, a method of adhering a surfactant to the surface of the pigment, and a method of a reactive substance (such as silane coupling agents, epoxy compounds, and polyisocyanates) to the surface of the pigment. These surface processing methods are described in Kinzoku Sekken No Seishitsu To Oyo (Nature and Application of Metallic Soap) (published by Saiwai Shobo Co., Ltd.), Insatsu Ink Gijutsu (Printing Ink Technology) (published by CMC Publishing Co., Ltd., 1984), and Saishin Ganryo Oyo Gijutsu (The Newest Pigment Application Technology) (published by CMC Publishing Co., Ltd., 1986).

From the viewpoints of stability of pigment dispersion in coating solutions for image forming layer and uniformity of image forming layer, the pigment preferably has a particle size in the range of 0.01 μm to 10 μm, more preferably from 0.05 μm to 1 μm, and particularly preferably from 0.1 μm to 1 μm.

As a method of dispersing the pigment, known dispersing technologies used in ink production or toner production can be used. Examples of dispersing machines include ultrasonic dispersing units, sand mills, attritors, pearl mills, super mills, ball mills, impellers, dispersers, KD mills, colloid mills, dynatrons, three-roll mills, and pressure kneaders. The details are described in Saishin Ganryo Oyo Gijutsu (The Newest Pigment Application Technology) (published by CMC Publishing Co., Ltd., 1986).

From the viewpoints of sensitivity, uniformity of image forming layer and durability, the pigment or dye in the Light-heat Converting agent (C) can be added in an amount of 0.01 to 50% by mass, preferably from 0.1 to 10% by mass, and particularly preferably 0.5 to 10% by mass in the case of the dye and 0.1 to 10% by mass in the case of the pigment, respectively on a basis of the whole of solid contents constituting the image forming layer.

The dye or pigment to be used may be used singly or in admixture of two or more thereof. For corresponding to exposing machines with a plurality of wavelengths, it is preferably employed to jointly use dyes or pigments having a different absorption wavelength.

[Other Components]

In the invention, in forming the positive image forming layer, various additives can be added as the need arises. From the viewpoint of enhancing dissolution inhibition of image areas into the developing solution, it is preferred to jointly use substances that are heat decomposable and in a non-decomposed state, substantially reduce dissolution of the alkali-soluble high-molecular compound, such as other onium salts, o-quinonediazide compounds, aromatic sulfone compounds, and aromatic sulfonic acid ester compounds. Examples of other onium salts include oniums other than the onium salts falling within the scope of the compound represented by the foregoing general formula (1), such as diazonium salts, ammonium salts, phosphonium salts, iodonium salts, sulfonium salts, selenonium salts, arsonium salts, and azinium salts.

Suitable examples of other onium salts that are used in the invention include diazonium salts described in S.I. Schlesinger, Photogr. Sci. Eng., 18, 387 (1974), T. S. Bal, et al., Polymer, 21, 423 (1980), and JP-A No. 5-158230; ammonium salts described in U.S. Pat. Nos. 4,069,055 and 4,069,056 and JP-A No. 3-140140;phosphonium salts described in D. C. Necker, et al., Macromolecules, 17, 2468 (1984), C. S. Wen, et al., Teh, Proc. Conf. Rad. Curing, ASIA, p.478, Tokyo, Oct (1988), and U.S. Pat. Nos. 4,069,055 and 4,069,056;iodonium salts described in J. V. Crivello, et al., Macromolecules, 10(6), 1307 (1977), Chem. & Eng. News, Nov., 28, p.31 (1988), European Patent No. 104,143, U.S. Pat. Nos. 5,041,358 and 4,491,628, and JP-A Nos. 2-150848 and 2-296514; sulfonium salts described in J. V. Crivello, et al., Polymer J., 17, 73 (1985), J. V. Crivello, et al., J. Org. Chem., 43, 3055 (1978), W. R. Watt, et al., J. Polymer Sci., Polymer Chem. Ed., 22, 1789 (1984), J. V. Crivello, et al., Polymer Bull., 14, 279 (1985), J. V. Crivello, et al., Macromolecules, 14(5), 1141 (1981), J. V. Crivello, et al., Polymer Sci., Polymer Chem. Ed., 17, 2877 (1979), European Patent Nos. 370,693, 233,567, 297,443 and 297,442, U.S. Pat. Nos. 4,933,377, 3,902,114, 5,041,358, 4,491,628, 4,760,013, 4,734,444 and 2,833,827, and German Patent Nos. 2,904,626, 3,604,580 and 3,604,581;selenonium salts described in J. V. Crivello, et al., Macromolecules, 10(6), 1307 (1977) and J. V. Crivello, et al., J. Polymer Sci., Polymer Chem. Ed., 17, 1047 (1979); and arsonium salts described in C. S. Wen, et al., Teh, Proc. Conf. Rad. Curing, ASIA, p.478, Tokyo, October (1988).

Of these other onium salts are particularly preferable diazonium salts. Further, particularly suitable examples of diazonium salts are those described in JP-A No. 5-158230.

Examples of counter ions of the foregoing other onium salts include tetrafluoroboric acid, hexafluorophosphoric acid, triiso-propylnaphthalenesulfonic acid, 5-nitro-o-toluenesulfonic acid, 5-sulfosalicylic acid, 2,5-dimethylbenzenesulfonic acid, 2,4,6-trimethyl-benzenesulfonic acid, 2-nitrobenzenesulfonic acid, 3-chlorobenzenesulfonic acid, 3-bromobenzenesufonic acid, 2-fluorocaprylnaphthalenesulfonic acid, dodecylbenzenesulfonic acid, 1-naphthol-5-sulfonic acid, 2-methoxy-4-hydroxy-5-benzoyl-beznenesulfonic acid, and p-toluenesulfonic acid. Of these are particularly suitable hexafluorophosphoric acid, triisopropylnaphthalenesulfonic acid, and alkyl aromatic sulfonic acids such as 2,5-dimethylbenzenesulfonic acid.

Suitable examples of quinonediazides include o-quinonediazide compounds. The o-quinonediazide compound to be used in the invention is a compound containing at least one o-quinonediazide group, whose alkali solubility increases by heat decomposition, and compounds having various structures can be used. Namely, the o-quinonediazide assists dissolution of photosensitive materials due to both of an effect in which it loses dissolution inhibition of a binder by heat decomposition and an effect in which the o-quinonediazide itself converts into an alkali-soluble substance. Examples of o-quinonediazide compounds that are used in the invention include compounds described in J. Kosar, Light-Sensitive Systems, pp.339-352, John Wiley & Sons. Inc. Especially, sulfonic acid esters or sulfonic acid acids of o-quinonediazide reacted with various aromatic polyhydroxy compounds or aromatic amino compounds are suitable. Further, esters of benzoquinone-(1,2)-diazidosulfonic acid chloride or naphthoquinone-(1,2)-diazido-5-sulfonic acid chloride and a pyrrogallol-acetone resin described in JP-B No. 43-28403 and esters of benzoquinone-(1,2)-diazidosulfonic acid chloride or naphthoquinone-(1,2)-diazido-5-sulfonic acid chloride and a phenol-formaldehyde resin described in U.S. Pat. Nos. 3,046,120 and 3,188,210 are also suitably used.

In addition, esters of naphthoquinone-(1,2)-diazido-4-sulfonic acid chloride and a phenol-formaldehyde resin or a cresol-formaldehyde resin and esters of naphthoquinone-(1,2)-diazido-4-sulfonic acid chloride and a pyrrogallol-acetone resin are suitably used, too. Besides, useful o-quinonediazide compounds are reported in and known by various patents such as JP-A Nos. 47-5303, 48-63802, 48-63803, 48-96575, 49-38701 and 48-13354, JP-B Nos. 41-11222, 45-9610 and 49-17481, U.S. Pat. Nos. 2,797,213, 3,454,400, 3,544,323, 3,573,917, 3,674,495 and 3,785,825, British Patent Nos. 1,227,602, 1,251,345, 1,267,005, 1,329,888 and 1,330,932, and German Patent No. 854,890.

The addition amount of the o-quinonediazide compound is preferably in the range of 1 to 50% by mass, more preferably 5 to 30% by mass, and particularly preferably 10 to 30% by mass based on the whole of solid contents of the image forming material. Such o-quinonediazide compounds may be used alone or in admixture.

The addition amount of other additives than the o-quinonediazide compound is preferably in the range of 1 to 50% by mass, more preferably 5 to 30% by mass, and particularly preferably 10 to 30% by mass based on the whole of solid contents of the image forming material. Incidentally, in the invention, it is preferred to contain the additives and the binder in the same layer.

For the purpose of further enhancing the sensitivity, cyclic acid anhydrides, phenols, and organic acids can be used jointly. Specific examples of cyclic acid anhydrides include phthalic anhydride, tetrahydrophthalic anhydride, hexahydrophthalic anhydride, 3,6-endoxy-Δ⁴-tetrahydrophthalic anhydride, tetrachlorophthalic anhydride, maleic anhydride, chloromaleic anhydride, α-phenylmaleic anhydride, succinic anhydride, and pyromellitic anhydride, as described in U.S. Pat. No. 4,115,128. Examples of phenols include bisphenol A, p-nitrophenol, p-ethoxyphenol, 2,4,4′-trihydroxybenzophenone, 2,3,4-trihydroxybenzophenone, 4-hydroxybenzophenone, 4,4′,4″-trihydroxytriphenylmethane, and 4,4′,3″,4″-tetrahydroxy-3,5,3′,5′-tetramethyltriphenylmethane. In addition, examples of organic acids include sulfonic acids, sulfinic acids, alkylsulfuric acids, phosphonic acids, phosphoric acid esters, and carboxylic acids, as described in JP-A Nos. 60-88942 and 2-96755. Specific examples include p-toluenesulfonic acid, dodecylbenzenesulfonic acid, p-toluenesulfinic acid, ethylsulfuric acid, phenylphosphonic acid, phenylphosphinic acid, phenyl phosphonate, phenyl phosphinate, phenyl phosphate, diphenyl phosphate, benzoic acid, isophthalic acid, adipic acid, p-toluylic acid, 3,4-dimethoxybenzoic acid, phthalic acid, terephthalic acid, 4-cyclohexene-1,2-dicarboxylic acid, erucic acid, laurylic acid, n-undecanoic acid, and ascorbic acid. A proportion of the cyclic acid anhydrides, phenols or organic acids occupying in the image forming material is preferably from 0.05 to 20% by mass, more preferably from 0.1 to 15% by mass, and particularly preferably from 0.1 to 10% by mass.

In the invention, for widening stability of processings against the development condition, nonionic surfactants described in JP-A Nos. 62-251740 and 3-208514, ampholytic surfactants described in JP-A Nos. 59-121044 and 4-13149, cyclohexane based compounds described in European Patent No. 950,517, and fluorine-containing monomer copolymers described in JP-A No. 11-288093 can be added in the coating solution for image forming layer.

Specific examples of nonionic surfactants include sorbitan tristearate, sorbitan monopalmitate, sorbitan trioleate, stearic acid monoglyceride, and polyoxyethylene nonylphenyl ether. Specific examples of ampholytic surfactants include alkyl di(aminoethyl) glycines, alkyl polyaminoethyl glycine hydrochlorides, 2-alkyl-N-carboxyethyl-N-hydroxyethyl imidazolinium betaines, and N-tetradecyl-N,N-betaines (such as a trade name: AMOGEN K, manufactured by Daiichi Kogyo K. K.).

As siloxane based compounds, block copolymers of dimethylsiloxane and a polyalkylene oxide are preferable. Specific examples include polyalkylene oxide-modified silicones such as DBE-224, DBE-621, DBE-712, DBP-732 and DBP-534 (trade names, manufactured by Chisso Corporation) and TEGO GLIDE 100 (a trade name, manufactured by Tego Chemie Service GmbH, Germany).

A proportion of the nonionic surfactants or ampholytic surfactants occupying in the image forming material is preferably from 0.05 to 15% by mass, and more preferably from 0.1 to 5% by mass.

In the image forming layer of the invention, printing-out agents for obtaining visible images immediately after heating by exposure and dyes or pigments as image coloring agents can be added.

Representative examples of printing-out agents include combinations of a compound capable of releasing an acid upon heating by exposure (photo acid-releasing agent) and an organic dye capable of forming a salt. Specific examples include combinations of an o-naphthoquinonediazido-4-sulfonic acid halogenide and a salt-forming organic dye described in JP-A Nos. 50-36209 and 53-8128 and combinations of a trihalomethyl compound and a salt-forming organic dye described in JP-A Nos. 53-36223, 54-74728, 60-3626, 61-143748, 61-151644, and 63-58440. Examples of such trihalomethyl compounds include oxazole based compounds and triazine based compounds, and both of these compounds are excellent in stability with time and give distinct print-out images.

As image coloring agents, other dyes than the foregoing salt-forming organic dyes can be used. Examples of suitable dyes inclusive of salt-forming organic dyes include oil-soluble dyes and basic dyes. Specific examples include Oil Yellow # 101, Oil Yellow # 103, Oil Pink #312, Oil Green BG, Oil Blue BOS, Oil Blue #603, Oil Black BY, Oil Black BS and Oil Black T-505 (all being manufactured by Orient Chemical Industries, Ltd.), Victoria Pure Blue, Crystal Violet (CI42555), Methyl Violet (CI42535), Ethyl Violet, Rhodamine B (CI145170B), Malachite Green (CI42000), and Methylene Blue (CI52015). Further, dyes described in JP-A No. 62-293247 are particularly preferable. These dyes are used in a proportion of 0.01 to 10% by mass, and preferably 0.1 to 3% by mass based on the whole of solid contents of the image forming material. Further, for imparting flexibility of coating film, and the like., if desired, plasticizers are added in the image forming material of the invention. Examples include butyl phthalyl, polyethylene glycol, tributyl citrate, diethyl phthalate, dibutyl phthalate, dihexyl phthalate, dioctyl phthalate, tricresyl phosphate, tributyl phosphate, trioctyl phosphate, tetrahydrofurfuryl oleate, and oligomers and polymers of acrylic acid or methacrylic acid.

Besides, epoxy compounds, vinyl ethers, and additionally, hydroxymethyl group-containing phenol compounds and alkoxymethyl group-containing phenol compounds described in JP-A No. 8-276558, and crosslinking compounds having an alkaline dissolution inhibiting action described in JP-A No. 11-160860 as previously proposed by the present inventors can properly be added according to the purpose.

The image forming material of the invention is one comprising this image forming layer formed on a proper support and can be applied to various utilizations such as planographic printing plate precursors, colorproof materials, and display materials, and is especially useful as a heat mode type planographic printing plate precursor that can be subjected to direct plate making upon exposure with infrared laser.

<Planographic Printing Plate Precursor>

An embodiment in which the image forming material of the invention is applied as a planographic printing plate precursor will be specifically described below while referring to examples.

[Image Forming Layer]

A planographic printing plate precursor to which the image forming material of the invention is applied can be produced by dissolving components of coating solutions of image forming layer in a solvent and coating the solution on a proper support. Further, a protective layer, a resin interlayer, a backcoat layer, and the like. can be formed similarly according to the purpose.

Examples of solvents to be used herein include ethylene dichloride, cyclohexanone, methyl ethyl ketone, methanol, ethanol, propanol, ethylene glycol monomethyl ether, 1-methoxy-2-propanol, 2-methoxyethyl acetate, 1-methoxy-2-propyl acetate, dimethoxyethane, methyl lactate, ethyl lactate, N,N-dimethylacetamide, N,N-dimethylformamide, tetramethylurea, N-methylpyrrolidone, dimethyl sulfoxide, sulfolane, y-butyrolactone, and tolune. However, it should not be construed that the invention is limited thereto. These solvents may be used alone or in admixture.

The concentration of the foregoing components (the whole of solid contents including the additives) in the solvent is preferably from 1 to 50% by mass.

The coating amount (solids content) on the support obtained after coating and drying varies depending on the utility, but so far as image forming layers of planographic printing plate precursor are concerned, it is usually preferably from 0.5 to 5.0 g/m². As the coating amount decreases, the apparent sensitivity increases, but film characteristics of the image forming layer are lowered.

As the method of coating, various methods can be employed. Examples include bar coater coating, rotary coating, spray coating, curtain coating, dip coating, air knife coating, blade coating, and roll coating.

In the invention, surfactants for improving the coating property, such as fluorine based surfactants described in JP-A No. 62-170950, can be added to the image forming layer. The addition amount of such a surfactant is preferably from 0.01 to 1% by mass, and more preferably from 0.05 to 0.5% by mass in the whole of solid contents of the image forming layer.

[Resin Interlayer]

In the planographic printing plate precursor, it is possible to provide a resin interlayer between the image forming layer and the support, if desired.

By providing the resin interlayer, an infrared-sensitive layer (image recording layer) whose solubility in alkaline developing solutions increases upon exposure is provided on the exposure surface or in the vicinity thereof, whereby the sensitivity to infrared laser becomes better. Further, when a resin interlayer made of a high-molecular compound is provided between the support and the infrared-sensitive layer, the resin interlayer functions as a heat insulating layer. Accordingly, there gives rise to an advantage such that a heat generated by exposure with infrared laser does not diffuse into the support but is efficiently used for image formation, thereby achieving high sensitivity.

Further, in unexposed areas, the image recording layer that is non-penetrating against alkaline developing solutions functions itself as a protective layer of the resin interlayer, Accordingly, it is thought that not only development stability becomes good, but also images having excellent discrimination can be formed and that stability with time can be ensured.

Additionally, the resin interlayer is preferably constituted as a layer made of an alkali-soluble high-molecular compound as the major component and is extremely good in solubility in developing solutions. Accordingly, by providing such a resin interlayer in the vicinity of the support, even in the case where a developing solution whose activity has been lowered is used, when the components of the photosensitive layer whose dissolution inhibiting ability has been released by exposure are dissolved and dispersed in the developing solution, exposed areas are rapidly removed without generation of film retention, and the like. It is thought that this also contributes to an improvement of developability. From the foregoing reasons, it is thought that the resin interlayer is useful.

[Support]

The support that is used in the invention is a dimensionally stable sheet-like material. Examples include papers, papers laminated with plastics (such as polyethylene, polypropylene, and polystyrene), metal sheets (such as aluminum, zinc, and copper), and plastic films (such as cellulose diacetate, cellulose triacetate, cellulose propionate, cellulose butyrate, cellulose acetate butyrate, cellulose nitrate, polyethylene terephthalate, polyethylene, polystyrene, polypropylene, polycarbonate, and polyvinyl acetal), and the foregoing papers or plastic films laminated or vapor deposited with metals.

In the case where the invention is applied to a planographic printing plate precursor, polyester films or aluminum sheets are preferable as the support according to the invention. Of these, aluminum sheets that have good dimensional stability and are relatively cheap are particularly preferable. Suitable aluminum sheets are pure aluminum sheets and alloy sheets containing aluminum as a major component and trace amounts of foreign elements, and further, plastic films laminated or vapor deposited with aluminum may be employed. Examples of foreign elements contained in aluminum alloys include silicon, iron, manganese, copper, magnesium, chromium, zinc, bismuth, nickel, and titanium. The content of foreign elements in the alloy is at most 10% by mass. In the invention, pure aluminum is particularly suitable. However, since it is difficult to produce completely pure aluminum from the standpoint of refining technology, those containing slightly foreign elements may be used.

Aluminum sheets that are applied in the invention are not specified with respect to their compositions, and those that have hitherto been known and used can be properly utilized. The aluminum sheets that are applied in the invention have a thickness of about 0.1 to 0.6 mm, preferably 0.15 to 0.4 mm, and particularly preferably 0.2 to 0.3 mm.

Prior to roughing the aluminum sheet, if desired, the aluminum sheet is subjected to degreasing processing with, for example, a surfactant, an organic solvent or an alkaline aqueous solution for the purpose of removing a rolling oil on the surface. The roughing processing of the surface of the aluminum shesan be carried out by various methods such as a method of mechanically roughing the surface, a method of electrochemically dissolving and roughing the surface, and a method of chemically selectively dissolving the surface. As the mechanical method, known methods such as ball polishing, brush polishing, blast polishing, and buff polishing can be employed. As the electrochemical roughing method, a method of using an alternating current or direct current in a hydrochloric acid or nitric acid electrolytic solution can be employed. Further, a combination of the both methods as disclosed in JP-A No. 54-63902 can also be employed. The thus roughed aluminum sheet is subjected to alkali etching processing and neutralization processing as the need arises. Thereafter, if desired, the aluminum sheet is further subjected to anodic oxidation processing for the purpose of enhancing water retention and ablation resistance of the surface. As electrolytes to be used for the anodic oxidation processing of the aluminum sheet, various electrolytes capable of forming a porous oxidized film can be used. In general, sulfuric acid, phosphoric acid, oxalic acid, chromic acid, or mixed acids thereof can be used. A concentration of such an electrolyte is properly determined depending on the kind of electrolyte.

The processing condition of the anodic oxidation varies depending on the electrolyte and hence, cannot be unequivocally specified. In general, it is proper that: the concentration of electrolyte is from 1 to 80% by mass, the liquid temperature is from 5 to 70° C., the current density is from 5 to 60 A/dm², the voltage is from 1 to 100 V, and the electrolysis time is from 10 seconds to 5 minutes. When the amount of the anodically oxidized film is less than 1.0 g/m², press life is liable to be insufficient, or scuffs are likely formed in non-image areas of planographic printing plate, whereby so-called “scuff stain” in which an ink easily adheres to scuffs during printing is likely generated. After the anodic oxidation processing, the aluminum surface is subjected to hydrophilic processing. Examples of the hydrophilic processing that is used in the invention include a method of using alkali metal silicates (such as a sodium silicate aqueous solution) as disclosed in U.S. Pat. Nos. 2,714,066, 3,181,461, 3,280,734, and 3,902,734. According to this method, the support is subjected to dip processing or electrolysis processing with a sodium silicate aqueous solution. Besides, there are employed a method of processing with potassium fluorozirconate as disclosed in JP-B No. 36-22063 and a method of processing with polyvinylphosphonic acid as disclosed in U.S. Pat. Nos. 3,276,868, 4,153,461 and 4,689,272.

The planographic printing plate precursor to which the image forming material of the invention is applied is one comprising a positive image forming layer provided on the support, and an undercoating layer can be provided therebetween as the need arises.

As components of the undercoating layer, various organic compounds are used. Examples include carboxymethyl cellulose; dextrin; gum arabic; amino group-containing phosphonic acids such as 2-aminoethylphosphonic acid; optionally substituted organic phosphonic acids such as phenylphosphonic acid, naphthylphosphonic acid, alkylphosphonic acids, glycerophosphonic acid, methylenediphosphonic acid, and ethylenediphosphonic acid; optionally substituted organic phosphoric acids such as phenylphosphoric acid, naphthylphosphoric acid, alkylphosphoric acids, and glycerophosphoric acid; optionally substituted organic phosphinic acids scuh as phenylphosphinic acid, naphthylphosphinic acid, alkylphosphinic acids, and glycerophosphinic acid; amino acids such as glycine and β-alanine; and hydroxyl group-containing amino hydrochlorides such as triethanolamine hydrochloride. These compounds may be used in admixture of two or more thereof.

This organic undercoating layer can be provided in the following methods. That is, there are a method in which a solution of the organic compound dissolved in water or an organic solvent such as methanol, ethanol, and methyl ethyl ketone is coated on an aluminum sheet and dried to provide an organic undercoating layer; and a method in which an aluminum sheet is dipped in a solution of the organic compound dissolved in water or an organic solvent such as methanol, ethanol, and methyl ethyl ketone to adsorb the compound on the aluminum sheet, which is then rinsed with water, and the like. and dried to provide an organic undercoating layer. In the former method, a solution of the organic compound having a concentration of 0.005 to 10% by mass can be coated in various methods.

In the latter method, the concentration of the solution is from 0.01 to 20% by mass, and preferably from 0.05 to 5% by mass; the dipping temperature is from 20 to 90° C., and preferably from 25 to 50° C.; and the dipping time is from 0.1 seconds to 20 minutes, and preferably from 2 seconds to one minute. It is possible to adjust the solution as used herein so as to have a pH in the range of 1 to 12 with basic substances such as ammonia, triethylamine, and potassium hydroxide, or acidic substances such as hydrochloric acid and phosphoric acid. For improving tone reproducibility of image recording materials, yellow dyes may be added.

A coverage of the organic undercoating layer is suitably from 2 to 200 mg/m², and preferably from 5 to 100 mg/m². When the coverage is less than 2 mg/m², sufficient press life cannot be obtained. When it exceeds 200 mg/m², sufficient press life cannot be obtained, too.

[Exposure and Development]

The thus prepared positive planographic printing plate precursor is usually imagewise exposed and then developed.

As light sources of rays to be used for imagewise exposure, light sources having an light-emitting wavelength in near infrared to infrared revisions are preferable, and solid lasers and semiconductor lasers are particularly preferable.

As the developing solution and a replenisher thereof of the planographic printing plate precursor to which the image forming material of the invention is applied, conventionally known alkaline aqueous solutions can be used.

Examples include inorganic alkali salts such as sodium silicate, potassium silicate, sodium tertiary phosphate, potassium tertiary phosphate, ammonium tertiary phosphate, sodium secondary phosphate, potassium secondary phosphate, ammonium secondary phosphate, sodium carbonate, potassium carbonate, ammonium carbonate, sodium hydrogencarbonate, potassium hydrogencarbonate, ammonium hydrogencarbonate, sodium borate, potassium borate, ammonium borate, sodium hydroxide, ammonium hydroxide, potassium hydroxide, and lithium hydroxide; and organic alkaline agents such as monomethylamine, dimethylamine, trimethylamine, monoethylamine, diethylamine, triethylamine, monoisopropylamine, diisopropylamine, triisopropylamine, n-butylamine, monoethanolamine, diethanolamine, triethanolamine, monoiso-propanolamine, diisopropanolamine, ethyleneimine, ethylenediamine, and pyridine. These alkaline agents may be used alone or in combination of two or more thereof.

Of these alkaline developing solutions are particularly preferable aqueous solutions of silicates such as sodium silicate and potassium silicate. This is because it is possible to adjust the developability by a ratio of silicon oxide SiO₂ as the component of the silicate to an alkali metal oxide M₂O and a concentration thereof. For example, alkali metal silicates described in JP-A No. 54-62004 and JP-B No. 57-7427 are effectively used.

In addition, in the case where development is carried out using an automatic processor, it is known that by adding one the same as in the developing solution or an aqueous solution (replenisher) having a higher alkaline strength than the developing solution to the developing solution, a large amount of planographic printing plate precursors can be processed without exchanging the developing solution as used in a developing bath over a long period of time. This method is suitably applied, too in the invention.

For the purposes of accelerating or retarding developability, diffusing development scums, and enhancing ink-philic property of image areas of printing plates, various surfactants and organic solvents can be added to the developing solution and replenisher, as the need arises.

As surfactants are preferable anionic, cationic, nonionic and ampholytic surfactants. Also, it is possible to add hydroquinone, resorcin, inorganic salt based reducing agents such as sodium salts and potassium salts of inorganic acids such as sulfurous acid and hydrogensulfurous acid, organic carboxylic acids, defoaming agent, or hard water softeners to the developing solution and replenisher, as the need arises.

The printing plate thus developed using the developing solution and replenisher is subjected to post treatment with, for example, washing water, a rinse solution containing a surfactant, and a desensitizing solution containing gum arabic and starch derivatives. In the invention, in the case where the image forming material is used as a printing plate, these treatments can be employed through various combinations as the post treatment.

In recent years, in the industries of plate making and printing, for the purposes of rationalization and standardization, an automatic processor for printing plate is widely used. Such an automatic processor generally includes a development section and a post treatment section and further includes a unit for conveying a printing plate and respective processing solution tanks and spray units, in which an exposed printed plate is conveyed horizontally and developed while spraying each of processing solutions drawn up by a pump from spray nozzles. Further, recently, there is also known a method in which a printing plate is processed in a processing solution tank filled with a processing solution while dipping and conveying by guide rollers. In such automatic processing, the processing can be performed while replenishing a replenisher to each processing solution according to the processing amount and operation time. Moreover, a so-called non-returnable processing system of treating with a substantially virgin processing solution can also be applied.

In the invention, in the case where a planographic printing plate obtained by imagewise exposing, developing and water washing and/or rinsing and/or gumming includes unnecessary image areas (for example, film edge marks of original image film), the unnecessary image areas are erased. For achieving erasion, it is preferred to employ a method in which an erasing solution described in JP-B No. 2-13293 is coated on unnecessary image areas, and the coated unnecessary image areas are allowed to stand for a while as they are and then washed with water. Also, there can be utilized a method in which unnecessary image areas are irradiated with actinic rays introduced through an optical fiber and then developed described in JP-A No. 59-174842.

The thus obtained planographic printing plate can be provided for printing step after coating a desensitizing gum, if desired. In the case where a planographic printing plate is required to have higher press life, the planographic printing plate is subjected to burning processing. In the case where a planographic printing plate is subjected to burning processing, it is preferred to treat the planographic printing plate with a surface conditioning solution described in JP-B Nos. 61-2518 and 55-28062, JP-A Nos. 62-31859 and 61-159655 prior to the burning processing.

Examples of methods of performing such processing include a method in which a surface conditioning solution is coated on a planographic printing plate using a sponge or absorbent cotton impregnated with the surface conditioning solution, a method in which the planographic printing plate is dipped in a vat filled with a surface conditioning solution and coated with the surface conditioning solution, and a method in which a surface conditioning solution is coated using an automated coater. Further, what a coating amount is made uniform after coating by a squeegee or a squeegee roller gives rise more preferred results.

A suitable coating amount of the surface conditioning solution is in general from 0.03 to 0.8 g/m² (on a dry mass). The surface conditioning solution-coated planographic printing plate is heated at high temperatures by a burning processor (for example, a burning processor “BP-1300” (trade name) sold by Fuji Photo Film Co., Ltd.), and the like. after drying, as the need arises. In this case, the heating temperature and time vary depending on the kind of components forming an image, and the heating is preferably carried out at from 180 to 300° C. for from 1 to 20 minutes.

If desired, the burning processed planographic printing plate can be properly subjected to conventionally employed processings such as water washing and gumming. In the case where a surface conditioning solution containing a water-soluble high-molecular compound is used, so-called desensitizing processing such as gumming can be omitted. The planographic printing plate thus obtained through such processings is fixed in an offset printer and used for producing a number of prints.

### EXAMPLES

The present invention will be described below with reference to the following Examples, but it should not be construed that the invention is limited thereto.

[Preparation of Substrate A]

A 0.24 mm-thick aluminum plate (an aluminum alloy containing 0.06% by mass of Si, 0.30% by mass of Fe, 0.014% by mass of Cu, 0.001% by mass of Mn, 0.001% by mass of Mg, 0.001% by mass of Zn, and 0.03% by mass of Ti, with the remainder being Al and inevitable impurities) was subjected continuously to the following processings.

The aluminum plate was subjected to continuous electrochemical roughing processing using an alternating current of 60 Hz. At this time, an electrolytic solution that was used was an aqueous solution of 10 g/L of nitric acid (containing 5 g/L of aluminum ions and 0.007% by mass of ammonium ions) at a temperature of 80° C. After washing with water, the aluminum plate was subjected to etching processing at 32° C. by spraying a solution having a sodium hydroxide concentration of 26% by mass and an aluminum ion concentration of 6.5% by mass to dissolve 0.20 g/m² of the aluminum plate, followed by washing with water by spraying. Thereafter, the aluminum plate was subjected to desmutting processing by spraying an aqueous solution having a sulfuric acid concentration of 25% by mass (containing 0.5% by mass of aluminum ions) at a temperature of 60° C. and washed with water by spraying.

The aluminum plate was subjected to anodic oxidation processing using an anodic oxidation system by two-stage feeding electrolysis processing. Sulfuric acid was used as an electrolytic solution to be supplied in an electrolysis section. Thereafter, the aluminum plate was washed with water by spraying. A final amount of oxidized film was 2.7 g/m².

The aluminum support obtained by anodic oxidation processing was treated with an alkali metal silicate (silicate processing) by dipping in a processing bath containing a 1% by mass aqueous solution of No. 3 sodium silicate at a temperature of 30° C. for 10 seconds. Thereafter, the aluminum support was washed with water by spraying.

An undercoating solution having the following composition was coated on the thus obtained aluminum support after treatment with an alkali metal silicate and dried at 80° C. for 15 seconds to form a coating film, whereby a substrate A was obtained. After drying, the coating film had a coverage of 15 mg/m².

<Composition of Undercoating Solution>

| | | |
|---|---|---|
| Compound as shown below: | 0.3 | g |
| Methanol: | 100 | g |
| Water: | 1 | g |

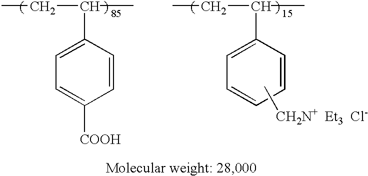

[Preparation of Substrate B]

A 0.24 mm-thick aluminum plate (an aluminum alloy containing 0.06% by mass of Si, 0.30% by mass of Fe, 0.014% by mass of Cu, 0.001% by mass of Mn, 0.001% by mass of Mg, 0.001% by mass of Zn, and 0.03% by mass of Ti, with the remainder being Al and inevitable impurities) was subjected continuously to the following processings.

The surface of the aluminum plate was mechanically roughed using a rotating roller-shaped nylon brush while supplying a suspension of a polishing agent (quartz sand) and water with a specific gravity of 1.12 as a polishing slurry liquid. Thereafter, the aluminum plate was subjected to etching processing at 70° C. by spraying a solution having a sodium hydroxide concentration of 2.6% by mass and an aluminum ion concentration of 6.5% by mass to dissolve 6 g/m² of the aluminum plate, followed by washing with water by spraying. Further, the aluminum plate was subjected to desmutting processing by spraying an aqueous solution having a nitric acid concentration of 1% by mass (containing 0.5% by mass of aluminum ions) at a temperature of 30° C. and washed with water by spraying. Thereafter, the aluminum plate was subjected to continuous electrochemical roughing processing using an alternating current of 60 Hz. At this time, an electrolytic solution was an aqueous solution of 10 g/L of nitric acid (containing 5 g/L of aluminum ions and 0.007% by mass of ammonium ions) at a temperature of 80° C. After washing with water, the aluminum plate was subjected to etching processing at 32° C. by spraying a solution having a sodium hydroxide concentration of 26% by mass and an aluminum ions concentration of 6.5% by mass to dissolve 0.20 g/m² of the aluminum plate, followed by washing with water by spraying. Thereafter, the aluminum plate was subjected to desmutting processing by spraying an aqueous solution having a sulfuric acid concentration of 25% by mass (containing 0.5% by mass of aluminum ions) at a temperature of 60° C. and washed with water by spraying.

The aluminum plate was subjected to anodic oxidation processing using an anodic oxidation system by two-stage feeding electrolysis processing. Sulfuric acid was used as an electrolytic solution to be supplied in an electrolysis section. Thereafter, the aluminum plate was washed with water by spraying. A final amount of oxidized film was 2.7 g/m².

The aluminum support obtained by anodic oxidation processing was treated with an alkali metal silicate (silicate processing) by dipping in a processing bath containing a 1% by mass aqueous solution of No. 3 sodium silicate at a temperature of 30° C. for 10 seconds. Thereafter, the aluminum support was washed with water by spraying.

An undercoating solution having the following composition was coated on the thus obtained aluminum support after treatment with an alkali metal silicate and dried at 80° C. for 15 seconds to form a coating film, whereby a substrate B was obtained. After drying, the coating film had a coverage of 15 mg/m².

<Composition of Undercoating Solution>

| | | |
|---|---|---|
| Compound as shown below: | 0.3 | g |
| Methanol: | 100 | g |
| Water: | 1 | g |

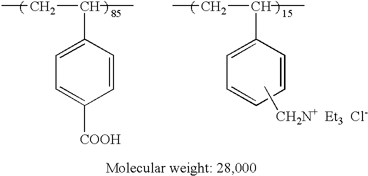

[Synthesis of Copolymer]

In a 500-mL three-necked flask equipped with a stirrer, a condenser and a dropping funnel, 31.0 g (0.36 moles) of methacrylic acid, 39.1 g (0.36 moles) of ethyl chloroformate, and 200 mL of acetonitrile were charged, and the mixture was stirred while being cooled in an ice water bath. To this mixture, 36.4 g (0.36 moles) of triethylamine was added dropwise from the dropping funnel over about 1 hour. After completion of the dropwise addition, the ice water bath was removed, and the resulting mixture was stirred at room temperature for 30 minutes.

To the reaction mixture, 51.7 g (0.30 moles) of p-aminobenzenesulfonamide was added, and the mixture was stirred for 1 hour while being warmed it at 70° C. in an oil bath. After completion of the reaction, the mixture was added to one liter of water while the water was stirred, and the resulting mixture was stirred for 30 minutes. The mixture was subjected to filtration, and deposits were taken out and formed into a slurry with 500 mL of water. The slurry was subjected to filtration, and the resulting solid was dried to obtain a white solid of N-(p-aminosulfonylphenyl)methacrylamide (yield: 46.9 g).

Next, 4.61 g (0.0192 moles) of N-(p-aminosulfonylphenyl)-methacrylamide, 2.58 g (0.0258 moles) of ethyl methacrylate, 0.80 g (0.015 moles) of acrylonitrile, and 20 g of N,N-dimethylacetamide were charged in a 200-mL three-necked flask equipped with a stirrer, a condenser and a dropping funnel, and the mixture was stirred while being heated at 65° C. in a warm water bath. To this mixture, 0.15 g of 2,2′-azobis(2,4-dimethylvaleronitrile) (a trade name: V-65, manufactured by Wako Pure Chemical Industries, Ltd.) was added as a polymerization initiator, and the mixture was stirred under a nitrogen gas stream for 2 hours while being kept it at 65° C. A mixture of 4.61 g of N-(p-aminosulfonylphenyl)methacrylamide, 2.58 g of methyl methacrylate, 0.80 g of acrylonitrile, 20 g of N,N-dimethylacetamide, and 0.15 g of the aforementioned V-65 was further added dropwise to the reaction mixture from the dropping funnel over 2 hours. After completion of the dropwise addition, the resulting mixture was stirred at 65° C. for an additional 2 hours. After completion of the reaction, 40 g of methanol was added to the reaction mixture, and the mixture was cooled. The resulting mixture was added to two liters of water while the water was stirred, and the mixture was stirred for 30 minutes. Deposits were taken out by filtration and dried to obtain 15 g of a white solid. This copolymer was measured by gel permeation chromatography and found to have a weight average molecular weight (polystyrene standard) of 54,000.

### Examples 1 to 8

[Preparation of Planographic Printing Plate Precursor]

On the obtained substrate A, the following coating solution 1 for an mage forming layer was coated in a coating amount of 0.85 g/m² and dried at 110° C. for 50 seconds by a PERFECT OVEN PH200 (manufactured by TABAI ESPEC CORP.) while the wind control set at 7. Thereafter, the following coating solution 2 for an image forming layer was coated in a coating amount of 0.30 g/m² and then dried at 120° C. for one minute, whereby planographic printing plate precursors were obtained.

<Coating Solution 1 for Image Forming Layer>

| | |
|---|---|
| Copolymer as described above: | 2.133 g |
| Specific IR coloring material shown in Table 20: | 0.109 g |
| 4,4′-Bishydroxyphenylsulfone: | 0.126 g |
| Cis-Δ⁴-tetrahydrophthalic anhydride: | 0.190 g |
| p-Toluenesulfonic acid: | 0.008 g |
| 3-Methoxy-4-diazodiphenylamine hexafluoro- | 0.030 g |
| phosphate: | |
| Ethyl Violet whose counter ion is changed to an anion of | 0.100 g |
| 6-hydroxy-2-naphthalenesulfonic acid: | |
| MEGAFAC F-176 (a trade name for surface property | 0.035 g |
| improving fluorine based surfactant, manufactured by | |
| Dainippon Ink and Chemicals, Incorporated): | |
| Methyl ethyl ketone: | 25.38 g |
| 1-Methoxy-2-propanol: | 13.0 g |
| γ-Butyrolactone: | 13.2 g |

<Coating Solution 2 for Image Forming Layer>

| | | |
|---|---|---|
| m,p-Cresol novolac | 0.3478 | g |
| (m/p ratio: 6/4, weight average molecular weight: | | |
| 4,500, containing 0.8% by weight of unreacted cresols): | | |
| Specific IR coloring material shown in Table 20: | 0.011 | g |
| Ethyl Violet whose counter ion is changed to 6- | 0.010 | g |
| hydroxy-2-naphthalenesulfonic acid: | | |
| Ammonium salt compound (1) having a structure as | 0.010 | g |
| shown below: | | |
| MEGAFAC F-176 (20%)(a trade name for surface | 0.022 | g |
| property improving surfactant, manufactured by | | |
| Dainippon Ink and Chemicals, Incorporated): | | |
| Methyl ethyl ketone: | 13.7 | g |
| 1-Methoxy-2-propanol: | 6.79 | g |

Ammonium salt compound (1)

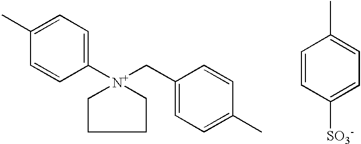

### Comparative Example 1

A planographic printing plate precursor was obtained in the same manner as in the foregoing Examples 1 to 8, except for using coating solutions prepared by adding a cyanine dye CD-X having the following structure in place of the specific IR coloring materials shown in Table 20 in the coating solutions 1 and 2 for image forming layer.

Cyanine Dye CD-X

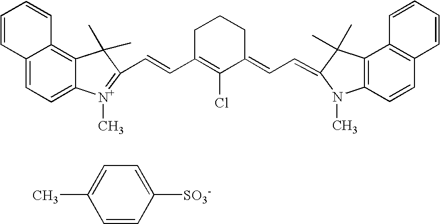

[Evaluation of Planographic Printing Plate Precursor]

Each of the thus obtained planographic printing plate precursors was evaluated using the following method. The evaluation results are also shown in Table 20.

(Sensitivity)

The obtained planographic printing plate precursor had a solid image drawn thereon using a TRENDSETTER (a trade name, manufactured by Creo Inc.) at a beam strength in the range of from 2 to 10 W and at a drum rotation speed of 150 rpm and was then developed for 12 seconds using a PS processor, LP940H (a trade name, manufactured by Fuji Photo Film Co., Ltd.) charged with a developing solution, DT-2 (a trade name, manufactured by Fuji Photo Film Co., Ltd.), (diluted at 1/8) and a finisher, FG-1 (a trade name, manufactured by Fuji Photo Film Co., Ltd.), (diluted at 1/1) while keeping a liquid temperature at 30° C. At this time, the developing solution had a conductivity of 43 mS/cm.

After the development, the printing plate precursor was observed with a loupe with a magnification of 25 times, and the presence or absence of film retention at a level at which printing staining did not substantially occur was evaluated. Then, an actual exposure energy was calculated from an exposure beam intensity at which no film retention was observed and defined as a sensitivity. According to the evaluation, the smaller the exposure energy is, the higher the sensitivity is.

(Development Latitude)

The obtained planographic printing plate precursor had a test pattern thereon using a TRENDSETTER (a trade name, manufactured by Creo Inc.) at a beam strength of 9 W and at a drum rotation speed of 150 rpm and 2 was then developed for 12 seconds using a PS processor, LP940H (a trade name, manufactured by Fuji Photo Film Co., Ltd.), charged with a solution obtained by diluting a developing solution, DT-2R (a trade name, manufactured by Fuji Photo Film Co., Ltd.), at 1/5 and blowing a carbon dioxide gas thereinto until the conductivity reached 37 mS/cm and a finisher, FG-1 (a trade name, manufactured by Fuji Photo Film Co., Ltd.), (diluted at 1/1) while keeping a liquid temperature at 30° C. Thereafter, a suitable amount of DT-2R (diluted at 1/5) was added to the developing solution to adjust the conductivity to 39 mS/cm, and a planographic printing plate precursor on which a test pattern had been similarly imagewise drawn was developed. Further, the conductivity was increased by 2 mS/cm at a time, and this operation was continued until film diminishment due to development of the image was significantly observed.

At this time, the presence or absence of staining or coloration caused by film retention of the image forming layer due to development failure was confirmed for the printing plate developed at each of the conductivities, and a conductivity of the developing solution at which the development could be performed well was determined. Next, a critical conductivity at which the development film diminishment was kept at a level such that printing resistance was not substantially influenced was determined.

A range between the conductivity of the developing solution at which the development could be performed well and the critical conductivity at which the development film diminishment was kept at a level such that printing resistance was not substantially influenced was defined as development latitude.

Incidentally, the wider the range of development latitude is, the larger the difference between solubilities in developing solutions at exposed areas and unexposed areas (solubility discrimination) which is one of the effects of the invention.

TABLE 20

| | Specific IR | Specific IR | | |
|---|---|---|---|---|
| | coloring | coloring | | |
| | material | material | | |
| | (Coating | (Coating | | |
| | solution | solution | | Development |
| | 1 for image | 2 for image | Sensitivity | latitude |
| | forming layer) | forming layer) | (mJ/cm²) | (mS/cm) |
| Example 1 | CD-1 | CD-1 | 105 | 10 |
| Example 2 | CD-10 | CD-10 | 100 | 10 |
| Example 3 | CD-27 | CD-27 | 100 | 10 |
| Example 4 | CD-38 | CD-38 | 105 | 12 |
| Example 5 | CD-50 | CD-50 | 105 | 10 |
| Example 6 | PD-3 | PD-3 | 110 | 12 |
| Example 7 | PD-19 | PD-19 | 110 | 10 |
| Example 8 | AD-2 | AD-2 | 110 | 12 |
| Comparative | CD-X* | CD-X* | 135 | 8 |
| Example 1 | | | | |

*A general cyanine dye CD-X was used in place of the specific IR coloring material according to the invention.

As is clear from Table 20, it was confirmed that the planographic printing plate precursors of Examples 1 to 8 using the specific IR coloring material according to the invention can achieve high sensitivity together with a wide development latitude better than the planographic printing plate precursor of Comparative Example 1 having a generally widely employed cyanine dye CD-X added thereto.

### Examples 9 to 16

[Preparation of Planographic Printing Plate Precursor]

On the substrate A, the following coating solution 3 for an image forming layer was coated in a coating amount of 1.00 g/m² and dried at 110° C. for 50 seconds by a PERFECT OVEN PH200 (manufactured by TABAI ESPEC CORP.) with the wind control set at 7. Thereafter, the following coating solution 4 for an image forming layer was coated in a coating amount of 0.24 g/m² and then dried at 120° C. for one minute, whereby planographic printing plate precursors were obtained.

<Coating Solution 3 for Image Forming Layer>

| | |
|---|---|
| Copolymer as described above: | 2.133 g |
| Specific IR coloring material shown in Table 21: | 0.109 g |
| 4,4′-Bishydroxyphenylsulfone: | 0.125 g |
| Cis-Δ⁴-tetrahydrophthalic anhydride: | 0.190 g |
| p-Toluenesulfonic acid: | 0.008 g |
| 3-Methoxy-4-diazodiphenylamine hexafluoro- | 0.030 g |
| phosphate: | |
| Ethyl Violet whose counter ion is changed to an anion | 0.100 g |
| of 6-hydroxy-2-naphthalenesulfonic acid: | |
| MEGAFAC F-176 | 0.035 g |
| (a trade name for surface property improving fluorine | |
| based surfactant, manufactured by Dainippon Ink and | |
| Chemicals, Incorporated): | |
| Methyl ethyl ketone: | 25.38 g |
| 1-Methoxy-2-propanol: | 13.0 g |
| γ-Butyrolactone: | 13.2 g |

<Coating Solution 4 for Image Forming Layer>

| | |
|---|---|
| m,p-Cresol novolac | 0.320 g |
| (m/p ratio: 6/4, weight average molecular weight: | |
| 4,500, containing 0.8% by weight of unreacted | |
| cresols): | |
| Specific IR coloring material shown in Table 21: | 0.010 g |
| Copolymer of ethyl methacrylate and 2- | 0.030 g |
| methacryloyloxyethyl succinic acid | |
| (molar ratio: 67/33, weight average molecular weight: | |
| 92,000): | |
| Ethyl Violet whose counter ion is changed to 6- | 0.012 g |
| hydroxy-2-naphthalenesulfonic acid: | |
| MEGAFAC F-176 (20%) | 0.022 g |
| (a trade name for surface property improving | |
| surfactant, manufactured by Dainippon Ink and | |
| Chemicals, Incorporated): | |
| Methyl ethyl ketone: | 13.07 g |
| 1-Methoxy-2-propanol: | 6.79 g |

### Comparative Example 2

A planographic printing plate precursor was obtained in the same manner as in the foregoing examples 9 to 16, except for using coating solutions prepared by adding the cyanine dye CD-X described in comparative example 1 in place of the specific IR coloring materials shown in Table 21 in the coating solutions 3 and 4 for image forming layer.

[Evaluation of Planographic Printing Plate Precursor]

Each of the thus obtained planographic printing plate precursors was evaluated with respect to the sensitivity and development latitude in the same manners as in Examples 1 to 8. The evaluation results are also shown in Table 21.

TABLE 21

| | Specific IR | Specific IR | | |
|---|---|---|---|---|
| | coloring | coloring | | |
| | material | material | | |
| | (Coating | (Coating | | |
| | solution | solution | | Development |
| | 3 for image | 4 for image | Sensitivity | latitude |
| | forming layer) | forming layer) | (mJ/cm²) | (mS/cm) |
| Example 9 | CD-2 | CD-2 | 95 | 10 |
| Example 10 | CD-17 | CD-17 | 95 | 10 |
| Example 11 | CD-29 | CD-29 | 90 | 10 |
| Example 12 | CD-36 | CD-36 | 95 | 12 |
| Example 13 | CD-3 | CD-54 | 95 | 10 |
| Example 14 | CD-1 | PD-1 | 100 | 12 |
| Example 15 | PD-2 | PD-22 | 105 | 10 |
| Example 16 | AD-6 | CD-27 | 105 | 12 |
| Comparative | CD-X* | CD-X* | 125 | 8 |
| Example 2 | | | | |

*A general cyanine dye CD-X was used in place of the specific IR coloring material according to the invention.

As is clear from Table 21, it was confirmed that the planographic printing plate precursors of Examples 9 to 16 using the specific IR coloring material according to the invention can achieve high sensitivity together with a wide development latitude better than the planographic printing plate precursor of Comparative Example 2 having a generally widely employed cyanine dye CD-X added thereto.

### Examples 17 to 24

[Preparation of Planographic Printing Plate Precursor]

On the substrate B, the following coating solution 5 for an image forming layer was coated in a coating amount of 1.00 g/m² and dried at 110° C. for 50 seconds by a PERFECT OVEN PH200 (manufactured by TABAI ESPEC CORP.) with the wind control set at 7. Thereafter, the following coating solution 6 for an image forming layer was coated in a coating amount of 0.30 g/m² and then dried at 120° C. for one minute, whereby planographic printing plate precursors were obtained.

<Coating Solution 5 for Image Forming Layer>

| | |
|---|---|
| Copolymer as described above: | 2.133 g |
| Specific IR coloring material shown in Table 22: | 0.109 g |
| 2-Mercapto-5-methylthio-1,3,4-thiadiazole: | 0.120 g |
| 4,4′-Bishydroxyphenylsulfone: | 0.075 g |
| Cis-Δ⁴ -tetrahydrophthalic anhydride: | 0.120 g |
| p-Toluenesulfonic acid: | 0.008 g |
| 3-Methoxy-4-diazodiphenylamine hexafluoro- | 0.030 g |
| phosphate: | |
| Victoria Pure Blue whose counter ion is changed to an | 0.100 g |
| anion of 6-hydroxy-2-naphthalenesulfonic acid: | |
| MEGAFAC F-176 | 0.035 g |
| (a trade name for surface property improving fluorine | |
| based surfactant, manufactured by Dainippon Ink and | |
| Chemicals, Incorporated): | |
| Methyl ethyl ketone: | 25.38 g |
| 1-Methoxy-2-propanol: | 13.0 g |
| γ-Butyrolactone: | 13.2 g |

<Coating Solution 6 for Image Forming Layer>

| | | |
|---|---|---|
| m,p-Cresol novolac | 0.320 | g |
| (m/p ratio: 6/4, weight average molecular weight: 4,500, | | |
| containing 0.8% by weight of unreacted cresols): | | |
| Specific IR coloring material shown in Table 22: | 0.0120 | g |
| Ethyl Violet whose counter ion is changed to an anion of | 0.030 | g |
| 6-hydroxy-2-naphthalenesulfonic acid: | | |
| Copolymer of ethyl methacrylate and 2- | 0.030 | g |
| methacryloyloxyethyl succinic acid (molar ratio: 67/33, | | |
| weight average molecular weight: 92,000): | | |
| Ammonium salt compound (2) having a structure as | 0.0080 | g |
| shown below: | | |
| MEGAFAC F-176 (20%) (a trade name for surface property | 0.022 | g |
| improving surfactant, manufactured by Dainippon Ink | | |
| and Chemicals, Incorporated): | | |
| Methyl ethyl ketone: | 13.07 | g |
| 1-Methoxy-2-propanol: | 6.79 | g |

Ammonium salt compound (2)

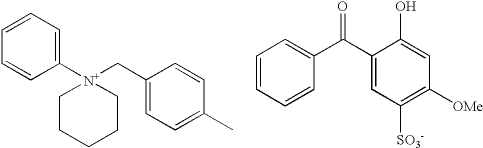

### Comparative Example 3

A planographic printing plate precursor was obtained in the same manner as in the foregoing Examples 17 to 24, except for using coating solutions prepared by adding the cyanine dye CD-X described in Comparative Example 1 in place of the specific IR coloring materials shown in Table 22 in the coating solutions 5 and 6 for image forming layer.

[Evaluation of Planographic Printing Plate Precursor]

Each of the thus obtained planographic printing plate precursors was evaluated with respect to the sensitivity and development latitude in the same manners as in Examples 1 to 8. The evaluation results are also shown in Table 22.

TABLE 22

| | Specific IR | Specific IR | | |
|---|---|---|---|---|
| | coloring | coloring | | |
| | material | material | | |
| | (Coating | (Coating | | |
| | solution | solution | | Development |
| | 5 for image | 6 for image | Sensitivity | latitude |
| | forming layer) | forming layer) | (mJ/cm²) | (mS/cm) |
| Example 17 | CD-5 | CD-5 | 85 | 10 |
| Example 18 | CD-16 | CD-16 | 80 | 10 |
| Example 19 | CD-20 | CD-27 | 80 | 10 |
| Example 20 | CD-38 | CD-60 | 85 | 12 |
| Example 21 | CD-50 | CD-X | 100 | 10 |
| Example 22 | CD-8 | PD-3 | 90 | 12 |
| Example 23 | CD-22 | PD-6 | 85 | 10 |
| Example 24 | CD-2 | AD-12 | 85 | 12 |
| Comparative | CD-X* | CD-X* | 115 | 8 |
| Example 3 | | | | |

*A general cyanine dye CD-X was used in place of the specific IR coloring material according to the invention.

As is clear from Table 22, it was confirmed that the planographic printing plate precursors of Examples 17 to 24 using the specific IR coloring material according to the invention can achieve high sensitivity together with a wide development latitude better than the planographic printing plate precursor of Comparative Example 3 having a generally widely employed cyanine dye CD-X added thereto.

### Examples 25 to 32

[Preparation of Planographic Printing Plate Precursor]

On the substrate B, the following coating solution 7 for an image forming layer was coated in a coating amount after drying of 1.2 g/m², whereby planographic printing plate precursors were obtained.

<Coating Solution 7 for Image Forming Layer>

| | | |
|---|---|---|
| Fluorine-containing polymer | 0.03 | g |
| (having a structure as shown below): | | |
| Copolymer as described above: | 0.75 | g |
| Novolac (m/p = 6/4, Mw = 4,000): | 0.20 | g |
| Tetrapropylammonium p-hydroxybenzenesufonate: | 0.04 | g |
| Cis-Δ⁴-tetrahydrophthalic anhydride: | 0.03 | g |
| Specific IR coloring material shown in Table 23: | 0.023 | g |
| Dye in which a counter ion of Victoria Pure Blue BOH is | 0.015 | g |
| a 1-naphthalenesulfonic acid anion: | | |
| 3-Methoxy-4-diazodiphenylamine hexafluoro- | 0.02 | g |
| phosphate: | | |
| n-Dodecyl stearate: | 0.03 | g |
| Fluorine based surfactant | 0.05 | g |
| (MEGAFAC F-177 (a trade name), manufactured by | | |
| Dainippon Ink and Chemicals, Incorporated): | | |
| γ-Butyrolactone: | 10 | g |
| Methyl ethyl ketone: | 10 | g |
| 1-Methoxy-2-propanol: | 8 | g |

Fluorine-containing polymer

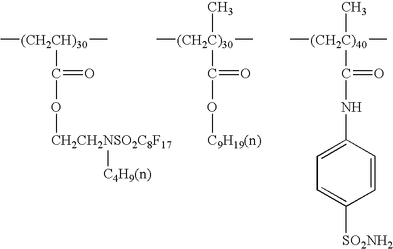

### Comparative Example 4

A planographic printing plate precursor was obtained in the same manner as in the foregoing Examples 25 to 32, except for using coating solutions prepared by adding the cyanine dye CD-X described in Comparative Example 1 in place of the specific IR coloring materials shown in Table 23 in the coating solution 7 for image forming layer.

[Evaluation of Planographic Printing Plate Precursor]

Each of the thus obtained planographic printing plate precursors was evaluated with respect to the sensitivity and development latitude in the same manners as in Examples 1 to 8. The evaluation results are also shown in Table 23.

TABLE 23

| | Specific IR coloring | | |
|---|---|---|---|
| | material | | |
| | (Coating solution 7 | | Development |
| | for image forming | Sensitivity | latitude |
| | layer) | (mJ/cm²) | (mS/cm) |
| Example 25 | CD-4 | 75 | 8 |
| Example 26 | CD-11 | 75 | 8 |
| Example 27 | CD-30 | 80 | 8 |
| Example 28 | CD-41 | 75 | 8 |
| Example 29 | CD-56 | 75 | 10 |
| Example 30 | PD-10 | 80 | 8 |
| Example 31 | PD-24 | 80 | 8 |
| Example 32 | AD-13 | 80 | 8 |
| Comparative | CD-X* | 105 | 6 |
| Example 4 | | | |

*A general cyanine dye CD-X was used in place of the specific IR coloring material according to the invention.

As is clear from Table 23, it was confirmed that the planographic printing plate precursors of Examples 25 to 32 using the specific IR coloring material according to the invention can achieve a high sensitivity together with a wide development latitude better than the planographic printing plate precursor of Comparative Example 4 having a generally widely employed cyanine dye CD-X added thereto.

### Examples 33 to 40

[Preparation of Planographic Printing Plate Precursor]

On the substrate B, the following coating solution 8 for an image forming layer was coated and dried at 130° C. for 1 minute to form an image forming layer, whereby planographic printing plate precursors were obtained. The coating amount after drying was 1.3 g/m².

<Coating Solution 8 for Image Forming Layer>

| | |
|---|---|
| Novolac resin | 1.0 g |
| (Cresol novolac of m/p ratio = 6/4, Mw = 4,000): | |
| Copolymer of ethyl methacrylate and 2- | 0.10 g |
| methacryloyloxyethyl succinic acid | |
| (molar ratio: 67/33, weight average molecular weight: | |
| 92,000): | |
| 2-Mercapto benzimidazole: | 0.05 g |
| Specific IR coloring material shown in Table 24: | 0.05 g |
| Dye in which a counter anion of Victoria Pure Blue | 0.01 g |
| BOH is a 6-hydroxy-2-naphthalenesulfonic acid anion: | |
| Fluorine based surfactant | 0.05 g |
| (MEGAFAC F-177 (a trade name), manufactured by | |
| Dainippon Ink and Chemicals, Incorporated): | |
| γ-Butyrolactone: | 3.0 g |
| Methyl ethyl ketone: | 8.0 g |
| 1-Methoxy-2-propanol: | 7.0 g |

### Comparative Example 5

A planographic printing plate precursor was obtained in the same manner as in the foregoing Examples 33 to 40, except for using coating solutions prepared by adding the cyanine dye CD-X described in Comparative Example 1 in place of the specific IR coloring materials shown in Table 24 in the coating solution 8 for image forming layer.

[Evaluation of Planographic Printing Plate Precursor]

Each of the thus obtained planographic printing plate precursors was evaluated with respect to the sensitivity and development latitude in the same manners as in Examples 1 to 8. The evaluation results are also shown in Table 24.

TABLE 24

| | Specific IR coloring | | |
|---|---|---|---|
| | material | | |
| | (Coating solution 8 | | Development |
| | for image forming | Sensitivity | latitude |
| | layer) | (mJ/cm²) | (mS/cm) |
| Example 33 | CD-2 | 95 | 10 |
| Example 34 | CD-10 | 100 | 10 |
| Example 35 | CD-27 | 95 | 10 |
| Example 36 | CD-38 | 100 | 12 |
| Example 37 | CD-50 | 100 | 12 |
| Example 38 | PD-3 | 105 | 10 |
| Example 39 | PD-19 | 105 | 10 |
| Example 40 | AD-2 | 105 | 10 |
| Comparative | CD-X* | 125 | 6 |
| Example 5 | | | |

*A general cyanine dye CD-X was used in place of the specific IR coloring material according to the invention.

As is clear from Table 24, it was confirmed that the planographic printing plate precursors of Examples 33 to 40 using the specific IR coloring material according to the invention can achieve high sensitivity together with a wide development latitude better than the planographic printing plate precursor of Comparative Example 5 having a generally widely employed cyanine dye CD-X added thereto.

As shown in the aforementioned Examples, any of the planographic printing plate precursors using the specific IR coloring material according to the invention are excellent in sensitivity and solubility discrimination. Accordingly, it has been understood that the first embodiment of the image forming material of the invention is useful as a heat mode-corresponding positive working planographic printing plate precursor.

According to the first embodiment of the invention, it is possible to provide an image forming material useful as a heat mode-corresponding positive working planographic printing plate precursor having a large difference of solubility in developing solutions between exposed areas and unexposed areas (solubility discrimination) and a high sensitivity.

### Examples 41 to 70

[Preparation of Substrates A and B]

Substrate A and B were prepared in the same manner as in Example 1.

[Synthesis of Copolymer 1]

A copolymer 1 was synthesized in the same manner as in Example 1

[Preparation of Planographic Printing Plate Precursor]

On the substrate A, the following coating solution 9 for an image forming layer was coated in a coating amount of 0.85 g/m² and dried at 110° C. for 50 seconds by a PERFECT OVEN PH200 (manufactured by TABAI ESPEC CORP.) with the wind control set at 7. Thereafter, the following coating solution 10 for an image forming layer was coated in a coating amount of 0.30 g/m² and then dried at 120° C. for one minute, whereby planographic printing plate precursors of examples 41 to 70 were obtained.

<Coating Solution 9 for Image Forming Layer>

| | | |
|---|---|---|
| Copolymer 1 as shown above: | 2.133 | g |
| Cyanine dye CD-X | 0.109 | g |
| (having a structure as shown below): | | |
| 4,4′-Bishydroxyphenylsulfone: | 0.126 | g |
| Tetrahydrophthalic anhydride: | 0.190 | g |
| p-Toluenesulfonic acid: | 0.008 | g |
| 3-Methoxy-4-diazodiphenylamifle hexafluoro- | 0.030 | g |
| phosphate: | | |
| Ethyl Violet whose counter ion is changed to an anion | 0.100 | g |
| of 6-hydroxy-2 -naphthalenesulfonic acid: | | |
| MEGAFAC F-176 | 0.035 | g |
| (a trade name for surface property improving fluorine | | |
| based surfactant, manufactured by Dainippon Ink and | | |
| Chemicals, Incorporated): | | |
| Methyl ethyl ketone: | 25.38 | g |
| 1-Methoxy-2-propanol: | 13.0 | g |
| y-Butyrolactone: | 13.2 | g |

Cyanine dye CD-X

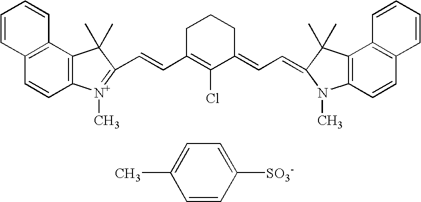

<Coating Solution 10 for Image Forming Layer>

| | |
|---|---|
| m,p-Cresol novolac | 0.3478 g |
| (m/p ratio: 6/4, weight average molecular weight: | |
| 4,500, containing 0.8% by weight of unreacted | |
| cresols): | |
| Cyanine dye CD-X as described above: | 0.0192 g |
| Onium salt represented by the general formula (2) | 0.0115 g |
| (compound shown in Table 25): | |
| MEGAFAC F-176 (20%) | 0.022 g |
| (a trade name for surface property improving | |
| surfactant, manufactured by Dainippon Ink and | |
| Chemicals, Incorporated): | |
| Methyl ethyl ketone: | 13.07 g |
| 1-Methoxy-2-propanol: | 6.79 g |

### Comparative Example 6

A planographic printing plate precursor of Comparative Example 6 was obtained in the same manner as in Examples 41 to 70, except for using the coating solution 10 for an image forming layer to be used in the upper image forming layer, from which the onium salt shown in Table 25 was eliminated.

### Comparative Example 7

A planographic printing plate precursor of Comparative Example 7 was obtained in the same manner as in Examples 41 to 70, except for using the coating solution 10 for an image forming layer to be used in the upper image forming layer, in which an ammonium compound (ammonium C—X) having a structure as shown below was used in place of the onium salt represented by the general formula (2).

Ammonium (C—X)

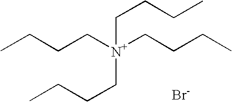

### Comparative Example 8

A planographic printing plate precursor of Comparative Example 8 was obtained in the same manner as in Examples 41 to 70, except for using the coating solution 10 for an image forming layer to be used in the upper image forming layer, in which an ammonium compound (ammonium C—Y) having a structure as shown below was used in place of the onium salt represented by the general formula (2).

Ammonium (C—Y)

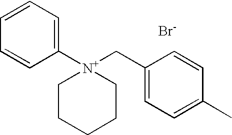

[Evaluation of Planographic Printing Plate Precursor]

Each of the thus obtained planographic printing plate precursors (Examples 41 to 70 and Comparative Examples 6 to 8) was evaluated using the following method. The evaluation results are also shown in Table 25.

(1. Sensitivity)

The obtained planographic printing plate precursor had a solid image drawn thereon using a TRENDSETTER (a trade name, manufactured by Creo Inc.) at a beam strength in the range of from 2 to 10 W and at a drum rotation speed of 150 rpm and was then developed for 12 seconds using a PS processor, LP940H (a trade name, manufactured by Fuji Photo Film Co., Ltd.) charged with a developing solution, DT-2 (a trade name, manufactured by Fuji Photo Film Co., Ltd.), (diluted at 1/8) and a finisher, FG-1 (a trade name, manufactured by Fuji Photo Film Co., Ltd.), (diluted at 1/1) while keeping a liquid temperature at 30° C. At this time, the developing solution had a conductivity of 43 mS/cm.

After the development, the printing plate precursor was observed by a loupe with a magnification of 25 times, and the presence or absence of film retention at a level at which printing staining did not substantially occur was evaluated. Then, an actual exposure energy was calculated from an exposure beam intensity at which no film retention was observed and defined as a sensitivity. According to the evaluation, the smaller the exposure energy is, the higher the sensitivity is.

(2. Latent Image Stability)

After exposure, the planographic printing plate precursor was stored in an environment at 25° C. and at a humidity of 70% for one hour and then evaluated in the same manner as in the foregoing evaluation of sensitivity. Thus, a degree of reduction of sensitivity immediately after the exposure was taken as an index. A numerical value expresses [(sensitivity one hour after the exposure)−(sensitivity immediately after the exposure)]. The small the numerical value, the better the latent image stability is.

(3. Development Latitude)

The obtained planographic printing plate precursor was imagewise drawn with a test pattern using a TRENDSETTER (a trade name, manufactured by Creo Inc.) at a beam strength of 9 W and at a drum rotation speed of 150 rpm and was then developed for 12 seconds using a PS processor, LP940H (a trade name, manufactured by Fuji Photo Film Co., Ltd.), charged with a solution obtained by diluting a developing solution, DT-2R (a trade name, manufactured by Fuji Photo Film Co., Ltd.), at 1/5 and blowing a carbon dioxide gas thereinto until the conductivity reached 37 mS/cm and a finisher, FG-1 (a trade name, manufactured by Fuji Photo Film Co., Ltd.), (diluted at 1/1) while keeping a liquid temperature at 30° C. Thereafter, a suitable amount of DT-2R (diluted at 1/5) was added to the developing solution to adjust the conductivity at 39 mS/cm, and the planographic printing plate precursor in which a test pattern had been similarly imagewise drawn was developed. Further, the conductivity was increased by 2 mS/cm each, and this operation was continued until film diminishment due to development of the image was remarkably observed.

At this time, with respect to the printing plate developed at each of the conductivities, the presence or absence of staining or coloration caused by film retention of the image forming layer due to development failure was confirmed, and a conductivity of the developing solution at which the development could be performed well was determined. Next, a critical conductivity at which the development film diminishment was kept at a level such that printing resistance was not substantially influenced was determined.

A width between the conductivity of the developing solution at which the development could be performed well and the critical conductivity at which the development film diminishment was kept at a level such that printing resistance was not substantially influenced was defined as development latitude.

TABLE 25

| | | | Latent image | Development |
|---|---|---|---|---|
| | | Sensitivity | stability | latitude |
| | Onium salt | (mJ/cm²) | (mJ/cm²) | (mS/cm) |
| Example 41 | C-1 | 110 | 5 | 10 |
| Example 42 | C-2 | 115 | 5 | 10 |
| Example 43 | C-3 | 115 | 5 | 10 |
| Example 44 | C-4 | 115 | 5 | 10 |
| Example 45 | C-5 | 105 | 5 | 12 |
| Example 46 | C-6 | 100 | 5 | 10 |
| Example 47 | C-7 | 105 | 5 | 10 |
| Example 48 | C-8 | 105 | 5 | 10 |
| Example 49 | C-9 | 110 | 5 | 10 |
| Example 50 | C-10 | 100 | 0 | 12 |
| Example 51 | C-11 | 115 | 5 | 10 |
| Example 52 | C-12 | 110 | 5 | 10 |
| Example 53 | C-13 | 110 | 5 | 10 |
| Example 54 | C-14 | 105 | 5 | 12 |
| Example 55 | C-15 | 100 | 0 | 12 |
| Example 56 | C-16 | 110 | 5 | 10 |
| Example 57 | C-17 | 110 | 5 | 10 |
| Example 58 | C-18 | 100 | 0 | 10 |
| Example 59 | C-19 | 110 | 5 | 10 |
| Example 60 | C-20 | 100 | 0 | 10 |
| Example 61 | C-21 | 100 | 5 | 12 |
| Example 62 | C-22 | 110 | 5 | 10 |
| Example 63 | C-23 | 115 | 5 | 10 |
| Example 64 | C-24 | 110 | 5 | 10 |
| Example 65 | C-25 | 105 | 5 | 12 |
| Example 66 | C-26 | 105 | 5 | 10 |
| Example 67 | C-27 | 110 | 5 | 10 |
| Example 68 | C-28 | 105 | 5 | 10 |
| Example 69 | C-29 | 105 | 5 | 10 |
| Example 70 | C-30 | 100 | 0 | 10 |
| Comparative | Nil | 105 | 5 | 1 |
| Example 6 | | | | |
| Comparative | C-X | 145 | 20 | 2 |
| Example 7 | | | | |
| Comparative | C-Y | 115 | 25 | 12 |
| Example 8 | | | | |

As shown in Table 25, it can be understood that the planographic printing plate precursors of Examples 41 to 70 to which the image forming material of the invention is applied realize an improvement of latent image stability while keeping the development latitude and sensitivity at high levels. On the other hand, it has been understood that the planographic printing plate precursor of Comparative Example 6, in which the onium salt represented by the general formula (2) (onium salt according to the invention) is not added can be subjected to high-sensitivity recording but is inferior in the development latitude; that the planographic printing plate precursor of Comparative Example 7 in which the known ammonium compound C—X capable of forming a strong mutual action with alkali-soluble resins is added is inferior in all of the sensitivity, development latitude and latent image stability so that it is at a problematic level in the practical use; and that the planographic printing plate precursor of Comparative Example 8 in which the ammonium C—Y is added is good in the sensitivity and development latitude but is inferior in the latent image stability.

### Examples 71 to 100

On the substrate B, the following coating solution 11 for an image forming layer was coated in a coating amount after drying of 1.2 g/m², whereby planographic printing plate precursors of examples 71 to 100 were obtained.

<Coating Solution 11 for Image Forming Layer>

| | | |
|---|---|---|
| Fluorine-containing polymer | 0.03 | g |
| (having a structure as shown below): | | |
| Copolymer 1 as described above: | 0.75 | g |
| Novolac (m/p = 6/4, Mw = 4,000): | 0.20 | g |
| Onium salt represented by the general formula (2) | 0.05 | g |
| (compound shown in Table 26): | | |
| Tetrahydrophthalic anhydride: | 0.03 g | |
| Pyrylium dye B | 0.017 g | |
| (having a structure as shown below): | | |
| Dye in which a counter ion of Victoria Pure Blue BOR is | 0.015 | g |
| a 1-naphthalenesulfonic acid anion: | | |
| 3-Methoxy-4-diazodiphenylamine hexafluoro- | 0.02 | g |
| phosphate: | | |
| n-Dodecyl stearate: | 0.03 | g |
| Fluorine based surfactant | 0.05 | g |
| (MEGAFAC F-177 (a trade name), manufactured by | | |
| Dainippon Ink and Chemicals, Incorporated): | | |
| γ-Butyrolactone: | 10 | g |
| Methyl ethyl ketone: | 10 | g |
| 1-Methoxy-2-propanol: | 8 | g |

Fluorine-containing polymer

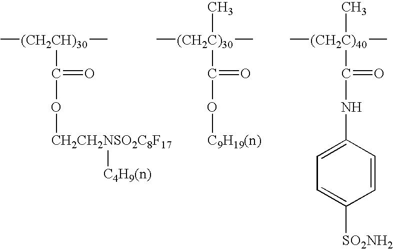

Pyrylium dye B

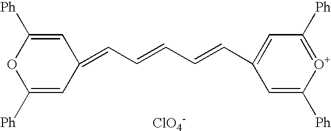

### Comparative Example 9

A planographic printing plate precursor of Comparative Example 9 was obtained in the same manner as in Examples 71 to 100, except for using the coating solution 11 for image forming layer, from which the onium salt represented by the general formula (2) was eliminated.

### Comparative Example 10

A planographic printing plate precursor of Comparative Example 10 was obtained in the same manner as in Examples 71 to 100, except for using the coating solution 11 for image forming layer, in which an ammonium compound (ammonium C—X) used in Comparative Example 7 was used in place of the onium salt represented by the general formula (2).

### Comparative Example 11

A planographic printing plate precursor of Comparative Example 11 was obtained in the same manner as in Examples 71 to 100, except for using the coating solution 11 for image forming layer, in which an ammonium compound (ammonium C—Y) used in Comparative Example 8 was used in place of the onium salt represented by the general formula (2).

Each of the obtained planographic printing plate precursors of Examples 71 to 100 and Comparative Examples 9 to 11 was evaluated in the same manners as in Example 41. The evaluation results are also shown in Table 26.

TABLE 26

| | | | Latent image | Development |
|---|---|---|---|---|
| | | Sensitivity | stability | latitude |
| | Onium salt | (mJ/cm²) | (mJ/cm²) | (mS/cm) |
| Example 71 | C-1 | 100 | 5 | 6 |
| Example 72 | C-2 | 105 | 5 | 6 |
| Example 73 | C-3 | 105 | 5 | 6 |
| Example 74 | C-4 | 105 | 5 | 6 |
| Example 75 | C-5 | 95 | 5 | 8 |
| Example 76 | C-6 | 90 | 5 | 6 |
| Example 77 | C-7 | 95 | 5 | 6 |
| Example 78 | C-8 | 100 | 5 | 6 |
| Example 79 | C-9 | 105 | 5 | 6 |
| Example 80 | C-10 | 90 | 0 | 8 |
| Example 81 | C-11 | 105 | 5 | 6 |
| Example 82 | C-12 | 105 | 5 | 6 |
| Example 83 | C-13 | 105 | 5 | 6 |
| Example 84 | C-14 | 100 | 5 | 8 |
| Example 85 | C-15 | 95 | 0 | 8 |
| Example 86 | C-16 | 105 | 5 | 6 |
| Example 87 | C-17 | 100 | 5 | 6 |
| Example 88 | C-18 | 95 | 0 | 8 |
| Example 89 | C-19 | 105 | 5 | 6 |
| Example 90 | C-20 | 90 | 0 | 6 |
| Example 91 | C-21 | 95 | 5 | 8 |
| Example 92 | C-22 | 100 | 5 | 6 |
| Example 93 | C-23 | 110 | 5 | 6 |
| Example 94 | C-24 | 105 | 5 | 6 |
| Example 95 | C-25 | 100 | 5 | 8 |
| Example 96 | C-26 | 100 | 5 | 8 |
| Example 97 | C-27 | 105 | 5 | 6 |
| Example 98 | C-28 | 100 | 5 | 6 |
| Example 99 | C-29 | 100 | 5 | 6 |
| Example 100 | C-30 | 90 | 0 | 6 |
| Comparative | Nil | 100 | 5 | 1 |
| Example 9 | | | | |
| Comparative | C-X | 145 | 45 | 2 |
| Example 10 | | | | |
| Comparative | C-Y | 105 | 45 | 8 |
| Example 11 | | | | |

As shown in Table 26, it can be understood that though the planographic printing plate precursors of Examples 71 to 100 to which the image forming material of the invention is applied have an image forming layer of a single layer structure, they realize an improvement of latent image stability while keeping the development latitude and sensitivity at high levels similar to those of the foregoing Examples 41 to 70 having an image forming layer of a double layer structure. On the other hand, it has been understood that the planographic printing plate precursor of Comparative Example 9 in which the onium salt represented by the general formula (2) is not added is inferior in the development latitude and that the planographic printing plate precursors of Comparative Examples 10 and 11 in which an ammonium compound falling outside the scope of the invention is added is inferior in any of the sensitivity, development latitude or latent image stability.

### Examples 101 to 130

On the substrate B, the following coating solution 12 for an image forming layer was coated and dried at 130° C. for 1 minute to form an image forming layer, whereby planographic printing plate precursors of Examples 101 to 130 were obtained. The coating amount after drying was 1.3 g/m².

<Coating Solution 12 for Image Forming Layer>

| | | |
|---|---|---|
| Novolac resin | 1.0 | g |
| (Cresol novolac of m/p ratio = 6/4, Mw = 4,000): | | |
| Onium salt represented by the general formula (2) | 0.05 | g |
| (compound shown in Table 27): | | |
| Cyanine dye CD-X | 0.05 | g |
| (having a structure as shown below): | | |
| Dye in which a counter anion of Victoria Pure Blue | 0.01 | g |
| BOR is a 1-naphthalenesulfonic acid anion: | | |
| Fluorine based surfactant | 0.05 | g |
| (MEGAFAC F-177 (a trade name), manufactured by | | |
| Dainippon Ink and Chemicals, Incorporated): | | |
| γ-Butyrolactone: | 3.0 | g |
| Methyl ethyl ketone: | 8.0 | g |
| 1 -Methoxy-2-propanol: | 7.0 | g |

Cyanine dye CD-X

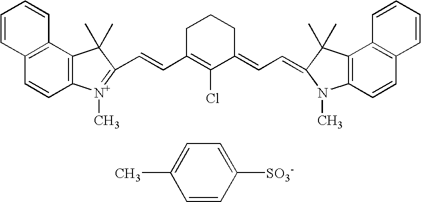

### Comparative Example 12

A planographic printing plate precursor of Comparative Example 12 was obtained in the same manner as in Examples 101 to 130, except for using the coating solution 12 for image forming layer, from which the onium salt represented by the general formula (2) was eliminated.

### Comparative Example 13

A planographic printing plate precursor of Comparative Example 13 was obtained in the same manner as in Examples 101 to 130, except for using the coating solution 12 for image forming layer, in which an ammonium compound (ammonium C—X) used in Comparative Example 7 was used in place of the onium salt represented by the general formula (2).

### Comparative Example 14

A planographic printing plate precursor of Comparative Example 14 was obtained in the same manner as in Examples 101 to 130, except for using the coating solution 12 for image forming layer, in which an ammonium compound (ammonium C—Y) used in Comparative Example 8 was used in place of the onium salt represented by the general formula (2).

Each of the obtained planographic printing plate precursors of Examples 101 to 130 and Comparative Examples 12 to 14 was evaluated in the same manners as in Example 41. The evaluation results are also shown in Table 27.

TABLE 27

| | | | Latent image | Development |
|---|---|---|---|---|
| | | Sensitivity | stability | latitude |
| | Onium salt | (mJ/cm²) | (mJ/cm²) | (mS/cm) |
| Example 101 | C-1 | 105 | 5 | 6 |
| Example 102 | C-2 | 110 | 5 | 6 |
| Example 103 | C-3 | 105 | 5 | 6 |
| Example 104 | C-4 | 110 | 5 | 6 |
| Example 105 | C-5 | 105 | 5 | 8 |
| Example 106 | C-6 | 95 | 5 | 6 |
| Example 107 | C-7 | 105 | 5 | 6 |
| Example 108 | C-8 | 105 | 5 | 6 |
| Example 109 | C-9 | 110 | 5 | 6 |
| Example 110 | C-10 | 90 | 0 | 8 |
| Example 111 | C-11 | 110 | 5 | 6 |
| Example 112 | C-12 | 110 | 5 | 6 |
| Example 113 | C-13 | 110 | 5 | 6 |
| Example 114 | C-14 | 105 | 5 | 8 |
| Example 115 | C-15 | 100 | 0 | 8 |
| Example 116 | C-16 | 110 | 5 | 6 |
| Example 117 | C-17 | 110 | 5 | 6 |
| Example 118 | C-18 | 100 | 0 | 8 |
| Example 119 | C-19 | 110 | 5 | 6 |
| Example 120 | C-20 | 100 | 0 | 6 |
| Example 121 | C-21 | 95 | 5 | 8 |
| Example 122 | C-22 | 115 | 5 | 6 |
| Example 123 | C-23 | 110 | 5 | 6 |
| Example 124 | C-24 | 110 | 5 | 6 |
| Example 125 | C-25 | 105 | 5 | 8 |
| Example 126 | C-26 | 105 | 5 | 6 |
| Example 127 | C-27 | 110 | 5 | 6 |
| Example 128 | C-28 | 105 | 5 | 6 |
| Example 129 | C-29 | 110 | 5 | 6 |
| Example 130 | C-30 | 95 | 0 | 6 |
| Comparative | Nil | 105 | 5 | 1 |
| Example 12 | | | | |
| Comparative | C-X | 145 | 40 | 2 |
| Example 13 | | | | |
| Comparative | C-Y | 105 | 40 | 8 |
| Example 14 | | | | |

As shown in Table 27, it can be understood that though the planographic printing plate precursors of Examples 101 to 130 to which the image forming material of the invention is applied have an image forming layer of a single layer structure using a novolac resin, they realize an improvement of latent image stability while keeping the development latitude and sensitivity at high levels similar to those of the foregoing Examples 41 to 70 having an image forming layer of a double layer structure. On the other hand, it has been understood that the planographic printing plate precursor of Comparative Example 12 in which the onium salt represented by the general formula (2) is not added is low in scuff resistance and inferior in the development latitude and that the planographic printing plate precursors of Comparative Examples 13 and 14 in which an ammonium compound falling outside the scope of the invention is added is problematic in any of the sensitivity, development latitude or latent image stability.

In the light of the above, according to the second embodiment of the invention, it is possible to provide a heat mode-corresponding positive working image forming material having excellent solubility discrimination. This image forming material is useful as a positive working planographic printing plate precursor that can be subjected to direct plate making using infrared lasers, is excellent in latitude during image formation by development, is improved in latent image stability, and is able to form images having an excellent contrast.

What is claimed is:

1. An image forming material comprising a support and an image forming layer which is laminated on the support and contains at least (A) a water-insoluble and alkali-soluble high-molecular compound and (B) a compound having a structure represented by the following general formula (1) and having an absorption maximum at a wavelength in a range of 760 nm to 1,200 nm:
X⁻M+ General formula (1):
wherein in the general formula (1), X⁻ represents an anion containing at least one substituent having an alkali-dissociating proton; and M⁺ represents a counter cation which is an atomic group having an absorption maximum at a wavelength in a range of 760 nm to 1,200 nm.

2. The image forming material according to claim 1, wherein in the general formula (1), the counter cation represented by M⁺ is a counter cation represented by the following general formula (A): 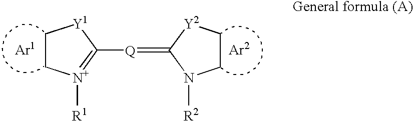
wherein in the general formula (A), R¹ and R² each independently represents an alkyl group having from 1 to 12 carbon atoms, which may have a substituent selected from an alkoxy group, an aryl group, an amide group, an alkoxycarbonyl group, a hydroxyl group, a sulfo group, and a carboxyl group; Y¹ and Y² each independently represents an oxygen atom, a sulfur atom, a selenium atom, a dialkylmethylene group, or —CH═CH—; Ar¹ and Ar² each independently represents an aromatic hydrocarbon group, which may have a substituent selected from an alkyl group, an alkoxy group, a halogen atom, and an alkoxycarbonyl group, and may fuse an aromatic ring together with Y¹ or Y² and two carbon atoms adjacent thereto; and Q represents an alkoxy group, an aryloxy group, an alkylthio group, an arylthio group, a dialkylamino group, a diarylamino group, a halogen atom, an alkyl group, an aralkyl group, a cycloalkyl group, an aryl group, an oxy group, or an iminium salt group.

3. The image forming material according to claim 1, wherein in the general formula (1), the counter cation represented by M⁺ is a counter cation represented by the following general formula (C): 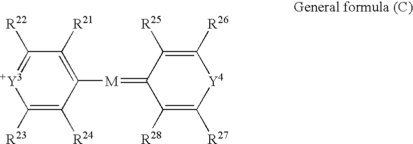
wherein in the general formula (C), Y³ and Y⁴ each independently represents an oxygen atom, a sulfur atom, a selenium atom, or a tellurium atom; M represents a methine chain having at least five or more conjugated carbon atoms; and R²¹ to R²⁴ and R²⁵ to R²⁸ each independently represents a hydrogen atom, a halogen atom, a cyano group, an alkyl group, an aryl group, an alkenyl group, an alkynyl group, a carbonyl group, a thio group, a sulfonyl group, a sulfinyl group, an oxy group, or an amino group.

4. The image forming material according to claim 1, wherein in the general formula (1), the counter cation represented by M⁺ is a counter cation represented by the following general formula (D): 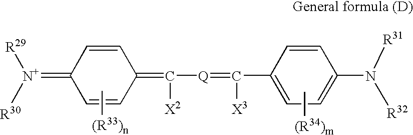
wherein in the general formula (D), R²⁹ to R³² each independently represents a hydrogen atom, an alkyl group, or an aryl group; R³³ and R³⁴ each independently represents an alkyl group, a substituted oxy group, or a halogen atom; n and m each independently represents an integer from 0 to 4; R²⁹ and R³⁰, or R³¹ and R³² may bond to form a ring; at least one of R²⁹ and R³⁰ may bond with R³³ to form a ring; at least one of R³¹ and R³² may bond with R³⁴ to form a ring; in the case when a plural number of R³³ or R³⁴ are present, the plurality of R³³ or the plurality of R³⁴ may bond with each other to form a ring; X² and X³ each independently represents a hydrogen atom, an alkyl group, or an aryl group; and Q represents an optionally substituted trimethine group or pentamethine group and may form a ring structure together with a divalent organic group.

5. The image forming material according to claim 1, wherein in the general formula (1), the counter cation represented by M⁺ is a counter cation represented by the following general formula (F-1) or (F-2): 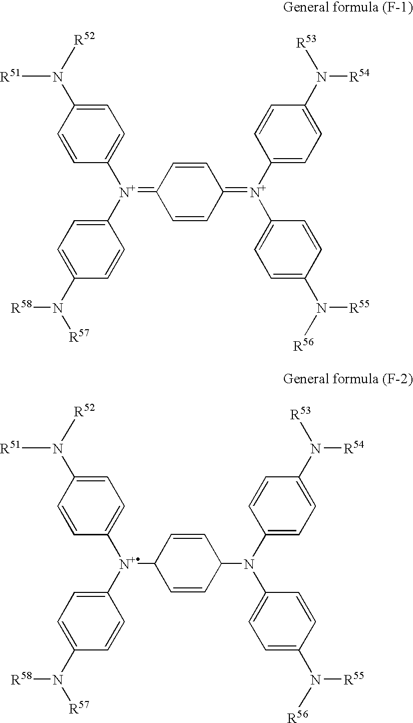
wherein in the general formula (F-1) and (F-2), R⁵¹ to R⁵⁸ each independently represents a hydrogen atom, an optionally substituted alkyl group, or an optionally substituted aryl group.

6. The image forming material according to claim 1, wherein in the general formula (1), the anion containing at least one substituent having an alkali-dissociating proton represented by X⁻ is selected from the group consisting of a phenolic hydroxyl group, a carboxyl group, a mercapto group, a phosphonic acid group, a phosphoric acid group, a sulfonamide group, a substituted sulfonamide based group, a sulfonic acid group, a sulfinic acid group, —C(CF₃)₂OH, and —COCH₂COCF₃.

7. The image forming material according to claim 1, wherein the compound having a structure represented by general formula (1) is an onium salt represented by the following general formula (1-A):
R^{A}—SO₃⁻M⁺ General formula (1-A):
wherein in the general formula (1-A), R^{A} represents a substituent containing at least one substituent having an alkali-dissociating proton; the substituent having an alkali-dissociating proton is synonymous with the substituent having an alkali-dissociating proton in the general formula (1); and M⁺ is synonymous with M⁺ in the general formula (1).

8. The image forming material according to claim 1, wherein the compound having a structure represented by general formula (1) is an onium salt represented by the following general formula (1-B):
Ar^{B}—SO₃⁻M⁺ General formula (1-B):
wherein in the general formula (1-B), Ar^{B} represents an aryl group containing at least one substituent having an alkali-dissociating proton; the substituent having an alkali-dissociating proton is synonymous with the substituent having an alkali-dissociating proton in the general formula (1); and M⁺ is synonymous with M⁺ in the general formula (1).

9. The image forming material according to claim 1, wherein the image forming layer further contains (C) a light-heat converting agent.

10. The image forming material according to claim 1, wherein the image forming material is a planographic printing plate precursor.

11. An image forming material comprising a support and an image forming layer which is laminated on the support and contains at least (A) a water-insoluble and alkali-soluble high-molecular compound, (C) a light-heat converting agent, and (D) an onium salt represented by the following general formula (2):
X⁻M₁⁺ General formula (2):
wherein in the general formula (2), X⁻ represents an anion containing at least one substituent having an alkali-dissociating proton; and M₁⁺ represents a counter cation selected from solfonium, iodonium, ammonium, phosphonium, and oxonium.

12. The image forming material according to claim 11, wherein in the general formula (2), the counter cation represented by M₁⁺ is quaternary ammonium.

13. The image forming material according to claim 12, wherein the quaternary ammonium has a structure represented by the following general formula (M): 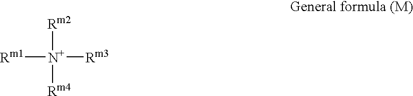
Wherein in the general formula (M), R^{m1} to R^{m4} each independently represents a substituent having one or more carbon atoms and may bond with each other to form a ring structure.

14. The image forming material according to claim 12, wherein the quaternary ammonium has a structure represented by the following general formula (M-1): 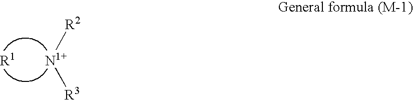
wherein in the general formula (M-1), R¹ represents a residue forming a ring structure containing an N¹ atom; R² and R³ each independently represents an organic group and may bond with each other to form a ring structure; and at least one of R² and R³ may be bonded to R¹ to from a ring structure.

15. The image forming material according to claim 11, wherein in the general formula (2), the anion containing at least one substituent having an alkali-dissociating proton and represented by X⁻ is selected from the group consisting of a phenolic hydroxyl group, a carboxyl group, a mercapto group, a phosphonic acid group, a phosphoric acid group, a sulfonamide group, a substituted sulfonamide based group, a sulfonic acid group, a sulfinic acid group, —C(CF₃)₂OH, and —COCH₂COCF₃.

16. The image forming material according to claim 11, wherein the onium salt represented by the general formula (2) is an onium salt represented by the following general formula (2-A):
R^{A}—SO₃⁻M₁⁺ General formula (2-A):
wherein in the general formula (2-A), R^{A} represents a substituent containing at least one substituent having an alkali-dissociating proton; the substituent having an alkali-dissociating proton is synonymous with the substituent having an alkali-dissociating proton in the general formula (2); and M₁⁺ is synonymous with M₁⁺ in the general formula (2).

17. The image forming material according to claim 11, wherein the onium salt represented by general formula (2) is an onium salt represented by the following general formula (2-B):
Ar^{B}—SO₃⁻M₁⁺ General formula (2-B):
wherein in the general formula (2-B), Ar^{B} represents an aryl group containing at least one substituent having an alkali-dissociating proton; the substituent having an alkali-dissociating proton is synonymous with the substituent having an alkali-dissociating proton in the general formula (2); and M₁⁺ is synonymous with M⁺ in the general formula (2).

18. The image forming material according to claim 11, wherein the onium salt represented by the general formula (2) does not exhibit substantially absorption between 500 nm and 600 nm.

19. The image forming material according to claim 11, wherein the image forming material is a planographic printing plate precursor.
